(19) United States
(12) Patent Application Publication
(10) Pub. No.: US 2014/0091418 A1
(43) Pub. Date: Apr. 3, 2014

(54) COLOR FILTER, CCD SENSOR, CMOS SENSOR, ORGANIC CMOS SENSOR, AND SOLID-STATE IMAGE SENSOR

(71) Applicant: Fujifilm Corporation, Tokyo (JP)

(72) Inventors: Hiroshi TAGUCHI, Shizuoka (JP); Naotsugu MURO, Shizuoka (JP); Makoto YAMADA, Shizuoka (JP)

(73) Assignee: Fujifilm Corporation, Tokyo (JP)

(21) Appl. No.: 14/096,966

(22) Filed: Dec. 4, 2013

Related U.S. Application Data
(63) Continuation of application No. PCT/JP2012/064017, filed on May 24, 2012.

(30) Foreign Application Priority Data
Jun. 6, 2011 (JP) 2011-126294
Apr. 20, 2012 (JP) 2012-096541

(51) Int. Cl. G02B 5/20; H01L 31/0232

(52) U.S. Cl. CPC G02B 5/201; H01L 31/0232
USPC 257/432; 359/891

(57) ABSTRACT

A color filter includes: a red pixel in which a transmittance of a light having a wavelength of 400 nm is 15% or less, and a transmittance of a light having a wavelength of 650 nm is 90% or more; a green pixel in which a transmittance of a light having a wavelength of 450 nm is 5% or less, and a transmittance of a light having a wavelength within a range of from 500 nm to 600 nm is 90% or more; and a blue pixel in which a transmittance of a light having a wavelength of 450 nm is 85% or more, a transmittance of a light having a wavelength of 500 nm is from 10% to 50%, and a transmittance of a light having a wavelength of 700 nm is 10% or less.

### CROSS-REFERENCE TO RELATED APPLICATIONS

This application is a continuation application of International Application No. PCT/JP2012/064017, filed May 24, 2012, the disclosure of which is incorporated herein by reference in its entirety. Further, this application claims priority from Japanese Patent Application No. 2011-126294, filed Jun. 6, 2011, and Japanese Patent Application No. 2012-096541, filed Apr. 20, 2012, the disclosures of which are incorporated herein by reference in their entirety.

### TECHNICAL FIELD

The present invention relates to a color filter, a charge-coupled device (CCD) sensor, a complementary metal oxide semiconductor (CMOS) sensor, an organic CMOS sensor, and a solid-state image sensor.

### BACKGROUND ART

Color filters are essential components of a solid-state image sensor, a liquid crystal display, and the like. Improvement in color separation and improvement in color reproducibility are required for a color filter for solid-state image sensor, in particular.

Such a color filter has a colored region with plural colors (that is, a colored cured film), and generally has at least colored regions of red color, green color, and blue color (hereinbelow, may be referred to as “color patterns”, or a “colored pixels”). As for a method of forming color patterns, a color pattern of the first color hue is formed by coating with a colored radiation-sensitive composition containing a red, green, or blue colorant, followed by light exposure and development, and if necessary a heating treatment; and the same coating, light exposure, and development, and, if necessary, heat treatment, are repeated for the second color hue and the third color hue.

As a colorant used for a color filter, pigments are widely used since it has a vivid tone and high coloring power. In particular, a pigment which is micronized and exhibits suitable color separation property is preferably used.

For example, it is known that, when a combination of two colorants of a green pigment having a specific structure and a yellow pigment having a specific structure is used as the pigment used in a green pixel of a color filter for a liquid crystal display device, white brightness is improved without any significant change of color temperature (see, for example, Japanese Patent Application Laid-Open (JP-A) No. 2005-173287). However, since a color filter for a solid-state image sensor is required to have improved color separation and improved color reproducibility of an image by lowering the cross point of a transmission curve of blue and red pixels, it was difficult to obtain sufficient color reproducibility by the technique described above.

In recent years, it has been desired to use ultrafine colored pixels (for example, a color pattern in which length of one side is 1.0 μm or less) for the purpose of improving resolution in a solid-state image sensor. However, it is known that deterioration is caused by noise due to the ultrafine colored pixels.

Conventionally, as a colorant for red pixels, a mixture of C. I. Pigment Red 254 and C. I. Pigment Yellow 139 is generally used. As a colorant for green pixels, a mixture of C. I. Pigment Green 36, C. I. Pigment Green 7, and C. I. Pigment Yellow 139 is used. Further, as a colorant for blue pixels, a mixture of C. I. Pigment Blue 15:6 and C. I. Pigment Violet 23 is used. According to such configuration, a color filter having red, green, and blue colors is formed.

However, when such a combination according to adjustment of proportions of respective colorants of red, green, and blue colors, or concentrations thereof is used in a solid-state image sensor, it is difficult to accomplish a balance between noise and color reproducibility. Thus, image quality improvement of a solid-state image sensor has been demanded.

### SUMMARY OF INVENTION

### Technical Problem

The invention is made under the circumstances described above, and is directed to approach the following objects.

Specifically, an aspect of the invention is to provide a color filter which has at least red, green, and blue color pixels and which allows a large amount of light to be transmitted therethrough, whereby a solid-state image sensor with low noise and favorable color reproducibility is obtained when the color filter is used for the solid-state image sensor.

Another aspect of the invention is to provide a solid-state image sensor such as a CCD sensor, a CMOS sensor, or an organic CMOS sensor having the color filter of the invention.

### Solution to Problem

Under the circumstances, the inventors of the invention have conducted intensive studies and found that the above objects relating to a color filter having red pixels, green pixels, and blue pixels are achieved when a light transmittance at 400 nm is 15% or less and a light transmittance at 650 nm is 90% or more in a red pixel, a light transmittance at 450 nm is 5% or less and a light transmittance at any wavelength within the range of from 500 nm to 600 nm is 90% or more in a green pixel, and a light transmittance at 450 nm is 85% or more, a light transmittance at 500 nm is from 10% to 50%, and a light transmittance at 700 nm is 10% or less in a blue pixel.

Embodiments of the invention are as described below.

<1> A color filter, comprising:
a red pixel having a transmittance at a wavelength of 400 nm or 15% or less, and a transmittance at a wavelength of 650 nm or 90% or more;
a green pixel having a transmittance at a wavelength of 450 nm of 5% or less, and a transmittance at a wavelength within a range of from 500 nm to 600 nm of 90% or more; and
a blue pixel having a transmittance at a wavelength of 450 nm of 85% or more, a transmittance at a wavelength of 500 nm of from 10% to 50%, and a transmittance at a wavelength of 700 nm of 10% or less.

<2> The color filter according to <1>, wherein:
the red pixel comprises C. I. Pigment Yellow 139;
the green pixel comprises at least one of C. I. Pigment Yellow 185 or C. I. Pigment Yellow 150; and
the blue pixel comprises a dipyrromethene dye represented by the following Formula (M):

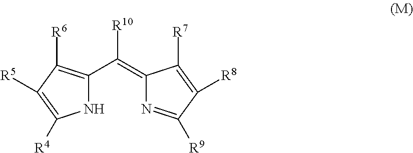

wherein, in Formula (M), R⁴ to R¹⁰ each independently represent a hydrogen atom or a monovalent substituent group; provided that R⁴ and R⁹ do not bind with each other to form a ring.

<3> The color filter according to <2>, wherein the total content of C. I. Pigment Yellow 185 and C. I. Pigment Yellow 150 in the green pixel is from 10% by mass to 60% by mass with respect to the total mass of the colorants included in the green pixel.

<4> The color filter according to <2>, wherein the content of C. I. Pigment Yellow 139 in the red pixel is from 20% by mass to 50% by mass with respect to the total mass of the colorants included in the red pixel.

<5> The color filter according to <2>, wherein the content of the dipyrromethene dye represented by Formula (M) in the blue pixel is from 10% by mass to 50% by mass with respect to the total mass of the colorants included in the blue pixel.

<6> A CCD sensor, comprising the color filter according to any one of <1> to <5>.

<7> A CMOS sensor, comprising the color filter according to any one of <1> to <5>.

<8> An organic CMOS sensor, comprising the color filter according to any one of <1> to <5>.

<9> A solid-state image sensor, comprising the color filter according to any one of <1> to <5>.

In the color filter of the present invention having a red pixel, a green pixel, and a blue pixel, the red pixel has a transmission of 15% or less at a wavelength of 400 nm and a transmission of 90% or more at a wavelength of 650 nm, the green pixel has a transmission of 5% or less at a wavelength of 450 nm and a transmission of 90% or more at any wavelength within the range of 500 nm to 600 nm, and the blue pixel has a transmission of 85% or more at a wavelength 450 nm, a transmission of from 10% to 50% at a wavelength of 500 nm, and a transmission of 10% or less at a wavelength of 700 nm. As a result, not only the cross point of the transmissions of the red pixel and green pixel is lowered but also the cross point of the transmissions of the green pixel and blue pixel is lowered. Therefore, the stray light in a boundary region between the red pixel and green pixel, and the stray light in a boundary region between the green pixel and blue pixel are reduced so that the generation of noise is significantly inhibited when the color filter of the invention is used in a solid-state image sensor.

Since the respective colored pixels of the color filter have the transmissions described above, the amount of transmitted light is increased for each colored pixel. Therefore, when the color filter of the invention is used for a solid-state image sensor, the sensitivity of the solid-state image sensor is improved, and more favorable color reproducibility is obtained.

In particular, when the red pixel contains C. I. Pigment Yellow 139, the green pixel contains at least one of C. I. Pigment Yellow 185 or C. I. Pigment Yellow 150, and the blue pixel contains a dipyrromethene pigment represented by Formula (M), desired transmissions for respective colored pixels are readily obtained. Further, when the colored filter of the invention is used for a solid-state image sensor, the generation of noise is inhibited, the sensitivity thereof is improved, and favorable color reproducibility is obtained for the solid-state image sensor.

### Advantageous Effects of Invention

According to the invention, when the color filter having red-, blue- and green-colored pixels with large amounts of transmitted light is used for a solid-state image sensor, the color filter enables a solid-state image sensor having little noise and favorable color reproducibility is provided.

Furthermore, a solid-state image sensor such as a CCD sensor, a CMOS sensor, or an organic CMOS sensor is provided by using the color filter according to the invention.

### BRIEF DESCRIPTION OF THE DRAWINGS

FIG. 1 is a cross-sectional schematic view showing the configuration of a solid-state image sensor.

FIG. 2 shows an example of the configuration of peripheral circuits of a solid-state image sensor.

### DESCRIPTION OF EMBODIMENTS

Hereinbelow, the present invention is described in greater detail.

Explanations of the constitutional elements described below are based on representative embodiments of the invention, and it is evident that the invention is not limited to them.

Further, the numeric range described in the specification with the term “to” indicates the range which includes the numbers described before and after “to” as a lower limit and an upper limit, respectively.

The color filter of the invention has at least a red pixel, a green pixel, and a blue pixel having the following spectral characteristics.

Specifically, the red pixel has spectral characteristics such that the transmission of light having a wavelength of 400 nm is 15% or less, preferably 14% or less, and more preferably 12% or less, and the transmission of light having a wavelength of 650 nm is 90% or more, preferably 92% or more, and more preferably 95% or more.

The green pixel has spectral characteristics such that the transmission of light having a wavelength of 450 nm is 5% or less and the transmission of light having a wavelength within the range of from 500 nm to 600 nm is 90% or more.

The blue pixel has spectral characteristics such that the transmission of light having a wavelength of 450 nm is 85% or more, preferably 86% or more, and more preferably 87% or more, the transmission of light having a wavelength of 500 nm is from 10% to 50%, preferably from 30% to 50%, more preferably from 35% to 49%, and still more preferably from 38% to 48%, and the transmission of light having a wavelength of 700 nm is 10% or less, preferably 9% or less, and more preferably 8% or less.

Spectral characteristics of the pixels having respective colors described above are measured according to the method described below.

A radiation-sensitive composition containing a colorant for having pixels having each color is prepared, and coated in a particular thickness on a glass substrate by a method such as spin coating. Them, drying of the coated film was conducted using a hot plate at 100° C. for 180 seconds, followed by further drying, a heating treatment (that is, post baking) using a hot plate at 200° C. for 300 seconds.

The glass substrate having colored pixels is subjected to transmission measurement in the wavelength range of 400 nm to 700 nm by using an ultraviolet, visible, and near infrared spectrophotometer UV3600 (trade name, manufactured by Shimadzu Corporation) (reference: glass substrate).

Since respective pixels of red color, green color, or blue color of the color filter of the invention contains a colorant, the transmission specified in the invention is obtained for each wavelength.

The colorant used for forming pixels having respective colors is described below.

Red Pixel

It is preferable that the red pixel has spectral characteristics such that the transmission of light at wavelength of 400 nm is 15% or less and the transmission of light at a wavelength of 650 nm is 90% or more. As a colorant used for obtaining such spectral characteristics, a pigment or a dye is preferably used. The pigment and dye may have any kind of chemical structure.

It is preferable that the red pixel contains at least one of a red pigment or a red dye as a red colorant and at least one of a yellow pigment or a yellow dye as a yellow colorant. It is more preferable that the red pixel contains a red pigment and a yellow pigment.

A mixture of a dye and a pigment may be used. Further, as for the colorant having each color hue, one type may be used or two or more types may be used in combination.

For example, a combination of two or more types of red colorants and a yellow colorant may be used, a combination of a red colorant and two or more types of yellow colorants may be used, or a combination of two or more types of red colorants and two or more types of yellow colorants may be used.

Examples of the red pigment include C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279.

Examples of red dye include C. I. Acid Red 1, 4, 8, 14, 17, 18, 26, 27, 29, 31, 34, 35, 37, 42, 44, 50, 51, 52, 57, 66, 73, 80, 87, 88, 91, 92, 94, 97, 103, 111, 114, 129, 133, 134, 138, 143, 145, 150, 151, 158, 176, 183, 198, 211, 215, 216, 217, 249, 252, 257, 260, 266, and 274.

Of these red colorants, C. I. Pigment Red 166, 177, 224, 242, and 254 are preferable, and C. I. Pigment Red 177 and 254 are particularly preferable.

Examples of the yellow pigment include C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214; and C. I. Pigment Orange 2, 5, 13, 16, 17:1, 31, 34, 36, 38, 43, 46, 48, 49, 51, 52, 55, 59, 60, 61, 62, 64, 71, and 73.

Examples of yellow dye include C. I. Acid Yellow 1, 3, 7, 9, 11, 17, 23, 25, 29, 34, 36, 42, 54, 72, 73, 76, 79, 98, 99, 111, 112, 114, 116, 184, and 243; and C. I. Food Yellow 3.

Of these yellow colorants, C. I. Pigment Yellow 139 is preferable.

The content ratio between the red colorant and the yellow colorant in a red pixel is preferably such that the transmission of light having a wavelength of 400 nm is 15% or less and the transmission of light having a wavelength of 650 nm is 90% or more in the red pixel.

In such a case, C. I. Pigment Red 254 is preferred as a red colorant.

Green Pixel

As for the spectral characteristics of a green pixel, it is preferable that the green pixel has a transmission of light having a wavelength of 450 nm of 5% or less and a transmission of light having a wavelength within the range of from 500 nm to 600 nm of 90% or more. As a colorant used for obtaining such spectral characteristics, a pigment or a dye is preferably used. Further, the pigment and dye may have any kind of chemical structure.

It is preferable that the green pixel contains at least one of a green pigment or a green dye as a green colorant and at least one of a yellow pigment or a yellow dye as a yellow colorant. It is more preferable that the green pixel contains a green pigment and a yellow pigment.

A mixture of a dye and a pigment may be used. Furthermore, as for the colorant having each color hue, one type may be used or two or more types may be used in combination.

For example, a combination of two or more types of green colorants and a yellow colorant may be used, a combination of a green colorant and two or more types of yellow colorants may be used, or a combination of two or more types of green colorants and two or more types of yellow colorants may be used.

Examples of the green pigment include C. I. Pigment Green 7, 10, 36, 37, and 58.

Examples of the green dye include C. I. Acid Green 1, 3, 5, 9, 16, 25, 27, and 50.

Of these green colorants, C. I. Pigment Green 7, 36, and 58 are preferable. C. I. Pigment Green 36 is particularly preferable.

Examples of the yellow pigment include C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214.

Examples of the yellow dye include C. I. Acid Yellow 1, 3, 7, 9, 11, 17, 23, 25, 29, 34, 36, 42, 54, 72, 73, 76, 79, 98, 99, 111, 112, 114, 116, 184, and 243; and C. I. food yellow 3.

Of these yellow colorants, C. I. Pigment Yellow 139, 150, and 185 are preferable. C. I. Pigment Yellow 150 and 185 are more preferable.

The content ratio between the green colorant and the yellow colorant in green pixels is preferably such that the transmission of light having a wavelength of 450 nm is 5% or less and the transmission of light having a wavelength within the range of from 500 nm to 600 nm is 90% or more in the green pixel.

In such a case, C. I. Pigment Green 36 is preferred as a green colorant.

Blue Pixel

As for the spectral characteristics of blue pixel, it is preferable that the blue pixel has a transmission of light having a wavelength of 450 nm of 85% or more, a transmission of light having a wavelength of 500 nm of from 10% to 50%, and a transmission of light having a wavelength of 700 nm of 10% or less. As a colorant used for obtaining such spectral characteristics, a pigment or a dye is preferably used. Further, the pigment and dye may have any kind of chemical structure.

It is preferable that a blue pixel contains at least one of a blue pigment or a blue dye as a blue colorant and at least one of a violet pigment or a violet dye as a violet colorant. It is more preferable that the blue pixel contains a blue pigment, a violet pigment, and a yellow pigment having a specific structure described below.

A mixture of a dye and a pigment may be used. Further, as for the colorant having each color hue, one type may be used or two or more types may be used in combination.

For example, a combination of two or more types of blue colorants and a violet colorant may be used, a combination of a blue colorant and two or more types of violet colorants may be used, or a combination of two or more types of blue colorants and two or more types of violet colorants may be used.

Examples of the blue pigment include C. I. Pigment Blue 1, 2, 15, 15:1, 15:2, 15:3, 15:4, 15:6, 16, 22, 60, 64, 66, 79, and 80.

Examples of the blue dye include C. I. Acid Blue 1, 7, 9, 15, 18, 23, 25, 27, 29, 40 to 45, 62, 70, 74, 80, 83, 86, 87, 90, 92, 103, 112, 113, 120, 129, 138, 147, 158, 171, 182, 192, 243, and 324:1.

Of these blue colorants, C. I. Pigment Blue 15:3 and 15:6 are preferable. C. I. Pigment Blue 15:6 is particularly preferable.

Examples of the violet pigment include C. I. Pigment Violet 1, 19, 23, 27, 32, 37, and 42.

Examples of the violet dye include C. I. Acid Violet 6B, 7, 9, 17, and 19, and C. I. Acid chrome Violet K3.

As for the violet pigment, a dipyrromethene pigment represented by Formula (M) described below is still more preferable.

The content ratio between the blue colorant and the violet colorant in a blue pixel is preferably such that the transmission of light at 450 nm is 85% or more, the transmission of light at 500 nm is from 10% to 50%, and the transmission of light at 700 nm is 10% or less in the blue pixel.

In such a case, C. I. Pigment Blue 15:6 is preferred as a blue colorant.

Dipyrromethene Pigment Represented by Formula (M) (Specific Dye)

In the invention, the blue pixel preferably contains a dipyrromethene pigment represented by Formula (M) below (hereinbelow, may be appropriately referred to as a “specific dye”).

The specific dye may be the dipyrromethene pigment represented by Formula (M), and the specific dye contains a structure derived from a dipyrromethene metal complex compound obtained from the compound of Formula (M) and a metal or a metallic compound, or a tautomer thereof.

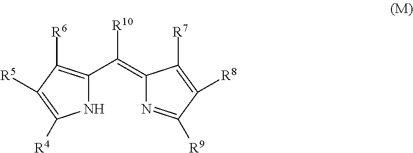

In Formula (M), R⁴ to R¹⁰ each independently represent a hydrogen atom or a monovalent substituent group, provided that R⁴ and R⁹ do not bind to each other to form a ring.

Examples of the dipyrromethene metal complex compound which is obtained from the dipyrromethene compound represented by Formula (M) and a metal or metallic compound, or a tautomer thereof include the dipyrromethene metal complex compound represented by Formula (5) or (6) shown below.

However, the invention is not limited to them.

Dipyrromethene Metal Complex Compound Represented by Formula (5)

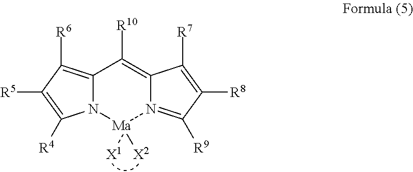

In Formula (5), R⁴ to R⁹ each independently represent a hydrogen atom or a substituent group; R¹⁰ represents a hydrogen atom, a halogen atom, an alkyl group, an aryl group, or a heterocyclic group; Ma represents a metal atom or a metal compound; X¹ represents a group capable of being bonded to Ma; X² represents a group that neutralizes the electric charge of Ma; X¹ and X² may bind to each other to form a 5-membered, 6-membered, or 7-membered ring with Ma, with the proviso that R⁴ and R⁹ do not bind to each other to form a ring. Further, the dipyrromethene metal complex compound represented by Formula (5) includes a tautomer.

The sites on the dipyrromethene metal complex compound represented by Formula (5) from which 1 to 2 hydrogen atoms are released to form a pigment residue is not specifically limited. However, from the viewpoint of synthetic suitability, any 1 or 2 sites on R⁴ to R⁹ are preferable, any 1 or 2 sites on R⁴, R⁶, R⁷ and R⁹ are more preferable, and any 1 or 2 sites on R⁴ and R⁹ are still more preferable.

The specific dye in the invention preferably has an alkali-soluble group.

When a pigment monomer or structural unit having an alkali-soluble group is used in a method for introducing an alkali group to the specific dye, an alkali-soluble group may be introduced to any 1 or 2 substituent groups of R⁴ to R¹⁰, X¹ and X² of the dipyrromethene metal complex compound represented by Formula (5). Among these substituent groups, any one of R⁴ to R⁹ and X¹ is preferable, any one of R⁴, R⁶, R⁷ and R⁹ is more preferable, and any one of R⁴ and R⁹ is still more preferable.

The dipyrromethene metal complex compound represented by Formula (5) may have a functional group other than the alkali-soluble group, as long as the effect of the invention is not impaired.

Examples of R⁴ to R⁹ include: a halogen atom (for example, fluorine, chlorine, or bromine); an alkyl group such as a linear, branched, or cyclic alkyl group having preferably 1 to 48 carbon atoms and more preferably 1 to 24 carbon atoms, examples thereof including a methyl group, an ethyl group, a propyl group, an isopropyl group, a butyl group, a t-butyl group, a pentyl group, a hexyl group, a heptyl group, an octyl group, a 2-ethylhexyl group, a dodecyl group, a hexadecyl group, a cyclopropyl group, a cyclopentyl group, a cyclohexyl group, a 1-norbornyl group, and a 1-adamantyl group; an alkenyl group such as an alkenyl group having preferably 2 to 48 carbon atoms, and more preferably 2 to 18 carbon atoms, examples thereof including a vinyl group, an allyl group, and a 3-buten-1-yl group; an aryl group such as an aryl group having preferably 6 to 48 carbon atoms and more preferably 6 to 24 carbon atoms, examples thereof including a phenyl group and a naphthyl group; a heterocyclic group such as a heterocyclic group having preferably 1 to 32 carbon atoms and more preferably 1 to 18 carbon atoms, examples thereof including a 2-thienyl group, a 4-pyridyl group, a 2-furyl group, a 2-pyrimidinyl group, a 1-pyridyl group, a 2-benzothiazolyl group, a 1-imidazolyl group, a 1-pyrazolyl group, and a benzotriazol-1-yl group; a silyl group such as a silyl group having preferably 3 to 38 carbon atoms and more preferably 3 to 18 carbon atoms, examples thereof including a trimethylsilyl group, a triethylsilyl group, a tributylsilyl group, a t-butyldimethylsilyl group, and a t-hexyldimethylsilyl group; a hydroxyl group; a cyano group; a nitro group; an alkoxy group such as an alkoxy group having preferably 1 to 48 carbon atoms and more preferably 1 to 24 carbon atoms, examples thereof including a methoxy group, an ethoxy group, a 1-butoxy group, a 2-butoxy group, an isopropoxy group, a t-butoxy group, a dodecyloxy group, and a cycloalkyloxy group such as a cyclopentyloxy group or a cyclohexyloxy group; an aryloxy group such as an aryloxy group having preferably 6 to 48 carbon atoms and more preferably 6 to 24 carbon atoms, examples thereof including a phenoxy group and a 1-naphthoxy group; a heterocyclic oxy group such as a heterocyclic oxy group having preferably 1 to 32 carbon atoms and more preferably 1 to 18 carbon atoms, examples thereof including a 1-phenyltetrazol-5-oxy group and a 2-tetrahydropyranyloxy group; a silyloxy group such as a silyloxy group having preferably 1 to 32 carbon atoms and more preferably 1 to 18 carbon atoms, examples thereof including a trimethylsilyloxy group, a t-butyldimethylsilyloxy group, and a diphenylmethylsilyloxy group; an acyloxy group such as a acyloxy group having preferably 2 to 48 carbon atoms and more preferably 2 to 24 carbon atoms, examples thereof including an acetoxy group, a pyvaloyloxy group, a benzoyloxy group, and a dodecanoyloxy group; an alkoxycarbonyl oxy group such as an alkoxycarbonyl oxy group having preferably 2 to 48 carbon atoms and more preferably 2 to 24 carbon atoms, examples thereof including an ethoxycarbonyl oxy group, a t-butoxycarbonyl oxy group, and a cycloalkyloxycarbonyl oxy group such as a cyclohexyl oxycarbonyloxy group; an aryloxycarbonyloxy group such as an aryloxycarbonyloxy group having preferably 7 to 32 carbon atoms and more preferably 7 to 24 carbon atoms, examples thereof including a phenoxycarbonyloxy group; a carbamoyloxy group such as a carbamoyl oxy group having preferably 1 to 48 carbon atoms and more preferably 1 to 24 carbon atoms, examples thereof including a N,N-dimethyl carbamoyloxy group, a N-butyl carbamoyloxy group, a N-phenyl carbamoyloxy group, and a N-ethyl-N-phenyl carbamoyloxy group; a sulfamoyloxy group such as a sulfamoyloxy group having preferably 1 to 32 carbon atoms and more preferably 1 to 24 carbon atoms, examples thereof including a N,N-diethyl sulfamoyloxy group and a N-propyl sulfamoyloxy group; an alkylsulfonyloxy group such as an alkylsulfonyloxy group having preferably 1 to 38 carbon atoms and more preferably 1 to 24 carbon atoms, examples thereof including a methyl sulfonyloxy group, a hexadecyl sulfonyloxy group, and a cyclohexyl sulfonyloxy group;
an aryl sulfonyloxy group such as an aryl sulfonyloxy group having preferably 6 to 32 carbon atoms and more preferably 6 to 24 carbon atoms, examples thereof including a phenylsulfonyloxy group; an acyl group such as an acyl group having preferably 1 to 48 carbon atoms and more preferably 1 to 24 carbon atoms, examples thereof including a formyl group, an acetyl group, a pyvaloyl group, a benzoyl group, a tetradecanoyl group, and a cyclohexanoyl group; an alkoxycarbonyl group such as an alkoxycarbonyl group having preferably 2 to 48 carbon atoms and more preferably 2 to 24 carbon atoms, examples thereof including a methoxycarbonyl group, an ethoxycarbonyl group, an octadecyloxycarbonyl group, a cyclohexyloxycarbonyl group, and a 2,6-di-tert-butyl-4-methylcyclohexyloxy carbonyl group; an aryloxycarbonyl group such as an aryloxycarbonyl group having preferably 7 to 32 carbon atoms and more preferably 7 to 24 carbon atoms, examples thereof including a phenoxycarbonyl group; a carbamoyl group such as a carbamoyl group having preferably 1 to 48 carbon atoms and more preferably 1 to 24 carbon atoms, examples thereof including a carbamoyl group, a N,N-diethyl carbamoyl group, a N-ethyl-N-octyl carbamoyl group, a N,N-dibutyl carbamoyl group, a N-propyl carbamoyl group, a N-phenyl carbamoyl group, a N-methyl-N-phenyl carbamoyl group, and a N,N-dicyclohexyl carbamoyl group; an amino group such as an amino group having preferably 32 or less carbon atoms and more preferably 24 or less carbon atoms, examples thereof including an amino group, a methylamino group, a N,N-dibutyl amino group, a tetradecyl amino group, a 2-ethylhexyl amino group, and a cyclohexyl amino group; an anilino group such as an anilino group having preferably 6 to 32 carbon atoms and more preferably 6 to 24 carbon atoms, examples thereof including an anilino group and a N-methylanilino group; a heterocyclic amino group such as a heterocyclic amino group having preferably 1 to 32 carbon atoms and more preferably 1 to 18 carbon atoms, examples thereof including a 4-pyridylamino group; a carbonamide group such as a carbonamide group having preferably 2 to 48 carbon atoms and more preferably 2 to 24 carbon atoms, examples thereof including an acetamide group, a benzamide group, a tetradecanamide group, a pyvaloyl amide group, and a cyclohexane amide group; a ureido group such as a ureido group having preferably 1 to 32 carbon atoms and more preferably 1 to 24 carbon atoms, examples thereof including a ureido group, a N,N-dimethylureido group, and a N-phenylureido group; an imide group such as an imide group having preferably 36 or less carbon atoms and more preferably 24 or less carbon atoms, examples thereof including a N-succinimide group and a N-phthalimide group; an alkoxycarbonyl amino group such as an alkoxycarbonyl amino group having preferably 2 to 48 carbon atoms and more preferably 2 to 24 carbon atoms, examples thereof including a methoxycarbonyl amino group, an ethoxycarbonyl amino group, a t-butoxycarbonylamino group, an octadecyl oxycarbonyl amino group, and a cyclohexyl oxycarbonyl amino group; an aryloxy carbonylamino group such as an aryloxy carbonylamino group having preferably 7 to 32 carbon atoms and more preferably 7 to 24 carbon atoms, examples thereof including a phenoxy carbonylamino group; a sulfonamide group such as a sulfonamide group having preferably 1 to 48 carbon atoms and more preferably 1 to 24 carbon atoms, examples thereof including a methane sulfonamide group, a butane sulfonamide group, a benzene sulfonamide group, a hexadecane sulfonamide group, and a cyclohexane sulfonamide group; a sulfamoyl amino group such as a sulfamoyl amino group having preferably 1 to 48 carbon atoms and more preferably 1 to 24 carbon atoms, examples thereof including a N,N-dipropyl sulfamoyl amino group and a N-ethyl-N-dodecyl sulfamoyl amino group; an azo group such as an azo group having preferably 1 to 32 carbon atoms and more preferably 1 to 24 carbon atoms, examples thereof including a phenyl azo group and a 3-pyrazolyl azo group;
an alkylthio group such as an alkylthio group having preferably 1 to 48 carbon atoms and more preferably 1 to 24 carbon atoms, examples thereof including a methylthio group, an ethylthio group, an octylthio group, and a cyclohexylthio group; an arylthio group such as an arylthio group having preferably 6 to 48 carbon atoms and more preferably 6 to 24 carbon atoms, examples thereof including a phenylthio group; a heterocyclic thio group such as a heterocyclic thio group having preferably 1 to 32 carbon atoms and more preferably 1 to 18 carbon atoms, examples thereof including a 2-benzothiazolylthio group, a 2-pyridylthio group, and a 1-phenyltetrazolylthio group; an alkylsulfinyl group such as an alkylsulfinyl group having preferably 1 to 32 carbon atoms and more preferably 1 to 24 carbon atoms, examples thereof including a dodecanesulfinyl group; an arylsulfinyl group such as an arylsulfinyl group having preferably 6 to 32 carbon atoms and more preferably 6 to 24 carbon atoms, examples thereof including a phenylsulfinyl group; an alkylsulfonyl group such as an alkylsulfonyl group having preferably 1 to 48 carbon atoms and more preferably 1 to 24 carbon atoms, examples thereof including a methylsulfonyl group, an ethylsulfonyl group, a propylsulfonyl group, a butylsulfonyl group, an isopropyl sulfonyl group, a 2-ethylhexyl sulfonyl group, a hexadecyl sulfonyl group, an octyl sulfonyl group, and a cyclohexyl sulfonyl group; an arylsulfonyl group such as an arylsulfonyl group having preferably 6 to 48 carbon atoms and more preferably 6 to 24 carbon atoms, examples thereof including a phenylsulfonyl group and a 1-naphthyl sulfonyl group; a sulfamoyl group such as a sulfamoyl group having preferably 32 or less carbon atoms and more preferably 24 or less carbon atoms, examples thereof including a sulfamoyl group, a N,N-dipropylsulfamoyl group, a N-ethyl-N-dodecylsulfamoyl group, a N-ethyl-N-phenylsulfamoyl group, and a N-cyclohexylsulfamoyl group; a sulfo group; a phosphonyl group such as a phosphonyl group having preferably 1 to 32 carbon atoms and more preferably 1 to 24 carbon atoms, examples thereof including a phenoxyphosphonyl group, an octyloxyphosphonyl group, and a phenylphosphonyl group; and a phosphinoyl amino group such as a phosphinoyl amino group having preferably 1 to 32 carbon atoms and more preferably 1 to 24 carbon atoms, examples thereof including a diethoxyphosphinoylamino group and a dioctyloxyphosphinoylamino group.

Among those described above, R⁴ and R⁹ is each preferably an alkylamino group, an arylamino group, a carbonamide group, a ureido group, an imide group, an alkoxycarbonyl amino group, or a sulfonamide group, R⁴ and R⁹ is each more preferably a carbonamide group, a ureido group, an alkoxycarbonyl amino group, or a sulfonamide group, R⁴ and R⁹ is each still more preferably a carbonamide group, a ureido group, an alkoxycarbonyl amino group, or a sulfonamide group, and R⁴ and R⁹ is each even more preferably a carbonamide group or a ureido group.

Among those described above, R⁵ and R⁸ is each preferably an alkoxycarbonyl group, an aryloxy carbonyl group, a carbamoyl group, an alkylsulfonyl group, an aryl sulfonyl group, a nitrile group, an imide group, or a carbamoyl sulfonyl group, R⁵ and R⁸ is each more preferably an alkoxycarbonyl group, an aryloxy carbonyl group, a carbamoyl group, an alkylsulfonyl group, a nitrile group, an imide group, or a carbamoyl sulfonyl group, R⁵ and R⁸ is each still more preferably an alkoxycarbonyl group, an aryloxy carbonyl group, a carbamoyl group, a nitrile group, an imide group, or a carbamoyl sulfonyl group, and R⁵ and R⁸ is each even more preferably an alkoxycarbonyl group, an aryloxy carbonyl group, or a carbamoyl group.

Among those described above, R⁶ and R⁷ is each preferably a substituted or unsubstituted alkyl group, a substituted or unsubstituted aryl group, or a substituted or unsubstituted heterocyclic group, and R⁶ and R⁷ is each more preferably a substituted or unsubstituted alkyl group or a substituted or an unsubstituted aryl group.

When R⁶ or R⁷ represents an alkyl group, the alkyl group is preferably a linear, branched, or cyclic, substituted or unsubstituted alkyl group having 1 to 12 carbon atoms, and specific examples thereof include a methyl group, an ethyl group, a n-propyl group, an isopropyl group, a cyclopropyl group, a n-butyl group, an i-butyl group, a t-butyl group, a cyclobutyl group, a cyclopentyl group, a cyclohexyl group, and a benzyl group. More preferably, the alkyl group represented by R⁶ or R⁷ is a branched or cyclic, substituted or unsubstituted alkyl group having 1 to 12 carbon atoms, and specific examples thereof include an isopropyl group, a cyclopropyl group, an i-butyl group, a t-butyl group, a cyclobutyl group, a cyclopentyl group, and a cyclohexyl group. Still more preferably, the alkyl group represented by R⁶ or R⁷ is a secondary or tertiary, substituted or unsubstituted alkyl group having 1 to 12 carbon atoms, and specific examples thereof include an isopropyl group, a cyclopropyl group, an i-butyl group, a t-butyl group, a cyclobutyl group, and a cyclohexyl group.

When R⁶ or R⁷ represents an aryl group, the aryl group is preferably a substituted or unsubstituted phenyl group or a substituted or unsubstituted naphthyl group, and more preferably a substituted or unsubstituted phenyl group.

When R⁶ or R⁷ represents a heterocyclic group, the heterocyclic group is preferably a substituted or unsubstituted 2-thienyl group, a substituted or unsubstituted 4-pyridyl group, a substituted or unsubstituted 3-pyridyl group, a substituted or unsubstituted 2-pyridyl group, a substituted or unsubstituted 2-furyl group, a substituted or unsubstituted 2-pyrimidinyl group, a substituted or unsubstituted 2-benzothiazolyl group, a substituted or unsubstituted 1-imidazolyl group, a substituted or unsubstituted 1-pyrazolyl group, or a substituted or unsubstituted benzotriazol-1-yl group, and more preferably a substituted or unsubstituted 2-thienyl group, a substituted or unsubstituted 4-pyridyl group, a substituted or unsubstituted 2-furyl group, a substituted or unsubstituted 2-pyrimidinyl group, or a substituted or unsubstituted 1-pyridyl group.

In Formula (5), Ma represents a metal atom or a metal compound. The metal atom or the metal compound may be any metal atom or any metal compound as long as it is capable of forming a complex, and examples thereof include a divalent metal atom, a divalent metal oxide, a divalent metal hydroxide, and a divalent metal chloride.

Examples thereof include Zn, Mg, Si, Sn, Rh, Pt, Pd, Mo, Mn, Pb, Cu, Ni, Co, Fe or the like, metal chlorides such as AlCl, InCl, FeCl, TiCl₂, SnCl₂, SiCl₂, and GeCl₂, metal oxides such as TiO and VO, and metal hydroxides such as Si(OH)₂.

Among these, from the viewpoints of stability, spectral characteristics, heat resistance, light resistance or production suitability of the complex, the metal atom or metal complex is preferably Fe, Zn, Mg, Si, Pt, Pd, Mo, Mn, Cu, Ni, Co, TiO or VO, more preferably Zn, Mg, Si, Pt, Pd, Cu, Ni, Co or VO, still more preferably Zn, Cu, Co or VO, and most preferably Zn.

In Formula (5), R¹⁰ represents a hydrogen atom, a halogen atom, an alkyl group, an aryl group, or a heterocyclic group, and preferably a hydrogen atom.

In Formula (5), X¹ may be any group as long as it is capable of being bonded to Ma. Specific examples thereof include water, alcohols (for example, methanol, ethanol and propanol) and the compounds described in “Metal Chelates” ([1] written by Sakaguchi Takeichi and Ueno Keihei (1995, Nankodo Co., Ltd.), [2] (1996) and [3] (1997), etc.). Among these, from the view point of producibility, water, carboxylic acid compounds and alcohols are preferable, and water and carboxylic acid compounds are more preferable.

In Formula (5), examples of the “group that neutralizes the electric charge of Ma” represented by X² include a halogen atom, a hydroxyl group, a carboxylic acid group, a phosphoric acid group, and a sulfonic acid group. Of these, from the viewpoint of production, a halogen atom, a hydroxyl group, a carboxylic acid group, and a sulfonic acid group are preferable, a hydroxyl group and a carboxylic acid group are more preferable.

In Formula (5), X¹ and X² may bind to each other to form a 5-membered, 6-membered, or 7-membered ring with Ma. The 5-membered, 6-membered, or 7-membered ring to be formed may be either a saturated ring or an unsaturated ring. Further, the ring of the 5-membered, 6-membered, or 7-membered ring may consists of a carbon atom only, or may form a heterocycle which has at least one atom selected from a nitrogen atom, an oxygen atom and/or a sulfur atom.

In preferred embodiments of the compound represented by Formula (5), R⁴ to R⁹ each independently represent the atom or group mentioned in the preferred embodiments of R⁴ to R⁹ described above, R¹⁰ represents the atom or group mentioned in the preferred embodiments of R¹⁰ described above, Ma is Zn, Cu, Co, or VO, X¹ is water or a carboxylic acid compound, X² is a hydroxyl group or a carboxylic acid group, and X¹ and X² may bind to each other to form a 5-membered or a 6-membered ring.

Dipyrromethene Metal Complex Compound Represented by Formula (6)

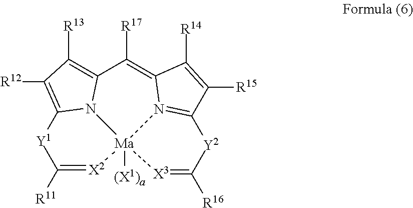

In Formula (6), R¹¹ and R¹⁶ each independently represent an alkyl group, an alkenyl group, an aryl group, a heterocyclic group, an alkoxy group, an aryloxy group, an alkylamino group, an aryl amino group, or a heterocyclic amino group; R¹² to R¹⁵ each independently represent a hydrogen atom or a substituent group; R¹⁷ represents a hydrogen atom, a halogen atom, an alkyl group, an aryl group, or a heterocyclic group; Ma represents a metal atom or a metal compound; X² and X³ each independently represent NR (in which R represents a hydrogen atom, an alkyl group, an alkenyl group, an aryl group, a heterocyclic group, an acyl group, an alkylsulfonyl group, or an aryl sulfonyl group), a nitrogen atom, an oxygen atom, or a sulfur atom; Y¹ and Y² each independently represent NR (in which R represents a hydrogen atom, an alkyl group, an alkenyl group, an aryl group, a heterocyclic group, an acyl group, an alkylsulfonyl group, or an aryl sulfonyl group), a nitrogen atom, or a carbon atom; R¹¹ and Y¹ may bind to each other to form a 5-membered, 6-membered, or 7-membered ring; and R¹⁶ and Y² may bind to each other to form a 5-membered, 6-membered, or 7-membered ring; X¹ is a group capable of being bonded to Ma; and a represents 0, 1 or 2. The dipyrromethene metal complex compound represented by Formula (6) includes a tautomer.

The sites on the dipyrromethene metal complex compound represented by Formula (6) from which 1 to 2 hydrogen atoms are released to form a pigment residue are not specifically limited, and it may be any 1 or 2 sites of R¹¹ to R¹⁷, X¹, Y¹ to Y².

However, from the viewpoint of synthetic suitability, any 1 or 2 sites on R¹¹ to R¹⁶ and X¹ are preferable, any 1 or 2 sites on R¹¹, R¹³, R¹⁴ and R¹⁶ are more preferable, and any 1 or 2 sites on R¹¹ and R¹⁶ are still more preferable.

When a pigment monomer or structural unit having an alkali-soluble group is used in a method for introducing an alkali-soluble group to the specific dye used in the invention, an alkali-soluble group may be introduced to any 1 or 2 substituent groups of R¹¹ to R¹⁷, X¹, and Y¹ to Y² of the dipyrromethene metal complex compound represented by Formula (6). Among these substituent groups, any one of R¹¹ to R¹⁶ and X¹ is preferable, any one of R¹¹, R¹³, R¹⁴ and R¹⁶ is more preferable, and any one of R¹¹ and R¹⁶ is still more preferable.

The dipyrromethene metal complex compound represented by Formula (6) may have a functional group other than the alkali-soluble group, as long as the effect of the invention is not impaired.

R¹² to R¹⁵ in Formula (6) have the same definitions as R⁵ to R⁸ in Formula (5), respectively, and the preferred embodiments thereof (including preferable examples thereof) are also the same. R¹⁷ in Formula (6) has the same definition as R¹⁰ in Formula (5), and the preferred embodiments thereof (including preferable examples thereof) are also the same. Ma in Formula (6) has the same definitions as Ma in Formula (5), and the preferred embodiments thereof (including preferable examples thereof) are also the same.

More specifically, among R¹² to R¹⁵ in Formula (6), R¹² and R¹⁵ is each preferably an alkoxycarbonyl group, an aryloxy carbonyl group, a carbamoyl group, an alkylsulfonyl group, an aryl sulfonyl group, a nitrile group, an imide group, or a carbamoyl sulfonyl group, more preferably an alkoxycarbonyl group, an aryloxy carbonyl group, a carbamoyl group, an alkylsulfonyl group, a nitrile group, an imide group, or a carbamoyl sulfonyl group, still more preferably an alkoxycarbonyl group, an aryloxy carbonyl group, a carbamoyl group, a nitrile group, an imide group, or a carbamoyl sulfonyl group, and even more preferably an alkoxycarbonyl group, an aryloxy carbonyl group, or a carbamoyl group.

R¹³ and R¹⁴ in Formula (6) is each preferably a substituted or unsubstituted alkyl group, a substituted or unsubstituted aryl group, or a substituted or unsubstituted heterocyclic group, and more preferably a substituted or unsubstituted alkyl group or a substituted or unsubstituted aryl group. Herein, the specific examples of more preferred alkyl group, aryl group, and heterocyclic group are the same as the specific examples of R⁶ and R⁷ in Formula (5) mentioned above.

R¹¹ and R¹⁶ in Formula (6) each represent: an alkyl group such as a linear, branched, or cyclic alkyl group having preferably 1 to 36 carbon atoms and more preferably 1 to 12 carbon atoms, examples thereof including a methyl group, an ethyl group, a propyl group, an isopropyl group, a butyl group, an isobutyl group, a t-butyl group, a hexyl group, a 2-ethylhexyl group, a dodecyl group, a cyclopropyl group, a cyclopentyl group, a cyclohexyl group, and a 1-adamantyl group; an alkenyl group such as an alkenyl group having preferably 2 to 24 carbon atoms and more preferably 2 to 12 carbon atoms, examples thereof including a vinyl group, an allyl group, and a 3-buten-1-yl group; an aryl group such as an aryl group having preferably 6 to 36 carbon atoms and more preferably 6 to 18 carbon atoms, examples thereof including a phenyl group and a naphthyl group; a heterocyclic group such as a heterocyclic group having preferably 1 to 24 carbon atoms and more preferably 1 to 12 carbon atoms, examples thereof including a 2-thienyl group, a 4-pyridyl group, a 2-furyl group, a 2-pyrimidinyl group, a 2-pyridyl group, a 2-benzothiazolyl group, a 1-imidazolyl group, a 1-pyrazolyl group, and a benzotriazol-1-yl group; an alkoxy group such as an alkoxy group having preferably 1 to 36 carbon atoms and more preferably 1 to 18 carbon atoms, examples thereof including a methoxy group, an ethoxy group, a propyloxy group, a butoxy group, a hexyloxy group, a 2-ethylhexyloxy group, a dodecyloxy group, and a cyclohexyloxy group; an aryloxy group such as an aryloxy group having preferably 6 to 24 carbon atoms and more preferably 6 to 18 carbon atoms, examples thereof including a phenoxy group and a naphthyloxy group; an alkylamino group such as an alkylamino group having preferably 1 to 36 carbon atoms and more preferably 1 to 18 carbon atoms, examples thereof including a methylamino group, an ethylamino group, a propylamino group, a butylamino group, a hexylamino group, a 2-ethylhexylamino group, an isopropylamino group, a t-butylamino group, a t-octylamino group, a cyclohexylamino group, a N,N-diethylamino group, a N,N-dipropylamino group, a N,N-dibutylamino group, and a N-methyl-N-ethylamino group; an aryl amino group such as an aryl amino group having preferably 6 to 36 carbon atoms and more preferably 6 to 18 carbon atoms, examples thereof including a phenylamino group, a naphthylamino group, a N,N-diphenyl amino group, and a N-ethyl-N-phenylamino group; and a heterocyclic amino group such as a heterocyclic amino group having preferably 1 to 24 carbon atoms and more preferably 1 to 12 carbon atoms, examples thereof including a 2-aminopyrrole group, a 3-aminopyrazole group, a 2-aminopyridine group, and a 3-aminopyridine group.

Of those described above, R¹¹ and R¹⁶ each is preferably an alkyl group, an alkenyl group, an aryl group, a heterocyclic group, an alkylamino group, an aryl amino group, or a heterocyclic amino group, R¹¹ and R¹⁶ each is more preferably an alkyl group, an alkenyl group, an aryl group, or a heterocyclic group, R¹¹ and R¹⁶ each is still more preferably an alkyl group, an alkenyl group, or an aryl group, and R¹¹ and R¹⁶ each is even more preferably an alkyl group.

In Formula (6), when an alkyl group, an alkenyl group, an aryl group, a heterocyclic group, an alkoxy group, an aryloxy group, an alkylamino group, an aryl amino group, or a heterocyclic amino group represented by R¹¹ or R¹⁶ is a group capable of being further substituted, it may be substituted with a substituent group that is described below with regard to the substituent group for R¹ in Formula (1). When it is substituted with two or more substituent groups, the substituent groups may be the same as or different from each other.

In Formula (6), X² and X³ each independently represent NR, a nitrogen atom, an oxygen atom, or a sulfur atom. As used herein, R represents a hydrogen atom; an alkyl group such as a linear, branched, or cyclic alkyl group having preferably 1 to 36 carbon atoms and more preferably 1 to 12 carbon atoms, examples thereof including a methyl group, an ethyl group, a propyl group, an isopropyl group, a butyl group, an isobutyl group, a t-butyl group, a hexyl group, a 2-ethylhexyl group, a dodecyl group, a cyclopropyl group, a cyclopentyl group, a cyclohexyl group, and a 1-adamantyl group; an alkenyl group such as a alkenyl group having preferably 2 to 24 carbon atoms and more preferably 2 to 12 carbon atoms, examples thereof including a vinyl group, an allyl group, and a 3-buten-1-yl group; an aryl group such as an aryl group having preferably 6 to 36 carbon atoms and more preferably 6 to 18 carbon atoms, examples thereof including a phenyl group and a naphthyl group; a heterocyclic group such as a heterocyclic group having preferably 1 to 24 carbon atoms and more preferably 1 to 12 carbon atoms, examples thereof including a 2-thienyl group, a 4-pyridyl group, a 2-furyl group, a 2-pyrimidinyl group, a 1-pyridyl group, a 2-benzothiazolyl group, a 1-imidazolyl group, a 1-pyrazolyl group, and a benzotriazol-1-yl group; an acyl group such as an acyl group having preferably 1 to 24 carbon atoms and more preferably 2 to 18 carbon atoms, examples thereof including an acetyl group, a pyvaloyl group, a 2-ethylhexyl group, a benzoyl group, and a cyclohexanoyl group; an alkylsulfonyl group such as an alkylsulfonyl group having preferably 1 to 24 carbon atoms and more preferably 1 to 18 carbon atoms, examples thereof including a methylsulfonyl group, an ethylsulfonyl group, an isopropylsulfonyl group, and a cyclohexylsulfonyl group; an arylsulfonyl group such as an arylsulfonyl group having preferably 6 to 24 carbon atoms and more preferably 6 to 18 carbon atoms, examples thereof including a phenylsulfonyl group and a naphthylsulfonyl group.

An alkyl group, an alkenyl group, an aryl group, a heterocyclic group, an acyl group, an alkylsulfonyl group, or an aryl sulfonyl group represented by R may be substituted with a substituent group that is described below with regard to the substituent group for R¹ in Formula (1). When it is substituted with two or more substituent groups, the substituent groups may be the same as or different from each other.

In Formula (6), Y¹ and Y² each independently represent NR, a nitrogen atom, or a carbon atom, and R has the same definition as R of X² or X³ described above, and the preferred embodiments thereof (including the preferred examples thereof) are also the same.

In Formula (6), R¹¹ and Y¹ may bind to each other to form a 5-membered ring (for example, cyclopentane, pyrrolidine, tetrahydrofuran, dioxolane, tetrahydrothiophene, pyrrole, furan, thiophene, indole, benzofuran, or benzothiophene), a 6-membered ring (for example, cyclohexane, piperidine, piperazine, morpholine, tetrahydropyran, dioxane, pentamethylene sulfide, dithiane, benzene, piperidine, piperazine, pyridazine, quinoline, or quinazoline), or a 7-membered ring (for example, cycloheptane or hexamethylene imine), together with carbon atoms.

In Formula (6), R¹⁶ and Y² may bind to each other to form a 5-membered ring (for example, cyclopentane, pyrrolidine, tetrahydrofuran, dioxolane, tetrahydrothiophene, pyrrole, furan, thiophene, indole, benzo furan, and benzo thiophene), a 6-membered ring (for example, cyclohexane, piperidine, piperazine, morpholine, tetrahydro pyran, dioxane, pentamethylene sulfide, dithiane, benzene, piperidine, piperazine, pyridazine, quinoline, and quinazoline), or a 7-membered ring (for example, cycloheptane and hexamethylene imine) together with the carbon atom.

In Formula (6), when the 5-membered, 6-membered, or 7-membered ring that is formed by binding between R¹¹ and Y¹ or R¹⁶ and Y² is a ring which may be substituted, it may be substituted with a substituent group that is described below with regard to the substituent group for R¹ in Formula (1). When it is substituted with two or more substituent groups, the substituent groups may be the same as or different from each other.

In Formula (6), X¹ is a group capable of being bonded to Ma. Specific examples thereof include the same groups represented by X¹ in Formula (5), and preferred embodiments thereof (including preferred examples thereof) are also the same. In Formula (6), a represents 0, 1 or 2.

In preferred embodiments of the compound represented by Formula (6), R¹² to R¹⁵ each independently represent the atom or group mentioned in the preferred embodiments of R⁵ to R⁸ in Formula (5) above, R¹⁷ represents the atom or group mentioned in the preferred embodiments of R¹⁰ in Formula (5) above, Ma is Zn, Cu, Co, or VO, X² is NR (in which R represents a hydrogen atom or an alkyl group), a nitrogen atom, or an oxygen atom, X³ is NR (in which R represents a hydrogen atom or an alkyl group) or an oxygen atom, Y¹ is NR (in which R represents a hydrogen atom, or an alkyl group), a nitrogen atom, or a carbon atom, Y² is a nitrogen atom or a carbon atom, R¹¹ and R¹⁶ each independently are an alkyl group, an aryl group, a heterocyclic group, an alkoxy group, or an alkylamino group, X¹ is a group which is bonded to Ma via an oxygen atom, and a is 0 or 1. R¹¹ and Y¹ may bind to each other to form a 5-membered or a 6-membered ring, or R¹⁶ and Y² may bind to each other to form a 5-membered or a 6-membered ring.

In more preferred embodiments of the compound represented by Formula (6), R¹² to R¹⁵ each independently represent the atom or group mentioned in the preferred embodiments of R⁵ to R⁸ for the compound represented by Formula (5), R¹⁷ represents the atom or group mentioned in the preferred embodiments of R¹⁰ in Formula (5), Ma is Zn, X² and X³ each are an oxygen atom, Y¹ is NH, Y² is a nitrogen atom, R¹¹ and R¹⁶ each independently are an alkyl group, an aryl group, a heterocyclic group, an alkoxy group, or an alkylamino group, X¹ is a group which is bonded to Ma via an oxygen atom, and a is 0 or 1. R¹¹ and Y¹ may bind to each other to form a 5-membered or a 6-membered ring, or R¹⁶ and Y² may bind to each other to form a 5-membered or a 6-membered ring.

From the viewpoint of the film thickness, the molar absorption coefficient of the dipyrromethene metal complex compound represented by Formula (5) or Formula (6) is preferably as high as possible. From the viewpoint of improving the color purity, the maximum absorption wavelength λmax is preferably from 520 nm to 580 nm, more preferably from 530 nm to 570 nm. The maximum absorption wavelength and the molar absorption coefficient are measured by using a spectrophotometer UV-2400PC (trade name, manufactured by SHIMADZU CORPORATION).

From the viewpoint of solubility, the melting point of the dipyrromethene metal complex compound represented by Formula (5) or (6) is preferably not too high.

The dipyrromethene metal complex compound represented by Formula (5) or (6) may be synthesized according to the method described in U.S. Pat. No. 4,774,339, U.S. Pat. No. 5,433,896, Japanese Patent Application Laid-Open (JP-A) No. 2001-240761, JP-A No. 2002-155052, Japanese Patent No. 3614586, Aust. J. Chem, 1965, 11, 1835-1845, or J. H. Boger et al, Heteroatom Chemistry, Vol. 1, No. 5, 389 (1990). Specifically, the method described in paragraph No. 0131 to 0157 of JP-A No. 2008-292970 may be used in the invention.

The specific dye of the invention is preferably a pigment multimer including a dipyrromethene structure. The pigment moiety in the pigment multimer including a dipyrromethene structure preferably has a structure derived from a dipyrromethene metal complex compound or a tautomer thereof, which are obtained from a dipyrromethene compound represented by Formula (M) and a metal or a metal compound.

Furthermore, the dipyrromethene metal complex compound or tautomer thereof, which are obtained from a dipyrromethene compound represented by Formula (M) and a metal or a metal compound, is preferably a dipyrromethene metal complex compound that is represented by Formula (5) or (6) described above.

The pigment multimer is described herein below.

The specific dye in the invention is preferably a pigment multimer having a dipyrromethene structure, and the weight average molecular weight (Mw) thereof is from 5,000 to 20,000, more preferably from 5,000 to 16,000, and still more preferably from 6,000 to 12,000.

When the weight average molecular weight (Mw) is less than 5,000, color transfer of a colorant caused by heat treatment, smearing of a colorant, alkali dissolution resistance, and solvent resistance tend to get deteriorated when a blue pixel is prepared using the dye. On the other hand, when the weight average molecular weight is more than 20,000, development residues are increased, in particular.

The dispersity (Mw/Mn) of the pigment multimer is preferably from 1.00 to 2.50.

When the dispersity (Mw/Mn) is more than 2.50, color transfer of a colorant caused by heat treatment, smearing of a colorant, alkali dissolution resistance, and solvent resistance tend to get deteriorated when a colored film is produced. It is necessary that the dispersity (Mw/Mn) is from 1.00 to 2.50. Preferably, it is from 1.00 to 2.20 and more preferably from 1.00 to 2.00.

Further, the weight average molecular weight and molecular weight distribution indicate the values that are measured by gel permeation chromatography (GPC) using HLC-8220GPC (trade name, manufactured by Tosoh corporation) (development solvent; NMP, detection; RI, and calculated in terms of polystyrene).

The specific dye of the invention preferably contains an alkali-soluble group.

Examples of the alkali soluble group include a carboxyl group, a phosphono group, and a sulfo group. Of these, a carboxyl group is preferable.

From the viewpoint of suitable use in photolithography described below, the acid value of the specific dye is preferably from 0.5 mmol/g to 3.0 mmol/g, more preferably from 0.6 mmol/g to 2.5 mmol/g, and still more preferably from 0.7 mmol/g to 2.0 mmol/g.

Examples of the specific dye of the invention include a dimer, a trimer, an oligomer, and a polymer.

When the pigment multimer is synthesized by a copolymerization reaction, a polymerizable monomer (comonomer) other than those mentioned above is not specifically limited as long as it is polymerizable with the polymerizable pigment monomer.

Examples of the comonomer include a styrene compound, a carboxylic acid monomer and an ester, amide, imide or anhydride thereof, and a vinyl compound.

Examples of the styrene compound include styrene, α-methylstyrene, hydroxy styrene, p-chloromethyl styrene, and m-chloromethyl styrene.

Examples of α,β-unsaturated carboxylic acid include acrylic acid, methacrylic acid, maleic acid, fumaric acid, itaconic acid, citraconic acid, mesaconic acid, and 1-butyne-2,3,4-tricarboxylic acid.

Examples of the ester of unsaturated carboxylic acid include methyl ester, ethyl ester, 2-hydroxyethyl ester, propyl ester, butyl ester, octyl ester, dodecyl ester, 2,2,6,6-tetramethyl-4-piperidyl ester, 1,2,2,6,6-pentamethyl-4-piperidyl ester, and 2-[3-(2-benzo triazolyl)-4-hydroxyphenyl]ethyl ester of the α,β-unsaturated carboxylic acid.

Examples of the amide of unsaturated carboxylic acid include methyl amide, dimethyl amide, ethyl amide, diethylamide, propyl amide, dipropyl amide, butyl amide, dibutyl amide, hexylamide, octyl amide, and phenyl amide of the α,β-unsaturated carboxylic acid.

Examples of the imide of unsaturated carboxylic acid include maleimide, itaconeimide, N-butyl maleimide, N-octyl maleimide, and N-phenyl maleimide. Examples of the vinyl compound include vinyl acetate, N-vinyl carbazole, and N-vinyl pyrrolidone.

The copolymerization ratio between the polymerizable pigment monomer and comonomer varies depending on the type of the polymerizable pigment monomer. However, the comonomer is present at the proportion of from 5 g to 10,000 g, more preferably from 5 g to 1,000 g, and still more preferably from 5 g to 100 g, with respect to 100 g of the polymerizable pigment monomer.

The specific dye in the invention is preferably a pigment multimer which has at least one structural unit represented by Formula (A), (B), or (C), or contains the dipyrromethene structure represented by Formula (D).

Structural Unit Represented by Formula (A)

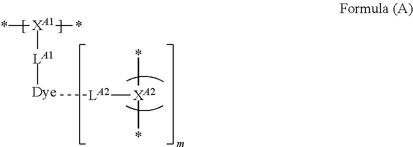

In Formula (A), X^{A1} represents a linking group formed by polymerization; L^{A1} represents a single bond or a divalent linking group; Dye represents a pigment residue that is obtained by removing one to 1+m hydrogen atoms from a pigment compound having the dipyrromethene structure; X^{A2} represents a linking group formed by polymerization; L^{A2} represents a single bond or a divalent linking group; m represents an integer from 0 to 3; and when m is 2 or more, the structures within [ ] may be the same as or different from each other. Dye and L^{A2} may be linked to each other via any one of a covalent bond, an ionic bond, and a coordination bond.

In Formula (A), X^{A1} and X^{A2} each independently represent a linking group formed by polymerization. Specifically, X^{A1} and X^{A2} each indicate a moiety that forms a repeating unit which corresponds to the main chain formed by a polymerization reaction. Further, the moieties shown between two * each correspond to a repeating unit.

Examples of X^{A1} and X^{A2} include, each independently, a linking group formed by polymerization of a substituted or unsubstituted, unsaturated ethylene group and a linking group formed by ring-opening polymerization of a cyclic ether. Preferably, it is a linking group formed by polymerization of an unsaturated ethylene group. Specific examples thereof include the linking groups (X-1) to (X-15) shown below. However, the linking group formed by polymerization in the invention is not limited to them.

In the following (X-1) to (X-15), the site indicated by * represents linking to L^{A1} or L^{A2}.

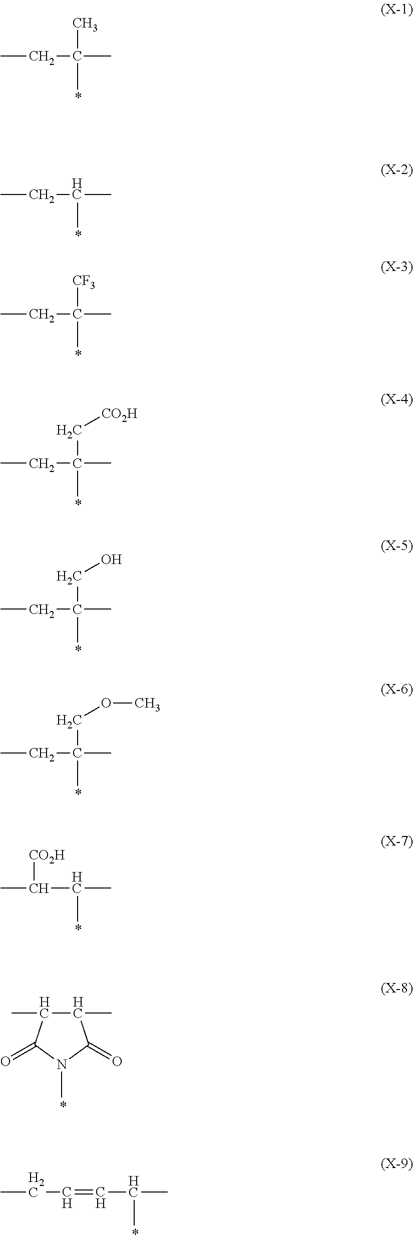

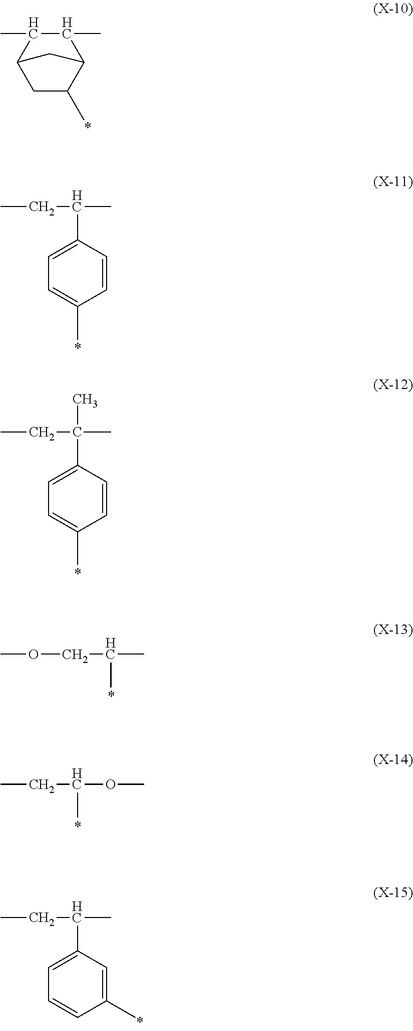

In Formula (A), L^{A1} and L^{A2} each independently represent a single bond or a divalent linking group. L^{A1} and L^{A2} each independently represent a substituted or unsubstituted linear, branched, or cyclic alkylene group having 1 to 30 carbon atoms (for example, a methylene group, an ethylene group, a trimethylene group, a propylene group, and a butylene group), a substituted or unsubstituted arylene group having 6 to 30 carbon atoms (for example, a phenylene group and a naphthalene group), a substituted or unsubstituted heterocyclic linking group, a —CH₂═CH₂—, —O—, —S—, —NR—, —C(═O)—, —SO—, —SO₂—, a linking group represented by the following Formula (2), a linking group represented by the following Formula (3), or a linking group represented by the following Formula (4), or a linking group that is formed by linking two or more of them (for example, —N(R)C(═O)—, —OC(═O)—, —C(═O)N(R)—, and —C(═O)O—). Herein, R represents a hydrogen atom, an alkyl group, an aryl group, or a heterocyclic group.

The divalent linking group in the invention is not limited at all as long as the effect of the invention is exerted.

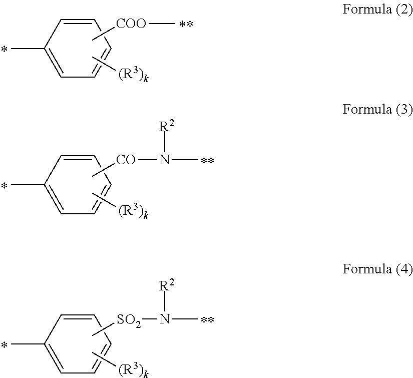

In Formulae (2) to (4), R² represents a hydrogen atom, an alkyl group, an aryl group, or a heterocyclic group; R³ represents a hydrogen atom or a substituent group; k represents an integer from 0 to 4; and when k is 2 or more, R³'s may be the same as or different from each other.

In Formulae (2) to (4), * represents a site for bonding with —C(R¹)═CH₂ group in Formula (1), and ** represents a site for bonding with L² in Formula (1) or Dye (when n=0).

In Formula (A), m represents an integer from 0 to 3. When m is 2 or more, plural X^{A2}'s may be the same as or different from each other. Similarly, when m is 2 or more, plural L^{A2}'s may be the same as or different from each other.

In Formula (A), m is preferably an integer from 0 to 2, more preferably 0 or 1, and still more preferably 0.

In Formula (A), Dye represents a pigment residue that is obtained by removing one to (1+m) hydrogen atoms from a pigment compound having the dipyrromethene structure.

In Formula (A), Dye and L^{A2} may be linked to each other via any one of a covalent bond, an ionic bond, and a coordination bond. Preferably, they are linked to each other via an ionic bond or a coordination bond.

Structural Unit Represented by Formula (B)

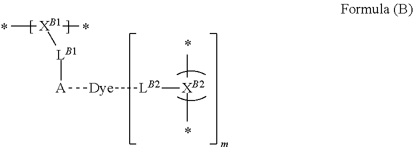

In Formula (B), X^{B1} represents a linking group formed by polymerization; L^{B1} represents a single bond or a divalent linking group; A represents a group which is capable of forming an ionic bond or a coordination bond with Dye; Dye represents a pigment compound containing the dipyrromethene structure which has a group capable of forming an ionic bond or a coordination bond with A, or a pigment residue that is obtained by removing one to m hydrogen atoms from the pigment compound; X^{B2} represents a linking group formed by polymerization; L^{B2} represents a single bond or a divalent linking group; m represents an integer from 0 to 3; and when m is 2 or more, the structures within [ ] may be the same as or different from each other. Dye and L^{B2} may be linked to each other via any one of a covalent bond, an ionic bond, and a coordination bond.

X^{B1}, L^{B1} and m in Formula (B) have the same definitions as X^{A1}, L^{A1} and m in Formula (A), respectively, and the preferred scope (including the preferred examples thereof) is also the same.

X^{B2} and L^{B2} and m in Formula (B) have the same definitions as X^{A2} and L^{A2} and m in Formula (A), respectively, and the preferred scope (including the preferred examples thereof) is also the same.

The group represented by A in Formula (B) may be any group as long as it is capable of being bonded to Dye via an ionic bond or a coordination bond. The group capable of forming an ionic bond may be an anionic group or a cationic group. The anionic group is preferably an anionic group having a pKa of 12 or less, such as a carboxyl group, a phospho group, a sulfo group, an acylsulfonamido group, or a sulfonimido group. More preferably, the anionic group has a pKa of 7 or less, and still more preferably 5 or less. The anionic group may have an ionic bond or a coordination bond with a heterocyclic group or Ma in Dye. More preferably, it forms an ionic bond with Ma. Although specific examples of the anionic group are described below, the invention is not limited to them. In the following specific examples, R represents a hydrogen atom, an alkyl group, an aryl group, or a heterocyclic group.

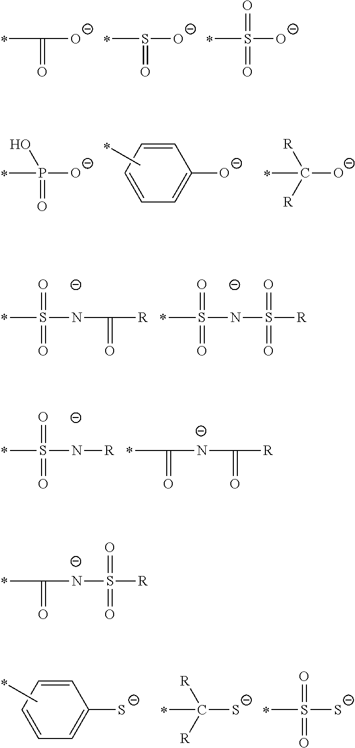

As a cationic group represented by A in Formula (B), a substituted or unsubstituted onium cation (for example, a substituted or unsubstituted ammonium group, a substituted or unsubstituted pyridinium group, a substituted or unsubstituted imidazolium group, a substituted or unsubstituted sulfonium group, a substituted or unsubstituted phosphonium group or the like) is preferable, and a substituted ammonium group is particularly preferable.

In Formula (B), m represents an integer from 0 to 3. When m is 2 or more, plural X^{B2}'s may be the same as or different from each other. Similarly, when m is 2 or more, plural L^{B2}'s may be the same as or different from each other.

In Formula (B), m is preferably an integer from 0 to 2, more preferably 0 or 1, and still more preferably 0.

In Formula (B), Dye represents a pigment compound having the dipyrromethene structure, or a pigment residue that is obtained by removing one to m hydrogen atoms from the pigment compound.

In Formula (B), Dye and L^{B2} may be linked to each other via any one of a covalent bond, an ionic bond, and a coordination bond. Preferably, they are linked to each other via an ionic bond or a coordination bond.

Structural Unit Represented by Formula (C)

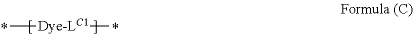

In Formula (C), L^{c1} represents a single bond or a divalent linking group; and Dye represents a divalent pigment residue that is obtained by removing any two hydrogen atoms from a pigment compound having the dipyrromethene structure. L^{c1} in Formula (C) has the same definition as L^{A1} in Formula (A), and the preferred scope (including the preferred examples thereof) is also the same.

Hereinbelow, examples of the structural unit containing the dipyrromethene structure included in the specific dye of the invention are shown.

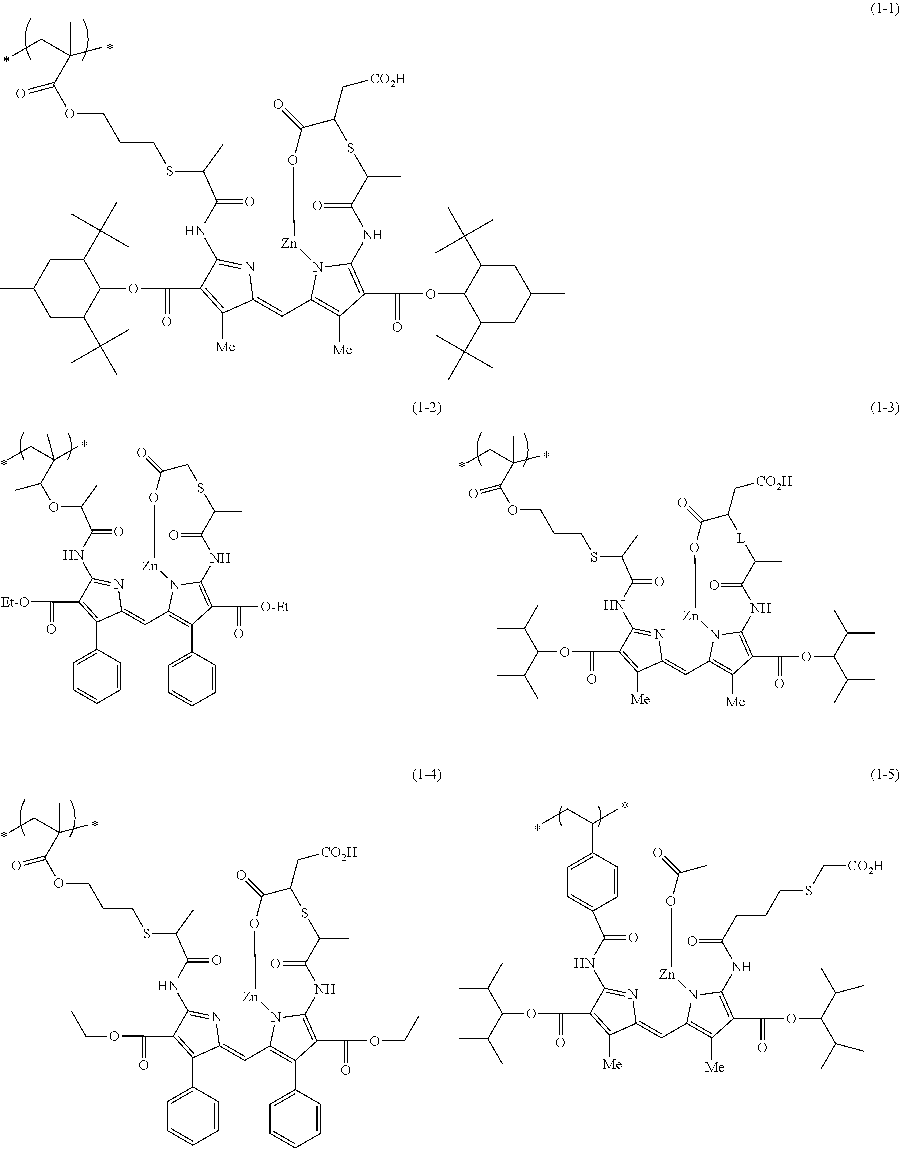

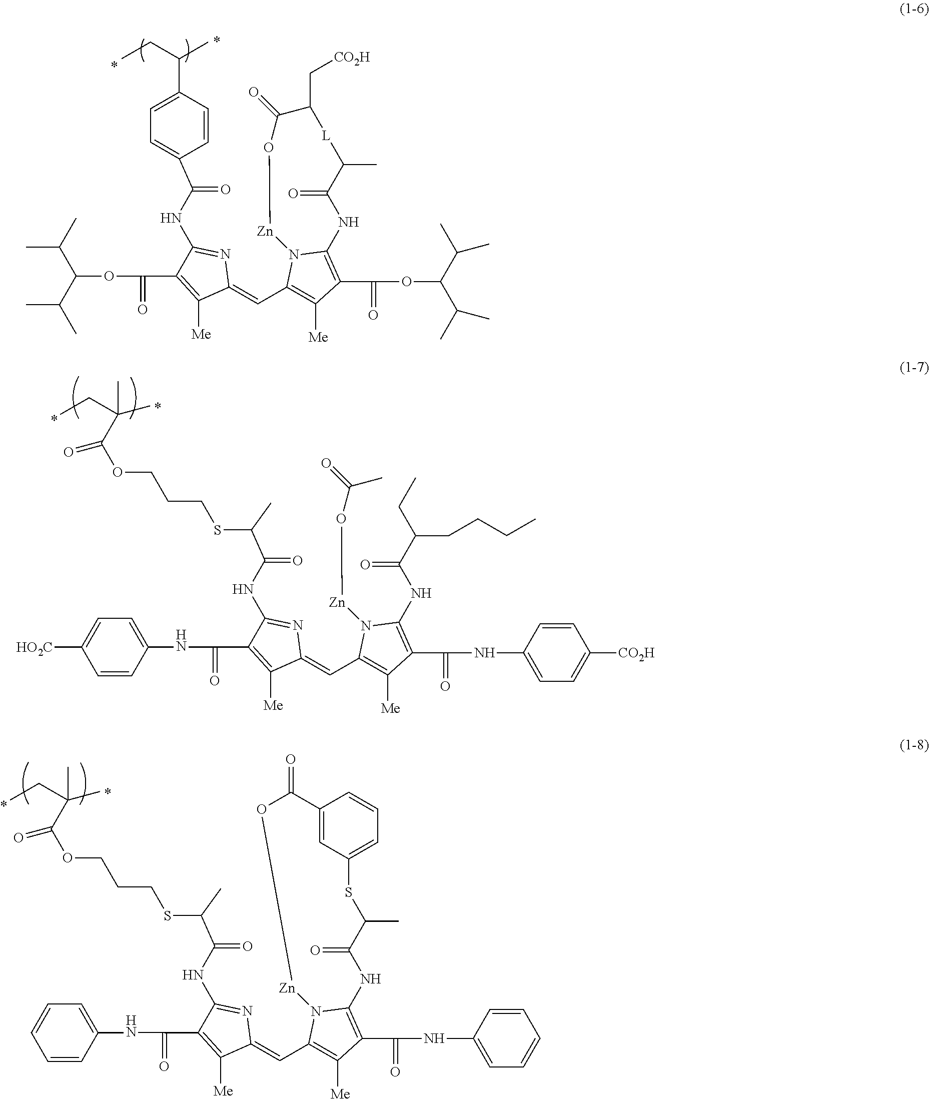

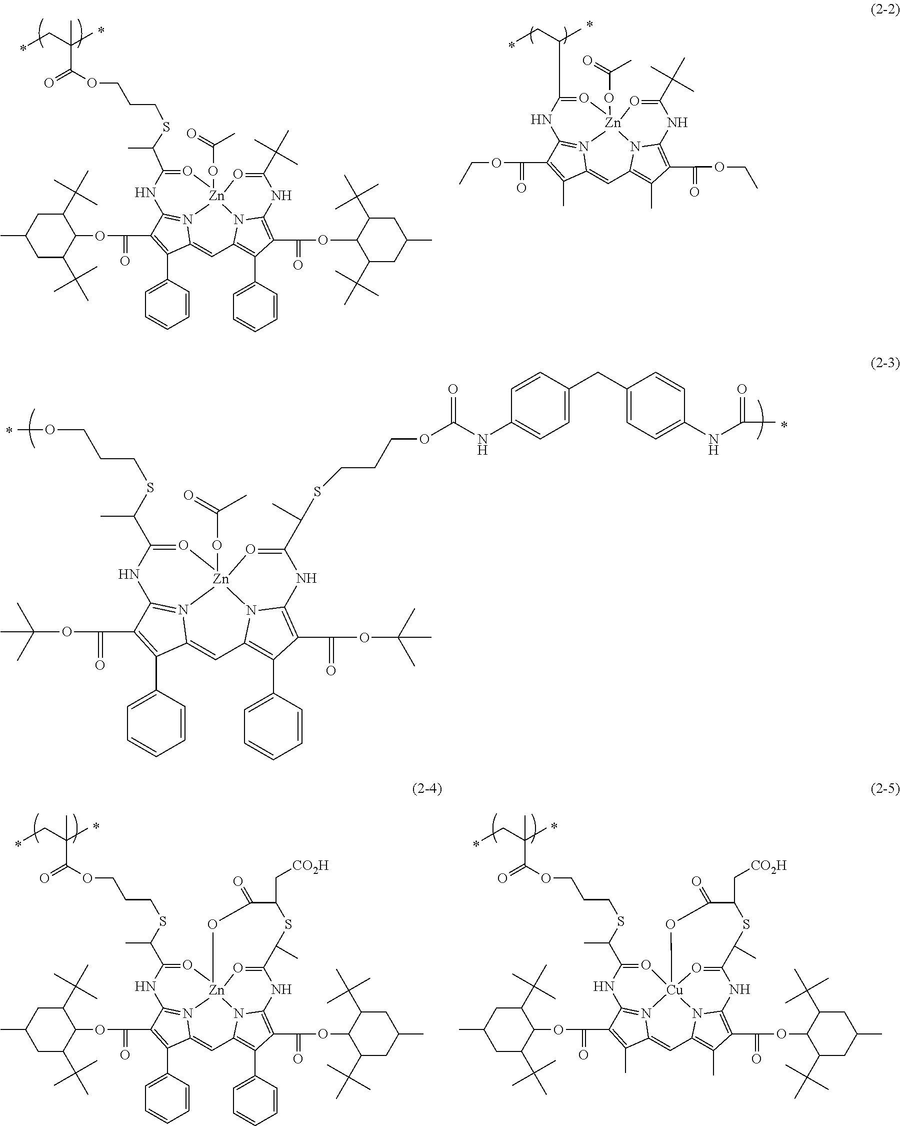

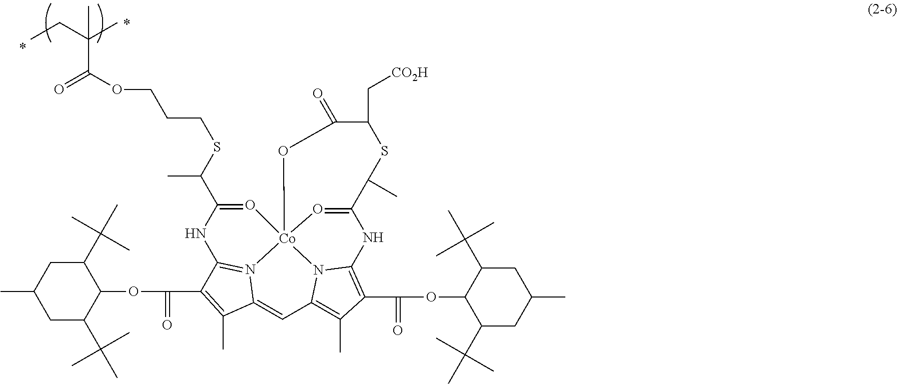

Copolymerization Components

The specific dye of the invention may be only formed from at least one of the structural units represented by Formulae (A), (B), and (C). Alternatively, the specific dye may be formed from at least one of the structural units represented by Formulae (A), (B), and (C) and another structural unit (in this case, at least one among at least one unit of the structural units represented by Formula (A), (B), or (C) and another structural unit preferably contains an alkali-soluble group).

As another structural unit, a structural unit having an alkali-soluble group (such as a carboxyl group, a phosphono group, or a sulfo group) in a side chain thereof is preferable.

Hereinbelow, specific examples of another structural unit are shown, but the invention is not limited to them.

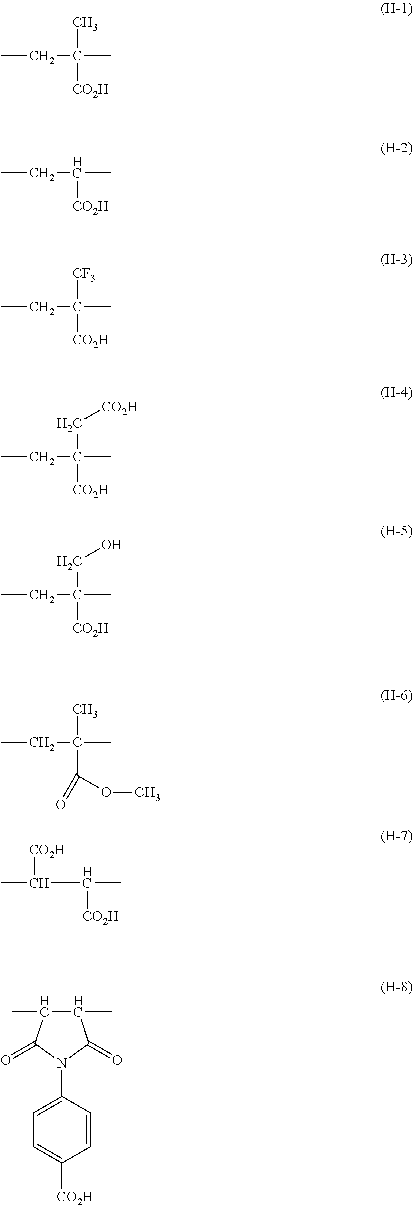

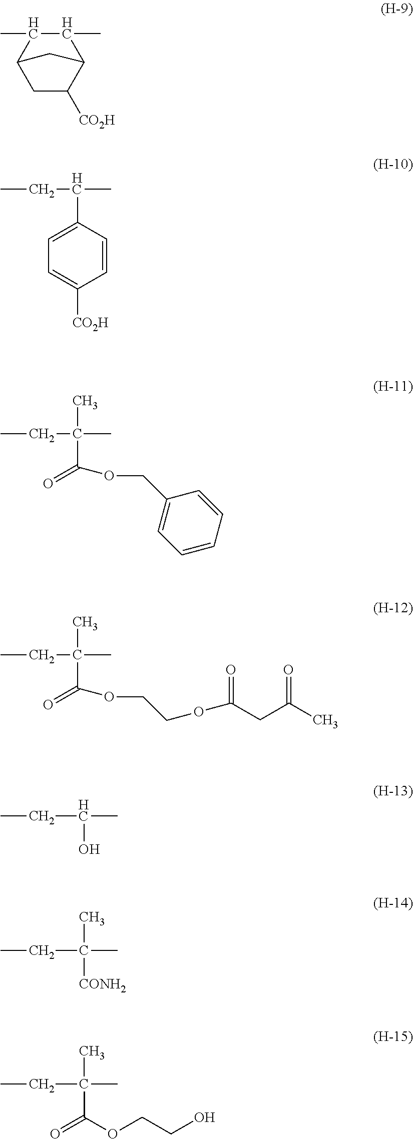

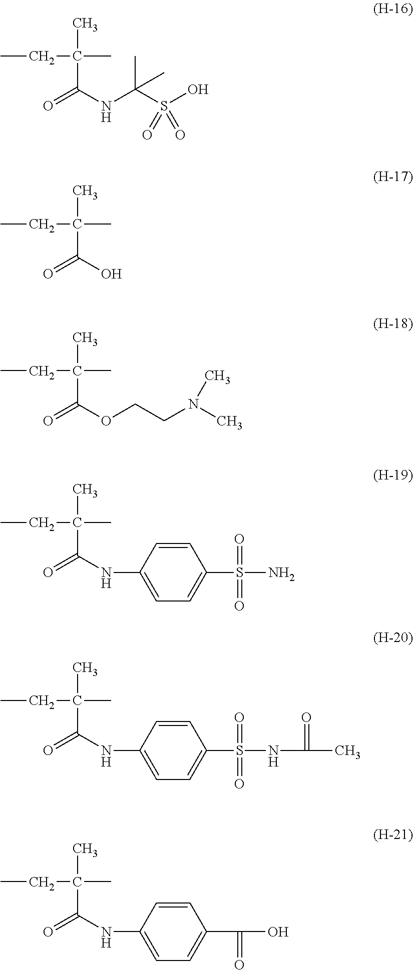

Further, the following structural units in which an unsaturated group is contained in a side chain thereof are also preferably used as a copolymerization component. Examples of the unsaturated group include an ethylenically unsaturated group (for example, a methacryl group, an acryl group, a styryl group, or the like), and when such a structural unit is used, heat resistance and solvent resistance are improved.

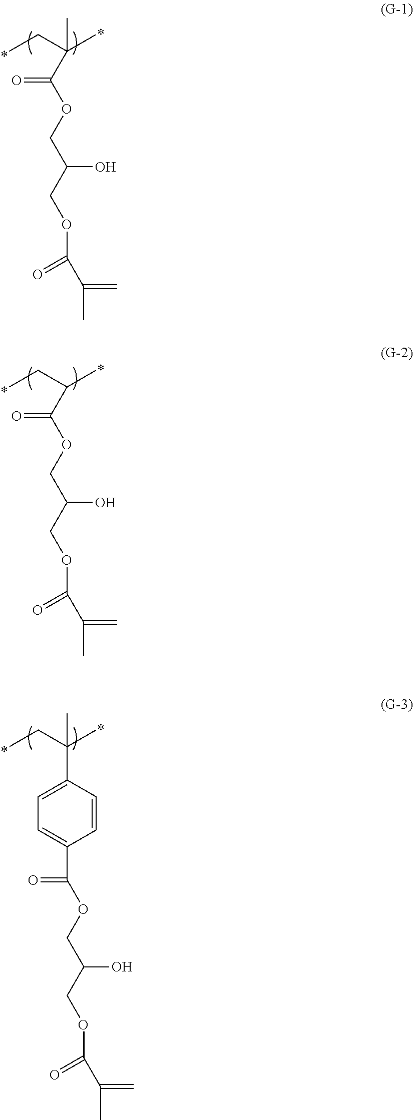

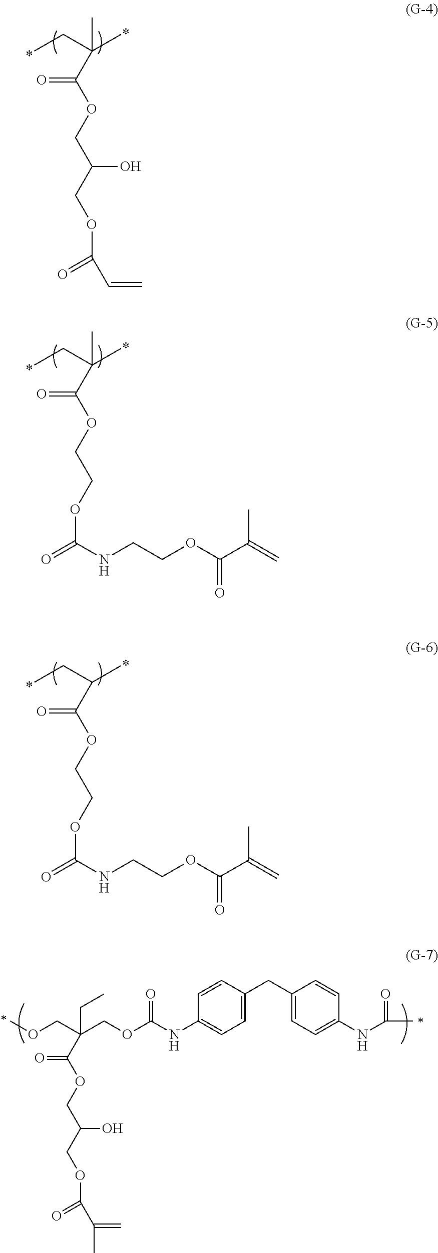

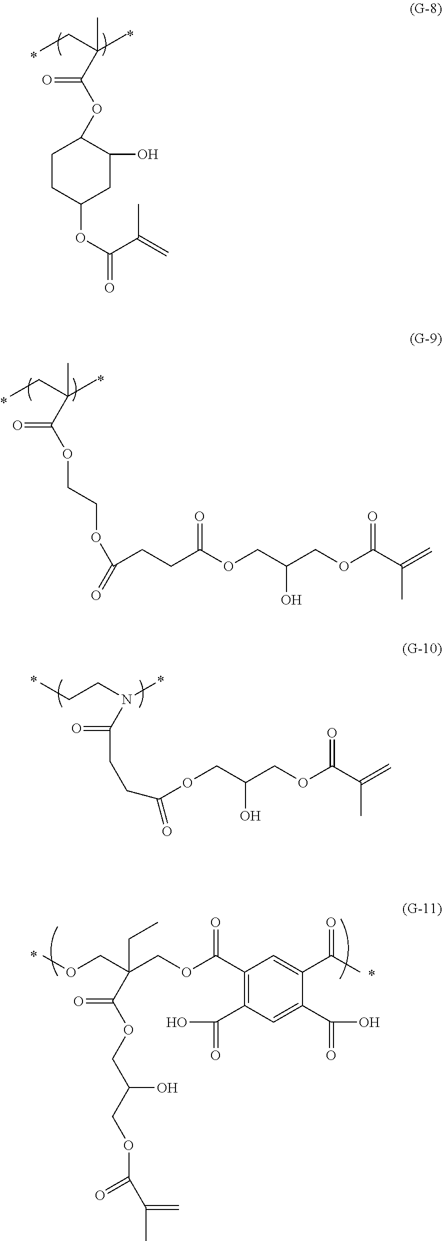

Pigment Multimer Represented by Formula (D)

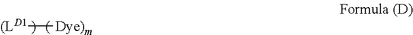

In Formula (D), L^{D1} represents a linking group with valency of m (i.e., an m-valent linking group); m represents an integer from 2 to 100; when m is 2 or more, the structures of Dye may be the same as or different from each other; and Dye represents a pigment residue that is obtained by removing one hydrogen atom from the pigment compound having the dipyrromethene structure.

In Formula (D), m is preferably from 2 to 80, more preferably 2 to 40, and still more preferably 2 to 10.

When m is 2, suitable examples of the divalent linking group represented by L^{D1} include a substituted or unsubstituted, linear, branched, or cyclic alkylene group having 1 to 30 carbon atoms (for example, a methylene group, an ethylene group, a trimethylene group, a propylene group, and a butylene group), a substituted or unsubstituted arylene group having 6 to 30 carbon atoms (for example, a phenylene group and a naphthalene group), a substituted or unsubstituted heterocyclic linking group, —CH₂═CH₂—, —O—, —S—, —NR—, —C(═O)—, —SO—, —SO₂—, and a linking group formed by connecting two or more of them (for example, —N(R)C(═O)—, —OC(═O)—, —C(═O)N(R)—, —C(═O)O—, and —N(R)C(═O)N(R)—). Herein, R represents a hydrogen atom, an alkyl group, an aryl group, or a heterocyclic group.

Examples of the m-valent linking group when m is 3 or more include a linking group which is formed from a center nucleus substituted by the divalent linking group mentioned above, and examples of the center nucleus include a substituted or unsubstituted arylene group (such as a 1,3,5-phenylene group, a 1,2,4-phenylene group, or a 1,4,5,8-naphthalene group), a heterocyclic linking group (for example, 1,3,5-triazine group), and an alkylene linking group.

Pigment Monomer Represented by Formula (1)

It is also preferable to obtain the specific pigment monomer in the invention by polymerization of a pigment monomer which contains the dipyrromethene structure represented by the following Formula (1).

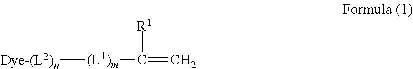

In Formula (1), R¹ represents a hydrogen atom, a halogen atom, an alkyl group, or an aryl group; L¹ represents —N(R²)C(═O)—, —OC(═O)—, —C(═O)N(R²)—, —C(═O)O—, a group represented by the following Formula (2), a group represented by the following Formula (3), or a group represented by the following Formula (4); L² represents a divalent linking group; m and n each independently represent 0 or 1; Dye represents a pigment residue which contains a dipyrromethene structure; and R² represents a hydrogen atom, an alkyl group, an aryl group, or a heterocyclic group.

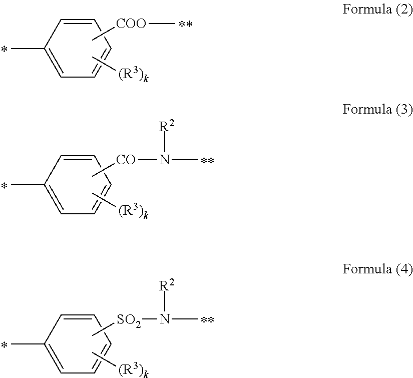

In Formulae (2) to (4) above, R² represents a hydrogen atom, an alkyl group, an aryl group, or a heterocyclic group; R³ represents a hydrogen atom or a substituent group; k represents an integer from 0 to 4; and when k is 2 or more, R³'s may be the same as or different from each other. In Formulae (2) to (4), * represents a site for bonding with a —C(R¹)═CH₂ group in Formula (1), and ** represents a site for bonding with L² in Formula (1) or Dye (when n=0).

Specifically, the pigment monomer which contains the dipyrromethene structure represented by Formula (1) is a pigment compound containing the dipyrromethene structure having the polymerizable group represented by -(L)ₙ-(L¹)ₘ-C(R¹)═CH₂ introduced therein.

Furthermore, when both m and n are 0, the —C(R¹)═CH₂ group is directly introduced to a pigment compound containing the dipyrromethene structure.

In Formula (1), R¹ represents a hydrogen atom, a halogen atom, an alkyl group, or an aryl group. When R¹ is an alkyl group or an aryl group, it may be either substituted or unsubstituted.

When R¹ is an alkyl group, it is a substituted or unsubstituted, linear, branched, or cyclic alkyl group preferably having 1 to 36 carbon atoms, and more preferably 1 to 6 carbon atoms. Examples of the alkyl group include a methyl group, an ethyl group, a propyl group, a butyl group, an octyl group, an isopropyl group, and a cyclohexyl group.

When R¹ is an aryl group, it is a substituted or unsubstituted aryl group preferably having 6 to 18 carbon atoms, more preferably 6 to 14 carbon atoms, and still more preferably 6 to 12 carbon atoms. Examples of the aryl group include a phenyl group and a naphthyl group.

When R¹ is a substituted alkyl group or a substituted aryl group, examples of the substituent group include: a halogen atom (for example fluorine, chlorine, bromine, and iodine; an alkyl group such as an alkyl group having preferably 1 to 24 carbon atoms and more preferably 1 to 12 carbon atoms, examples thereof including a methyl group, an ethyl group, a propyl group, a butyl group, an isopropyl group, a t-butyl group, a 2-ethylhexyl group, a dodecyl group, a cyclopropyl group, a cyclopentyl group, a cyclohexyl group, and an adamantyl group; an aryl group such as an aryl group having preferably 6 to 24 carbon atoms, and more preferably 6 to 12 carbon atoms, examples thereof including a phenyl group and a naphthyl group; a heterocyclic group such as a heterocyclic group having preferably 1 to 24 carbon atoms and more preferably 1 to 12 carbon atoms, examples thereof including a 2-thienyl group, a 4-pyridyl group, a 2-furyl group, a 2-pyrimidinyl group, a 1-pyridyl group, a 2-benzothiazolyl group, a 1-imidazolyl group, a 1-pyrazolyl group, and a benzotriazol-1-yl group; a silyl group such as a silyl group having preferably 3 to 24 carbon atoms and more preferably 3 to 12 carbon atoms, examples thereof including a trimethylsilyl group, a triethylsilyl group, a tributylsilyl group, a t-butyldimethylsilyl group, and a t-hexyldimethylsilyl group; a hydroxyl group; a cyano group; a nitro group; a sulfonic acid group; a phosphonic acid group; a carboxyl group; an alkoxy group such as an alkoxy group having preferably 1 to 24 carbon atoms, more preferably 1 to 12 carbon atoms, and still more preferably 1 to 6 carbon atoms, examples thereof including a methoxy group, an ethoxy group, a 1-butoxy group, a 2-butoxy group, an isopropoxy group, a t-butoxy group, a dodecyloxy group, and a cycloalkyloxy group such as a cyclopentyloxy group or a cyclohexyloxy group; an aryloxy group such as an aryloxy group having preferably 6 to 24 carbon atoms, and more preferably 6 to 12 carbon atoms, examples thereof including a phenoxy group and a 1-naphthoxy group; a heterocyclic oxy group such as a heterocyclic oxy group having preferably 1 to 24 carbon atoms and more preferably 1 to 12 carbon atoms, examples thereof including a 1-phenyltetrazol-5-oxy group and a 2-tetrahydropyranyloxy group; a silyloxy group such as a silyloxy group having preferably 1 to 24 carbon atoms and more preferably 1 to 12 carbon atoms, examples thereof including a trimethylsilyloxy group, a t-butyldimethylsilyloxy group, and a diphenylmethylsilyloxy group; an acyloxy group such as a acyloxy group having preferably 2 to 24 carbon atoms and more preferably 2 to 12 carbon atoms, examples thereof including an acetoxy group, a pyvaloyloxy group, a benzoyloxy group, and a dodecanoyloxy group; an alkoxycarbonyloxy group such as an alkoxycarbonyl oxy group having preferably 2 to 24 carbon atoms, more preferably 2 to 12 carbon atoms, and still more preferably 2 to 6 carbon atoms, examples thereof including an ethoxycarbonyl oxy group and a t-butoxycarbonyl oxy group; a cycloalkyl oxycarbonyl oxy group such as a cyclohexyl oxycarbonyl oxy group; an aryloxy carbonyloxy group such as an aryloxy carbonyloxy group having preferably 7 to 24 carbon atoms, and more preferably 7 to 12 carbon atoms, examples thereof including a phenoxy carbonyloxy group; a carbamoyloxy group such as a carbamoyloxy group having preferably 1 to 24 carbon atoms, more preferably 1 to 12 carbon atoms, and still more preferably 1 to 6 carbon atoms, examples thereof including a N,N-dimethylcarbamoyloxy group, a N-butyl carbamoyloxy group, a N-phenyl carbamoyloxy group, and a N-ethyl-N-phenyl carbamoyloxy group; a sulfamoyloxy group such as a sulfamoyloxy group having preferably 1 to 24 carbon atoms, more preferably 1 to 12 carbon atoms, and still more preferably 1 to 6 carbon atoms, examples thereof including a N,N-diethyl sulfamoyloxy group and a N-propyl sulfamoyloxy group; an alkylsulfonyloxy group such as an alkylsulfonyloxy group having preferably 1 to 24 carbon atoms, more preferably 1 to 12 carbon atoms, and still more preferably 1 to 6 carbon atoms, examples thereof including a methyl sulfonyloxy group, a hexadecyl sulfonyloxy group, and a cyclohexyl sulfonyloxy group; an aryl sulfonyloxy group such as an aryl sulfonyloxy group having preferably 6 to 24 carbon atoms, and more preferably 6 to 12 carbon atoms, examples thereof including a phenyl sulfonyloxy group; an acyl group such as an acyl group having preferably 1 to 24 carbon atoms and more preferably 1 to 12 carbon atoms, examples thereof including a formyl group, an acetyl group, a pyvaloyl group, a benzoyl group, a tetradecanoyl group, and a cyclohexanoyl group;
an alkoxycarbonyl group such as an alkoxycarbonyl group having preferably 2 to 24 carbon atoms, more preferably 2 to 12 carbon atoms, and still more preferably 2 to 6 carbon atoms, examples thereof including a methoxycarbonyl group, an ethoxycarbonyl group, an octadecyloxycarbonyl group, and a cyclohexyloxycarbonyl group; an aryloxycarbonyl group such as an aryloxycarbonyl group having preferably 7 to 24 carbon atoms, and more preferably 7 to 12 carbon atoms, examples thereof including a phenoxycarbonyl group; a carbamoyl group such as a carbamoyl group having preferably 1 to 24 carbon atoms and more preferably 1 to 12 carbon atoms, examples thereof including a carbamoyl group, a N,N-diethyl carbamoyl group, a N-ethyl-N-octyl carbamoyl group, a N,N-dibutyl carbamoyl group, a N-propyl carbamoyl group, a N-phenyl carbamoyl group, a N-methyl-N-phenyl carbamoyl group, and a N,N-dicyclohexyl carbamoyl group; an amino group such as an amino group having preferably 24 or less carbon atoms, and preferably 12 or less carbon atoms, examples thereof including an amino group, a methylamino group, a N,N-dibutylamino group, a tetradecylamino group, a 2-ethylhexylamino group, and a cyclohexylamino group; an anilino group such as an anilino group having preferably 6 to 24 carbon atoms, and more preferably 6 to 12 carbon atoms, examples thereof including an anilino group and a N-methylanilino group; a heterocyclic amino group such as a heterocyclic amino group having preferably 1 to 24 carbon atoms and more preferably 1 to 12 carbon atoms, examples thereof including a 4-pyridylamino group; a carbonamide group such as a carbonamide group having preferably 2 to 24 carbon atoms and more preferably 2 to 12 carbon atoms, examples thereof including an acetamide group, a benzamide group, a tetradecaneamide group, a pyvaloylamide group, and a cyclohexaneamide group; a ureido group such as a ureido group having preferably 1 to 24 carbon atoms and more preferably 1 to 12 carbon atoms, examples thereof including a ureido group, a N,N-dimethylureido group, and a N-phenylureido group; an imide group such as an imide group having preferably 20 or less carbon atoms, and more preferably 12 or less carbon atoms, examples thereof including a N-succinimide group and a N-phthalimide group; an alkoxycarbonyl amino group such as an alkoxycarbonyl amino group having preferably 2 to 24 carbon atoms and more preferably 2 to 12 carbon atoms, examples thereof including a methoxycarbonylamino group, an ethoxycarbonylamino group, a t-butoxycarbonylamino group, an octadecyl oxycarbonylamino group, and a cyclohexyl oxycarbonylamino group; an aryloxy carbonylamino group such as an aryloxy carbonylamino group having preferably 7 to 24 carbon atoms, and more preferably 7 to 12 carbon atoms, examples thereof including a phenoxy carbonylamino group; a sulfonamide group such as a sulfonamide group having preferably 1 to 24 carbon atoms and more preferably 1 to 12 carbon atoms, examples thereof including a methane sulfonamide group, a butane sulfonamide group, a benzene sulfonamide group, a hexadecane sulfonamide group, and a cyclohexane sulfonamide group; a sulfamoylamino group such as a sulfamoylamino group having preferably 1 to 24 carbon atoms and more preferably 1 to 12 carbon atoms, examples thereof including a N,N-dipropyl sulfamoylamino group and a N-ethyl-N-dodecyl sulfamoylamino group; an azo group such as an azo group having preferably 1 to 24 carbon atoms and more preferably 1 to 12 carbon atoms, examples thereof including a phenylazo group and a 3-pyrazolylazo group; an alkylthio group such as an alkylthio group having preferably 1 to 24 carbon atoms and more preferably 1 to 12 carbon atoms, examples thereof including a methylthio group, an ethylthio group, an octylthio group, and a cyclohexylthio group; an arylthio group such as an arylthio group having preferably 6 to 24 carbon atoms, and more preferably 6 to 12 carbon atoms, examples thereof including a phenylthio group; a heterocyclic thio group such as a heterocyclic thio group having preferably 1 to 24 carbon atoms and more preferably 1 to 12 carbon atoms, examples thereof including a 2-benzothiazolylthio group, a 2-pyridylthio group, and a 1-phenyltetrazolylthio group; an alkylsulfinyl group such as an alkylsulfinyl group having preferably 1 to 24 carbon atoms and more preferably 1 to 12 carbon atoms, examples thereof including a dodecanesulfinyl group;
an arylsulfinyl group such as an arylsulfinyl group having preferably 6 to 24 carbon atoms, and more preferably 6 to 12 carbon atoms, examples thereof including a phenylsulfinyl group; an alkylsulfonyl group such as an alkylsulfonyl group having preferably 1 to 24 carbon atoms and more preferably 1 to 12 carbon atoms, examples thereof including a methylsulfonyl group, an ethylsulfonyl group, a propylsulfonyl group, a butylsulfonyl group, an isopropyl sulfonyl group, a 2-ethylhexyl sulfonyl group, a hexadecyl sulfonyl group, an octyl sulfonyl group, and a cyclohexyl sulfonyl group; an arylsulfonyl group such as an arylsulfonyl group having preferably 6 to 24 carbon atoms, and more preferably 6 to 12 carbon atoms, examples thereof including a phenylsulfonyl group and a 1-naphthyl sulfonyl group; a sulfamoyl group such as a sulfamoyl group having preferably 24 or less carbon atoms, and more preferably 16 or less carbon atoms, examples thereof including a sulfamoyl group, a N,N-dipropylsulfamoyl group, a N-ethyl-N-dodecyl sulfamoyl group, a N-ethyl-N-phenyl sulfamoyl group, and a N-cyclohexyl sulfamoyl group; a sulfo group; a phosphonyl group such as a phosphonyl group having preferably 1 to 24 carbon atoms and more preferably 1 to 12 carbon atoms, examples thereof including a phenoxyphosphonyl group, an octyloxyphosphonyl group, and a phenylphosphonyl group; a phosphinoyl amino group such as a phosphinoyl amino group having preferably 1 to 24 carbon atoms and more preferably 1 to 12 carbon atoms, examples thereof including a diethoxyphosphinoyl amino group and a dioctyloxyphosphinoyl amino group.

Of the substituent groups described above, a halogen atom, alkyl group, an aryl group, a hydroxyl group, a sulfonic acid group, a phosphonic acid group, a carboxylic acid group, an alkoxy group, an aryloxy group, an alkoxycarbonyl oxy group, a cycloalkyl carbonyloxy group, an aryloxy carbonyloxy group, a carbamoyloxy group, a sulfamoyloxy group, an alkylsulfonyloxy group, an aryl sulfonyloxy group, an acyl group, an alkoxycarbonyl group, an aryloxycarbonyl group, a carbamoyl group, a carbonamide group, an imide group, a sulfonamide group, a sulfamoyl amino group, and a sulfamoyl group are preferable; an alkyl group, an aryl group, a hydroxyl group, a sulfonic acid group, a phosphonic acid group, a carboxylic acid group, an alkoxy group, an aryloxy group, an alkoxycarbonyl oxy group, an aryloxy carbonyloxy group, a carbamoyloxy group, a sulfamoyloxy group, an alkylsulfonyloxy group, an aryl sulfonyloxy group, an acyl group, an alkoxycarbonyl group, an aryloxy carbonyl group, a carbamoyl group, a carbonamide group, a sulfonamide group, a sulfamoyl amino group, and a sulfamoyl group are more preferable; a hydroxyl group, a sulfonic acid group, a phosphonic acid group, a carboxylic acid group, an alkoxy group, an aryloxy group, an alkoxycarbonyl oxy group, an aryloxy carbonyloxy group, a carbamoyloxy group, a sulfamoyloxy group, an alkylsulfonyloxy group, an arylsulfonyloxy group, an acyl group, an alkoxycarbonyl group, and an aryloxy carbonyl group are still more preferable; and a hydroxyl group, a sulfonic acid group, a carboxylic acid group, an alkoxy group, an alkoxycarbonyl oxy group, a carbamoyloxy group, a sulfamoyloxy group, an alkylsulfonyloxy group, an acyl group, and an alkoxycarbonyl group are particularly preferable.

Among the more preferred substituent groups described above, a sulfonic acid group, a carboxylic acid group, an alkoxy group, an alkoxycarbonyl oxy group, an alkylsulfonyloxy group, and an alkoxycarbonyl group are still more preferable, and a sulfonic acid group, a carboxylic acid group, an alkoxy group, and an alkoxycarbonyl group are even still more preferable, and a sulfonic acid group, a carboxylic acid group, and an alkoxy group are particularly preferable.

In Formula (1), R¹ is preferably a hydrogen atom, an alkyl group, or an aryl group, and more preferably a hydrogen atom or an alkyl group.

In Formula (1), when the substituent group of a substituted alkyl group or a substituted aryl group as R¹ is a group which can be further substituted, it may be substituted with the substituent group described above. When the substituent group is substituted with two or more additional substituent groups, the additional substituent groups may be the same as or different from each other.

In Formula (1), L¹ represents —N(R²)C(═O)—, —OC(═O)—, —C(═O)N(R²)—, —C(═O)O—, a group represented by Formula (2) below, a group represented by Formula (3) below, or a group represented by Formula (4) below. Herein, R² represents a hydrogen atom, an alkyl group, an aryl group, or a heterocyclic group.

In Formula (1), examples of an alkyl group, aryl group, and heterocyclic group represented by R² include the alkyl group, aryl group, and heterocyclic group that are described above as a substituent group for a substituted alkyl group and a substituted aryl group represented by R¹, and the preferred embodiments thereof (including the preferred examples thereof) are also the same.

An alkyl group, aryl group, or heterocyclic group represented by R² may be substituted with the substituent group described above in connection with R¹, and when it is substituted with two or more additional substituent groups, the additional substituent groups may be the same as or different from each other.

Hereinbelow, a group represented by Formula (2) below, a group represented by Formula (3) below, and a group represented by Formula (4) below that are expressed as L¹ in Formula (1) are described.

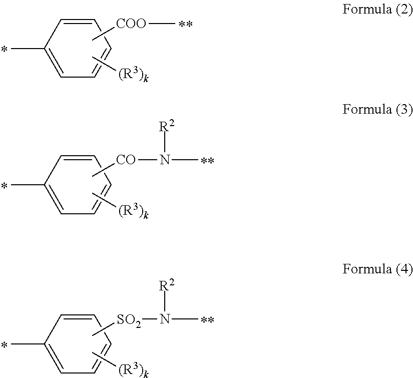

In Formulae (2) to (4), R² represents a hydrogen atom, an alkyl group, an aryl group, or a heterocyclic group; R³ represents a hydrogen atom or a substituent group; k represents an integer from 0 to 4; when k is 2 or more, R³'s may be the same as or different from each other; * represents a site for bonding with —C(R¹)═CH₂ group in Formula (1); and ** represents a site for bonding with L² in Formula (1) or Dye (when n=0).

R² in Formulae (2) to (4) has the same definition as R² in Formula (1), and the preferred embodiments thereof (including the preferred examples thereof) are also the same.

In Formulae (2) to (4), R³ represents a hydrogen atom or a substituent group, and examples of a substituent group represented by R³ include the substituent groups that are described above as a substituent group for a substituted alkyl group and a substituted aryl group as R¹, and the preferred embodiment thereof (including the preferred examples thereof) are also the same. k represents 0, 1, 2, 3, or 4. When k is 2, 3, or 4, R³'s may be the same as or different from each other.

When the substituent group represented by R³ is a group which can be further substituted, it may be substituted with the substituent group described above in connection with R¹, and when it is substituted with two or more additional substituent groups, the additional substituent groups may be the same as or different from each other.

From the viewpoint of synthesis, L¹ is preferably —N(R²)C(═O)—, —OC(═O)—, —C(═O)N(R²)—, or —C(═O)O—, more preferably —OC(═O)—, —C(═O)N(R²)—, or —C(═O)O—, and still more preferably —C(═O)N(R²)— or —C(═O)O—.

Next, L² in Formula (1) is described.

L² represents a divalent linking group which connects L¹ or a —C(R¹)═CH₂ group (when m=0) with Dye.

Preferred examples of L² include an alkylene group, an aralkylene group, an arylene group, —O—, —C(═O)—, —OC(═O)—, OC(═O)O—, —OSO₂—, —OC(═O)N(R⁵⁰)—, —N(R⁵⁰)—, —N(R⁵⁰)C(═O)—, —N(R⁵⁰)C(═O)O—, —N(R⁵⁰)C(═O)N(R⁵¹)—, —N(R⁵⁰)SO₂—, —N(R⁵⁰)SO₂N(R⁵¹)—, —S—, —S—S—, —SO—, —SO₂—, —SO₂N(R⁵⁰)—, and —SO₂O—. Further, it is also possible that plural divalent linking groups are bonded to one another to form a new divalent linking group.

R⁵⁰ and R⁵¹ each independently represent a hydrogen atom, an alkyl group, an aryl group, or a heterocyclic group. Examples of an alkyl group, an aryl group, and a heterocyclic group as R⁵⁰ and R⁵¹ include the alkyl group, aryl group, and heterocyclic group that are described above as a substituent group for R¹, and the preferred embodiments thereof (including the preferred examples thereof) are also the same. An alkyl group, aryl group, or heterocyclic group represented by R⁵⁰ or R⁵¹ may be substituted with the substituent group described above in connection with R¹, and when it is substituted with two or more additional substituent groups, the additional substituent groups may be the same as or different from each other.

When L² is an alkylene group, an aralkylene group, or an arylene group, which may be either unsubstituted or substituted. When the alkylene group, aralkylene group, or arylene group is substituted, it may be substituted with the substituent group described above in connection with R¹, and when it is substituted with two or more additional substituent groups, the additional substituent groups may be the same as or different from each other.

When L² is an alkylene group, an aralkylene group, or an arylene group, an alkylene group having 1 to 12 carbon atoms, an aralkylene group having 6 to 18 carbon atoms, and an arylene group having 6 to 18 carbon atoms are preferable. An alkylene group having 1 to 8 carbon atoms, an aralkylene group having 6 to 16 carbon atoms, and an arylene group having 6 to 12 carbon atoms are more preferable. An alkylene group having 1 to 6 carbon atoms and an aralkylene group having 6 to 12 carbon atoms are still more preferable.

As a combination of L¹ and L², a combination in which L¹ is —N(R²)C(═O)—, —OC(═O)—, —C(═O)N(R²)—, or —C(═O)O— and L² is an alkylene group having 1 to 12 carbon atoms, an aralkylene group a having 6 to 18 carbon atoms, an arylene group having 6 to 18 carbon atoms, an alkylthio ether having 2 to 18 carbon atoms, an alkylcarbonamide group having 2 to 18 carbon atoms, or an alkylamino carbonyl group having 2 to 18 carbon atoms is preferable. More preferably, a combination in which L¹ is —OC(═O)—, —C(═O)N(R²)—, or —C(═O)O— and L² is an alkylene group having 1 to 8 carbon atoms, an aralkylene group a having 6 to 16 carbon atoms, an arylene group having 6 to 12 carbon atoms, an alkylthio ether having 2 to 12 carbon atoms, an alkylcarbonamide group having 2 to 12 carbon atoms, or an alkylamino carbonyl group having 2 to 12 carbon atoms is preferable. Still more preferably, a combination in which L¹ is —C(═O)N(R²)— or —C(═O)O— and L² is an alkylene group having 1 to 6 carbon atoms, an aralkylene group a having 6 to 12 carbon atoms, an alkylthio ether having 2 to 6 carbon atoms, an alkylcarbonamide group having 2 to 6 carbon atoms, or an alkylamino carbonyl group having 2 to 6 carbon atoms is preferable.

Hereinbelow, examples of the polymerizable group represented by -(L²)ₙ-(L¹)ₘ-C(R¹)═CH₂ in Formula (1) are shown. However, the invention is not limited to them.

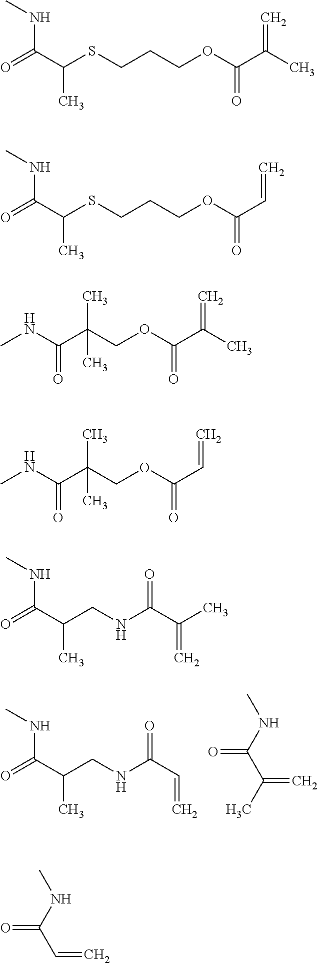

Exemplary Compounds of Specific Dye

Hereinbelow, exemplary compounds of the specific dye in the invention are described, but the invention is not limited to the following exemplary compounds.

Regarding the exemplary compounds, the term “wt %” is based on mass.

For obtaining the exemplary compounds 2-1 to 2-5, the constitutional component which has a composition ratio “a” and a methacryl component which has a composition ratio “(b+c)” are polymerized according to the ratio listed in the table. Part of the methacrylic acid component of a pigment multimer that is generated by polymerization is coordinated to Zn with an equimolar amount of the constitutional component which makes the composition ratio “a”.

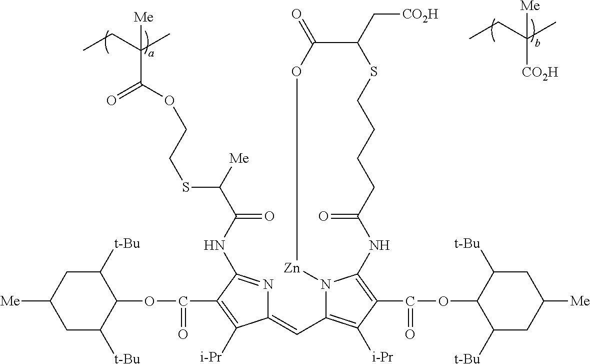

| Exemplary compound | a(wt-%) | b(wt-%) |
|---|---|---|
| 1-1 | 100 | 0 |
| 1-2 | 95 | 5 |
| 1-3 | 90 | 10 |
| 1-4 | 88 | 12 |
| 1-5 | 85 | 15 |
| 1-6 | 82 | 18 |
| 1-7 | 80 | 20 |
| 1-8 | 78 | 22 |
| 1-9 | 75 | 25 |
| 1-10 | 70 | 30 |

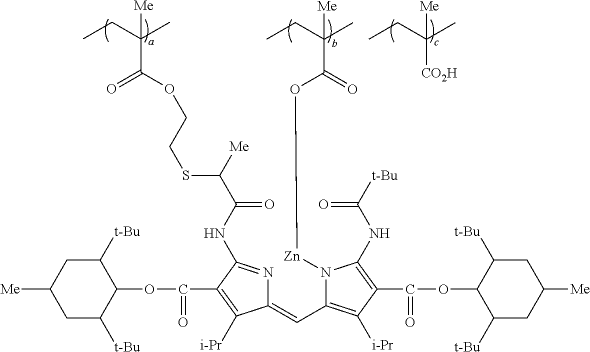

| Exemplary compound | a(wt-%) | b + c(wt-%) |
|---|---|---|
| 2-1 | 83 | 17 |
| 2-2 | 77 | 23 |
| 2-3 | 71 | 29 |
| 2-4 | 65 | 35 |
| 2-5 | 60 | 40 |

TABLE 1

| | | Constitutional unit | | |
|---|---|---|---|---|
| | Constitutional | of copolymerization | | Composition |
| | unit containing | component | | ratio for co- |
| Exemplary | dipyrromethene | Second | Third | polymerization |
| compound | structure | component | component | (% by mass) |
| 101 | 1-1 | G-1 | H-1 | 85/10/5 |
| 102 | 2-1 | G-1 | — | 90/10 |
| 103 | 2-1 | G-1 | H-1 | 85/10/5 |
| 104 | 2-1 | G-1 | H-2 | 85/10/5 |
| 105 | 2-3 | G-7 | — | 90/10 |
| 106 | 2-4 | G-1 | — | 90/10 |

Synthetic Examples of Specific dye

Hereinbelow, synthetic examples are described for several specific examples of the specific dye. However, the invention is not limited to them.

Synthesis of Exemplary Compound 1-4

The pigment monomer 1 (5.0 g) shown below, methacrylic acid (0.68 g), and 240 mg of n-dodecane thiol as a chain transfer agent were dissolved in 32 ml of propylene glycol monomethyl ether acetate (PGMEA), and the mixture was stirred at 85° C. under nitrogen atmosphere, and 542 mg of dimethyl 2,2′-azobis(2-methyl propionate) was added thereto. Then, 240 mg of dimethyl 2,2′-azobis(2-methyl propionate) was further added twice with an interval of 2 hours, and after increasing the temperature to 90° C., the mixture was further stirred for 2 hours. After completion of the reaction, the reaction mixture was added dropwise to 400 ml of acetonitrile. The crystals obtained were filtered, thereby obtaining the exemplary compound 1-4 (4.8 g).

The pigment monomer 1 shown below may be produced in accordance with the synthetic method disclosed in JP-A No. 2008-292970.

Further, the weight average molecular weight of the exemplary compound may be controlled by adjusting the amount of chain transfer agent and the reaction temperature, and the dispersity thereof may be controlled by modifying the type and amount of solvent used for re-precipitation.

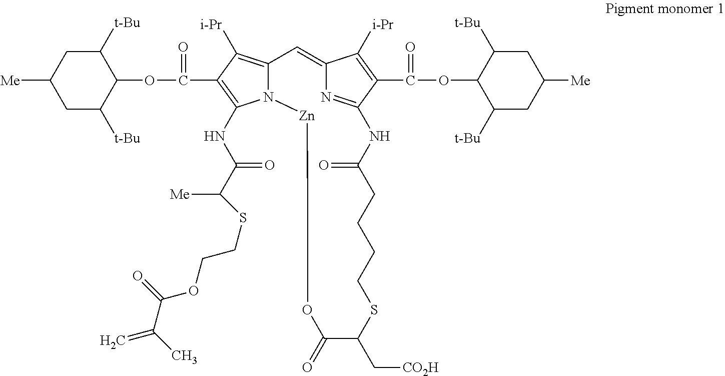

Synthesis of Exemplary Compound 2-3

The pigment monomer 2 (20 g) shown below, methacrylic acid (5.88 g), and 520 mg of thiomalic acid as a chain transfer agent were dissolved in 150 ml of propylene glycol monomethyl ether (PGME), and the mixture was stirred at 85° C. under nitrogen atmosphere, and 1.2 g of dimethyl 2,2′-azobis(2-methyl propionate) was added thereto. Then, 1.2 g of dimethyl 2,2′-azobis(2-methyl propionate) was further added twice with an interval of 2 hours, and after increasing the temperature to 90° C., the mixture was further stirred for 2 hours. After completion of the reaction, the reaction mixture was added dropwise to 2,000 ml of acetonitrile. The crystals obtained were filtered, thereby obtaining the exemplary compound 2-3 (21.2 g). Based on ¹H NMR spectrum, the elimination of the proton peak derived from AcO was found, and therefore it was confirmed that main chain carboxylic acid is coordinated like the exemplary compound 2-3.

The pigment monomer 2 shown below may be produced in accordance with the synthetic method disclosed in JP-A No. 2008-292970. The weight average molecular weight of the exemplary compound may be controlled by adjusting the amount of chain transfer agent and the reaction temperature, and the dispersity thereof may be controlled by modifying the type and amount of solvent used for re-precipitation.

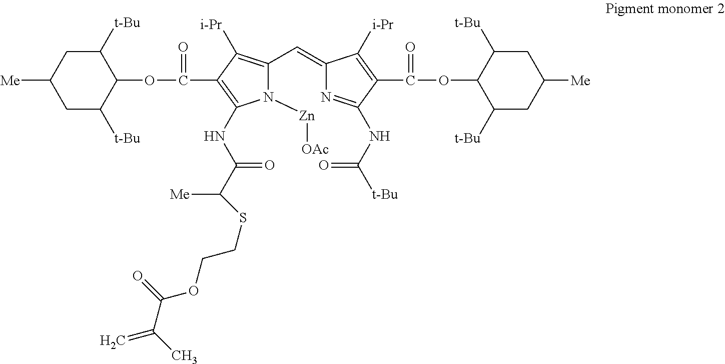

As described above, the specific dye in the invention is described. However, one type of the specific dye is preferably used in a blue pixel of a color filter of the invention, and two or more types of specific dyes may be also used therein.

The film thicknesses of a red pixel, a green pixel, and a blue pixel are each preferably 1.0 μm or less. When the film thickness is within this range, stray light between pixels is easily inhibited, and the resolving power is improved when a solid-state image sensor is produced.

The red pixel, green pixel, and blue pixel of the color filter of the invention may be formed, for example, by photolithography using radiation-sensitive compositions of respective colors containing the above-mentioned colorant, or by an inkjet method using the radiation-sensitive compositions of respective colors containing the above-mentioned colorant.

Of these, the photolithography method including preparing radiation-sensitive compositions is preferable from the viewpoint that fine patterns are easily formed into arbitrary shape.

Hereinbelow, the method of producing a color filter for a solid-state image sensor according to a method including preparing a colored radiation-sensitive composition of each color and applying it by photolithography is described. However, the color filter of the invention is not limited thereto.

Preparation of Colored Radiation-sensitive Composition

A colored radiation-sensitive composition is prepared using the colorant mentioned above together with a polymerizable compound and a photopolymerization initiator, and, if necessary, respective components such as a polymer compound, an organic solvent, or a surfactant. The colored radiation-sensitive composition is used for forming colored pixels of a color filter of the invention, and for example, a colored cured film that is obtained by curing by polymerization of the colored radiation-sensitive composition is used as a colored pixel.

Hereinbelow, each component contained in the colored radiation-sensitive composition of the invention is described in greater detail.

Further, regarding the colored radiation-sensitive composition of the invention, “total solid content” indicates the total mass of the components of the colored radiation-sensitive composition excluding an organic solvent.

As used herein, the term “alkyl group” indicates a “linear, branched, or cyclic” alkyl group, which may be either substituted or unsubstituted.

As used herein, the term “(meth)acrylate” indicates both or any one of acrylate and methacrylate, the term “(meth)acryl” indicates both or any one of acryl and methacryl, and the term “(meth)acryloyl” indicates both or any one of acryloyl and methacryloyl.

The monomer as used herein is distinguished from oligomers and polymers, and it indicates a compound having weight average molecular weight of 2,000 or less. As used herein, the term “polymerizable compound” indicates a compound having a polymerizable functional group, and it may be either a monomer or a polymer. The term “polymerizable functional group” indicates a group involved with a polymerization reaction.

Further, regarding the description of a group (or an atomic group) as used herein, the description that is not described with substituted or unsubstituted includes not only a group having no substituent group but also a group having a substituent group. For example, the term “alkyl group” includes not only an alkyl group having no substituent group (that is, unsubstituted alkyl group) but also an alkyl group having a substituent group (that is, substituted alkyl group).

As used herein, the term “process” includes not only a separate process but also a process with no clear distinction between the process and other process, if the desired effect of the process is obtained therefrom.

As used herein, the term “radiation” includes visible light, ultraviolet light, far ultraviolet light, electronic beam, X ray, and the like.

Preparation of Pigment Dispersion

When a pigment is used as a colorant, it is preferable that the colored radiation-sensitive composition is produced: by preparing in advance a pigment dispersion by dispersing the pigment, if necessary, with other components such as a pigment dispersant, an organic solvent, a pigment derivative, or a polymer compound; and mixing the thus-obtained pigment dispersion with a polymerizable compound and a photopolymerization initiator, and, if necessary, other components.

Hereinbelow, the formulation of a pigment dispersion and a method of preparing a pigment dispersion are described in detail.

The red radiation-sensitive composition contains a colorant which includes at least a red pigment, and it is preferable to include a red pigment such as C. I. Pigment Red 254 and C. I. Pigment Yellow 139.

The green radiation-sensitive composition contains a colorant which includes at least a green pigment, and it is preferable to include C. I. Pigment Green 36, and at least one of C. I. Pigment Yellow 185 or C. I. Pigment Yellow 150.

The blue radiation-sensitive composition contains a colorant which includes at least a blue pigment, and it is preferable to include C. I. Pigment Blue 15:6.

For preparing a colored radiation-sensitive composition, two or more colorants including a red pigment such as C. I. Pigment Red 254, which is preferably used for a red pixel, and C. I. Pigment Yellow 139 may be combined and used for producing a pigment dispersion. Similarly, two or more colorants including C. I. Pigment Green 36, which is preferably used for a green pixel, and at least one of C. I. Pigment Yellow 185 or C. I. Pigment Yellow 150 may be combined and used for producing a pigment dispersion.

Furthermore, two or more kinds of blue pigments such as C. I. Pigment Blue 15:6, which is preferably used for a blue pixel, may used for producing a pigment dispersion, either singly or in combination with a violet pigment.

When two or more pigment dispersions are used in combination, the components other than the pigment in the pigment dispersion and the method for preparing the pigment dispersion may be either the same as or different from each other.

The method for preparing a pigment dispersion is not specifically limited. Dispersion may be performed, for example, by mixing in advance a pigment and a pigment dispersant and dispersing in advance the mixture with a homogenizer and the like, and, next, by finely dispersing the product with a bead dispersing machine using zirconia beads and the like (for example, DISPERMAT manufactured by GETZMANN).

Pigment Dispersant

Examples of a pigment dispersant used for preparing a pigment dispersion include polymer dispersants (such as polyamide amine and salts thereof, polycarboxylic acids and salts thereof, high molecular-weight unsaturated acid esters, modified polyurethane, modified polyester, modified poly(meth)acrylate, (meth)acrylic copolymers, or naphthalene sulfonic acid formalin condensates), a surfactant such as polyoxyethylene alkyl phosphate, polyoxyethylene alkyl amine, and alkanol amine, and pigment derivatives.

The polymer dispersant may be further classified into a linear polymer, a terminal-modified polymer, a graft polymer, and a block polymer, in accordance with the structure thereof.

Examples of the terminal-modified polymer having an anchor moiety to the pigment surface include polymers having a phosphoric acid group at a terminal, such as those described in JP-A No. 3-112992 and Japanese Patent Application National Publication No. 2003-533455; polymers having a sulfonic acid group at a terminal, such as those described in JP-A No. 2002-273191; and polymers having a partial skeleton of an organic dye or a heterocycle such as those described in JP-A No. 9-77994. Further, polymers having terminals into which two or more anchor moieties to the pigment surface are introduced (such as an acidic group, a basic group, a partial skeleton of an organic dye or a heterocycle), such as those described in JP-A No. 2007-277514, exhibit favorable dispersion stability and are also preferable.

Examples of the graft polymer having an anchor moiety to the pigment surface include reaction products of poly(lower alkylene imine) and polyester, such as those described in JP-A No. 54-37082, Japanese Patent Application National Publication No. 8-507960, and JP-A No. 2009-258668; reaction products of polyallylamine and polyester, such as those described in JP-A No. 9-169821; copolymers of a macromonomer and a nitrogen-containing monomer, such as those described in JP-A No. 10-339949 and JP-A No. 2004-37986; graft polymers having a partial skeleton of an organic dye or a heterocycle, such as those described in JP-A No. 2003-238837, JP-A No. 2008-9426, and JP-A No. 2008-81732; and copolymers of a macromonomer and an acidic group-containing monomer, such as those described in JP-A No. 2010-106268. Amphoteric dispersant resins having a basic group and an acidic group, as described in JP-A No. 2009-203462, are particularly preferred from the viewpoints of dispersibility and dispersion stability of a pigment dispersion, and developability of a colored radiation-sensitive composition.

The macromonomer used for producing a graft polymer having an anchor moiety to the pigment surface by radical polymerization may be selected from known macromonomers, such as AA-6 (methyl polymethacrylate having a methacryloyl group as a terminal group), AS-6 (polystyrene having a methacryloyl group as a terminal group), AN-6S (styrene-acrylonitrile copolymer having a methacryloyl group as a terminal group) and AB-6 (polybutyl acrylate having a methacryloyl group as a terminal group) (trade names, all manufactured by Toagosei Co., Ltd.); PLACCEL FM5 (trade name, a product in which 5 molar equivalent of 8-caprolactone is added to 2-hydroxyethyl methacrylate), FA10L (trade name, a product in which 10 molar equivalent of 8-caprolactone is added to 2-hydroxyethyl acrylate) (all manufactured by Daicel Chemical Industries, Ltd.); and a polyester macromonomer described in JP-A No. 2-272009. Among these, polyester macromonomers having excellent flexibility and solvent compatibility are particularly preferred in view of dispersibility and dispersion stability of a pigment dispersion, and developability of a colored radiation-sensitive composition obtained by using the pigment dispersion. Furthermore, polyester macromonomers described in JP-A No. 2-272009 are most preferred.

The block polymer having an anchor moiety to the pigment surface is preferably those described in JP-A No. 2003-49110 and JP-A No. 2009-52010.

The pigment dispersants that may be used in the invention are also available as commercial products, and specific examples thereof include DISPERBYK-101 (polyamide amine phosphate), 107 (carboxylic acid ester), 110 (acid group-containing copolymer), 130 (polyamide), 161, 162, 163, 164, 165, 166, 170, and 2011 (high-molecular-weight copolymer), BYK-P 104, P105 (high-molecular-weight unsaturated polycarboxylic acid) (trade names, all manufactured by BYK Chemie); EFKA 4047, 4050, 4010, 4165 (polyurethane-based), EFKA 4330 to 4340 (block copolymer), 4400 to 4402 (modified polyacrylate), 5010 (polyester amide), 5765 (high-molecular-weight polycarboxylate), 6220 (fatty acid polyester), 6745 (phthalocyanine derivative), 6750 (azo pigment derivative) (trade names, all manufactured by EFKA); AJISPER PB821, PB822, PB880 and PB881 (trade names, all manufactured by Ajinomoto Fine-Techno Co., Inc.); FLOWLEN TG-710 (urethane oligomer), POLYFLOW No. 50E and No. 300 (acrylic copolymer) (trade names, all manufactured by Kyoeisha Chemical Co., Ltd.); DISPARLON KS-860, 873SN, 874, #2150 (aliphatic polycarboxylic acid), #7004 (polyether ester), DA-703-50, DA-705, DA-725 (trade names, all manufactured by Kusumoto Chemicals, Ltd.); DEMOL RN, N (naphthalene sulfonic acid formalin polycondensate), MS, C, SN-B (aromatic sulfonic acid formalin polycondensate), HOMOGENOL L-18 (high-molecular polycarboxylic acid), EMULGEN 920, 930, 935, and 985 (polyoxyethylene nonyl phenyl ether), ACETAMIN 86 (stearyl amine acetate) (trade names, all manufactured by Kao Corporation); SOLSPERSE 5000 (phthalocyanine derivative), 22000 (azo pigment derivative), 13240 (polyester amine), 3000, 17000, and 27000 (polymer having a functional moiety at a terminal), 24000, 28000, 32000, and 38500 (graft polymer) (trade names, all manufactured by the Lubrizol Corporation); NIKKOL T106 (polyoxyethylene sorbitan monooleate), MYS-IEX (polyoxyethylene monostearate) (trade names, all manufactured by Nikko Chemicals, Co., Ltd.); HINOACT T-8000E and the like (trade name, manufactured by Kawaken Fine Chemicals, Co., Ltd.); KP341 (organosiloxane polymer) (trade name, manufactured by Shin-Etsu Chemical Co., Ltd.); W001 (cationic surfactant, trade name, manufactured by Yusho Co., Ltd.); nonionic surfactants such as polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester; W004, W005, and W017 (anionic surfactants) (trade names, manufactured by Yusho Co., Ltd.); EFKA-46, EFKA-47, EFKA-47EA, EFKA POLYMER 100, EFKA POLYMER 400, EFKA POLYMER 401, EFKA POLYMER 450 (trade names, manufactured by Morishita and Co., Ltd.); DISPERSE AID 6, DISPERSE AID 8, DISPERSE AID 15, DISPERSE AID 9100 and the like (polymer dispersants) (trade names, manufactured by San Nopco Limited); ADEKA PLURONIC L31, F38, L42, L44, L61, L64, F68, L72, P95, F77, P84, F87, P94, L101, P103, F108, L121, and P-123 (trade names, manufactured by Adeka Corporation); and IONET S-20 (trade name, manufactured by Sanyo Chemical Industries, Ltd.).

These pigment dispersants may be used either singly or in a combination of two or more kinds thereof. In the invention, in particular, a combination of a pigment derivative and a polymer dispersant is preferably used. The pigment dispersant may be a combination of a terminal-modified polymer, graft polymer, or block copolymer having an anchor moiety to the pigment surface, as a pigment dispersant, with an alkali-soluble binder that is described below.

The content of the pigment dispersant in the pigment dispersion is preferably from 1 to 80 parts by mass, more preferably from 5 to 70 parts by mass, further preferably from 10 to 60 parts by mass, with respect to 100 parts by mass of a pigment.

Specifically, when a polymer dispersant is used, the amount thereof is preferably from 5 to 100 parts in terms of mass, more preferably from 10 to 80 parts by mass, with respect to 100 parts by mass of a pigment.

Pigment Derivative

It is preferable that the pigment dispersion further contains a pigment derivative.

The pigment derivative is, specifically, an organic pigment partially substituted with an acidic group, a basic group, or phthalimide methyl group. From the viewpoints of dispersibility and dispersion stability, the pigment derivative preferably contains an acidic group or a basic group.

Examples of organic pigments used for constituting a pigment derivative include diketopyrrolopyrrole pigment, azo pigment, phthalocyanine pigment, anthraquinone pigment, quinacridone pigment, dioxazine pigment, perinone pigment, perylene pigment, thioindigo pigment, isoindoline pigment, isoindolinone pigment, quinophthalone pigment, threne pigment, and metal complex pigment.

Further, preferred examples of the acidic group contained in the pigment derivative include sulfonic acid, carboxylic acid, and a quaternary ammonium salt thereof. More preferred examples thereof include a carboxylic acid group and a sulfonic acid group. Still more preferred examples thereof include a sulfonic acid group. Preferred examples of the basic group contained in the pigment derivative include an amino group. More preferred examples thereof include a tertiary amino group.

As a pigment derivative, quinoline pigment derivative, benzimidazolone pigment derivative, and isoindoline pigment derivative are preferable. Quinoline pigment derivative and benzimidazolone pigment derivative are more preferable. In particular, the pigment derivative having a structure represented by the following formula (P) is preferable.

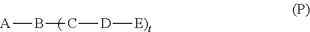

In Formula (P), A represents a partial structure selected from Formula (PA-1) to (PA-3) shown below; B represents a single bond or a linking group having valency of (t+1) (i.e., a (t+1)-valent linking group); C represents a single bond, —NH—, —CONH—, —CO₂—, —SO₂NH—, —O—, —S—, or —SO₂—; D represents a single bond, alkylene group, a cycloalkylene group, or an arylene group; E represents —SO₃H, —CO₂H, or —N(Rpa)(Rpb), in which Rpa and Rpb each independently represent an alkyl group, a cycloalkyl group, or an aryl group, and Rpa and Rpb may bind to each other to form a ring; and t represents an integer from 1 to 5.

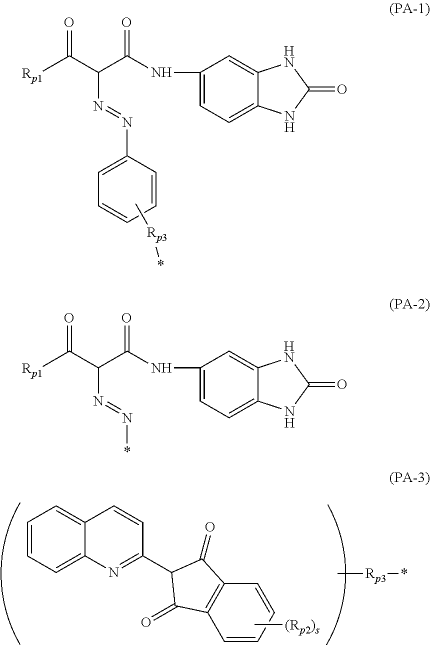

In Formulas (PA-1) and (PA-2), Rₚ₁ represents an alkyl group having 1 to 5 carbon atoms or an aryl group. In Formula (PA-3), Rₚ₁ represents a hydrogen atom, a halogen atom, an alkyl group, or a hydroxyl group; and s represents an integer from 1 to 4. In Formulas (PA-1) and (PA-3), Rₚ₃ represents a single bond, —NH—, —CONH—, —CO₂—, —SO₂NH—, —O—, —S—, or —SO₂—; and * represents a site for linking with B in Formula (P).

In Formula (P), Rₚ₁ is preferably a methyl group or a phenyl group, and a methyl group is most preferable. In Formula (PA-3), Rₚ₁ is preferably a hydrogen atom or a halogen atom, and a hydrogen atom and chlorine atoms are most preferable.

In Formula (P), examples of the (t+1)-valent linking group represented by B include an alkylene group, a cycloalkylene group, an arylene group, and a heteroarylene group. In particular, a linking group represented by any one of the following structural formulas (PA-4) to (PA-9) is particularly preferable.

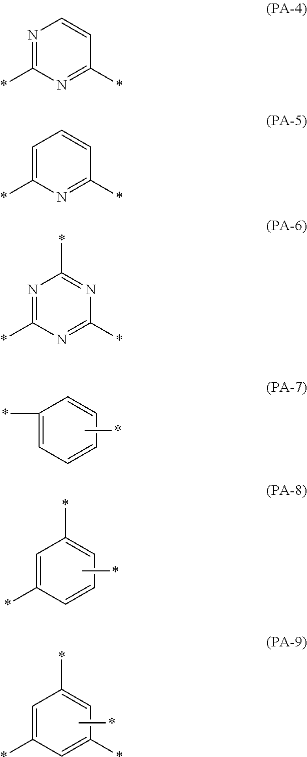

Among the structural formulas (PA-4) to (PA-9), a pigment derivative having a linking group of the structural formula (PA-5) or (PA-8) as B is preferable in that it provides more favorable dispersibility.

In Formula (P), examples of an alkylene group, a cycloalkylene group, and an arylene group that are represented by D include a methylene group, an ethylene group, a propylene group, a butylene group, a pentylene group, a hexylene group, a decylene group, a cyclopropylene group, a cyclobutylene group, a cyclopentylene group, a cyclohexylene group, a cyclooctylene group, a cyclodecylene group, a phenylene group, and a naphthylene group. Of these, D is particularly preferably an alkylene group, and most preferably an alkylene group having 1 to 5 carbon atoms.

In Formula (P), when E represents —N(Rpa)(Rpb), examples of the alkyl group, cycloalkyl group, or aryl group represented by Rpa or Rpb include a methyl group, an ethyl group, a propyl group, an isopropyl group, a butyl group, a sec-butyl group, a tert-butyl group, a pentyl group, an isopentyl group, a neopentyl group, a hexyl group, an octyl group, a decyl group, a cyclopropyl group, a cyclobutyl group, a cyclopentyl group, a cyclohexyl group, a cyclooctyl group, a cyclodecyl group, a phenyl group, and a naphthyl group. Rpa or Rpb is particularly preferably an alkyl group, and most preferably an alkyl group having 1 to 5 carbon atoms. In Formula (P), t is preferably 1 or 2.

The content of the pigment derivative in a pigment dispersion is preferably 1 to 50% by mass, and more preferably 3 to 30% by mass, with respect to the total mass of the pigment. The pigment derivative may be used either singly or in combination of two or more thereof.

Further, when a combination of pigment derivatives is used, the use amount (total amount) of the pigment derivatives is preferably within the range of 1 to 30 parts by mass, more preferably 3 to 20 parts by mass, and particularly preferably 5 to 15 parts by mass, with respect to 100 parts by mass of the pigment.

Organic Solvent

The pigment dispersion preferably contains an organic solvent.

The organic solvent is selected from the viewpoints of solubility of each component contained in the pigment dispersion or coatability of the pigment dispersion when it is applied to a colored radiation sensitive composition. Examples of the organic solvent usable in the pigment dispersion include those usable for preparation of a radiation-sensitive composition described below.

The content of the organic solvent in the pigment dispersion is preferably 50 to 95% by mass, and more preferably 70 to 90% by mass.

Polymer Compound

From the viewpoints of improving dispersion stability and controlling developability when the pigment dispersion is applied to a colored radiation sensitive composition, the pigment dispersion may further contain a polymer compound.

Examples of the polymer compound include polyamide amine and salts thereof, polycarboxylic acid and salts thereof, high molecular-weight unsaturated acid ester, modified polyurethane, modified polyester, modified poly(meth)acrylate, (meth)acrylic copolymers (in particular, a (meth)acrylate copolymer containing a carboxylic acid group and a polymerizable group in the side chain is preferable), and naphthalene sulfonic acid formalin condensates. The polymer material is adsorbed onto the surface of the pigment, and acts so as to prevent reaggregation of the pigment. Accordingly, a terminal-modified polymer, graft polymer or block polymer having an anchor moiety for a pigment surface is preferably used as the polymer material. For example, there is a graft copolymer containing, as a copolymerization unit, a monomer with heterocycle and a polymerizable oligomer with an ethylenically unsaturated bond.

Examples of other polymer material include polyamide amine phosphate salts, high molecular-weight unsaturated polycarboxylic acid, polyether ester, aromatic sulfonic acid formalin condensate, polyoxyethylene nonylphenyl ether, polyester amine, polyoxyethylene sorbitan monooleate, and polyoxyethylene monostearate.

The polymer material may be used either singly or in combination of two or more thereof.

The content of the polymer material in the pigment dispersion is preferably 20 to 80% by mass, more preferably 30 to 70% by mass, and still more preferably 40 to 60% by mass, with respect to the pigment.

Components to be included in Colored Radiation-Sensitive Composition Polymerizable Compound

The colored radiation sensitive-composition preferably includes a polymerizable compound.

Specifically, the polymerizable compound is selected from a compound having at least one terminal ethylenically unsaturated bond, and preferably two or more, terminal ethylenically unsaturated bonds. In particular, a tetra-functional or higher-functional polyfunctional polymerizable compound is preferable, and a penta-functional or higher-functional compound is more preferable.

These compounds are widely known in the field of the art, and any one of these compounds may be used in the invention without being particularly limited. The compounds may have a chemical form selected from a monomer, a prepolymer (a dimer, a trimer or an oligomer), a mixture thereof, or a multimer thereof. In the invention, the polymerizable compound may be used either singly or in combination of two or more thereof.

More specifically, examples of the monomer and prepolymer thereof include unsaturated carboxylic acid (for example, acrylic acid, methacrylic acid, itaconic acid, crotonic acid, isocrotonic acid, and maleic acid) or esters, amides, or multimers thereof. Preferred examples include an ester between unsaturated carboxylic acid and aliphatic polyhydric alcohol compound, amides between unsaturated carboxylic acid and aliphatic polyhydric amine compound, and multimers thereof. Further, addition product between unsaturated carboxylic acid ester or amides having a nucleophilic substituent group such as a hydroxyl group, an amino group, or a mercapto group and isocyanates or epoxy compound of mono functionality or poly functionality, or a dehydration condensation product with a mono functional or poly functional carboxylic acid is also suitably used. Further, an addition product between unsaturated carboxylic acid ester or amides having an electrophilic substituent group such as an isocyanate group and an epoxy group and mono functional or poly functional alcohols, amines, or thiols, or a substitution product between unsaturated carboxylic acid ester or amides having a leaving substituent group such as a halogen group or a tosyl oxy group and mono functional or poly functional alcohols, amines, an thiols can be also suitably used. As an another example, it is also possible to use unsaturated phosphonic acid, a vinyl benzene derivative such as styrene, or a group of compound substituted with vinyl ether or allyl ether instead of the unsaturated carboxylic acid described above.

Specific examples of the compound that can be used in the invention include the compounds described in paragraph Nos. 0095 to 0108 of JP-A No. 2009-288705.

Further, a compound having an ethylenically unsaturated group which has boiling point of 100° C. or higher under atmospheric pressure and at least one addition-polymerizable ethylene group is also preferable as a copolymerizable compound. Examples thereof include monofunctional acrylate or methacrylate such as polyethylene glycol mono(meth)acrylate, polypropylene glycol mono(meth)acrylate, and phenoxy ethyl(meth)acrylate; and polyfunctional acrylate or methacrylate such as polyethylene glycol di(meth)acrylate, trimethylol ethane tri(meth)acrylate, neopentyl glycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol(meth)acrylate, trimethylol propane tri(acryloyloxy propyl)ether, tri(acryloyloxyethyl)isocyanurate, glycerin or trimethylolethane that are obtained by adding ethylene oxide or propylene oxide to a polyfunctional alcohol and modifying with (meth)acrylate, urethane(meth)acrylates such as those described in Japanese Patent Application Publication (JP-B) No. 48-41708, JP-B No. 50-6034, or JP-A No. 51-37193, polyester acrylates such as those described in JP-A No. 48-64183, JP-B No. 49-43191, or JP-B No. 52-30490, and epoxy acrylates which are reaction products of an epoxy resin and (meth)acrylic acid, and a mixture thereof.

There is also polyfunctional (meth)acrylate which is obtained by reacting polyfunctional carboxylic acid and a cyclic ether group like glycidyl(meth)acrylate and a compound having an ethylenically unsaturated group.

Further, as a preferred polymerizable compound, a compound having two or more of an ethylenically unsaturated group and a fluorene ring as described in JP-A No. 2010-160418, JP-A No. 2010-129825, or Japanese Patent No. 4364216 or a cardo resin may be also used.

As a compound which has at least one addition-polymerizable ethylenically unsaturated group and boiling point of 100° C. or higher under atmospheric pressure, the compound described in paragraph Nos. 0254 to 0257 of JP-A No. 2008-292970 is also suitable.

In addition to those described above, the radical polymerizable monomer represented by Formulas (MO-1) to (MO-5) may be also suitably used. In the formula, when T is an oxyalkylene group, the terminal at carbon atom side is bonded to R.

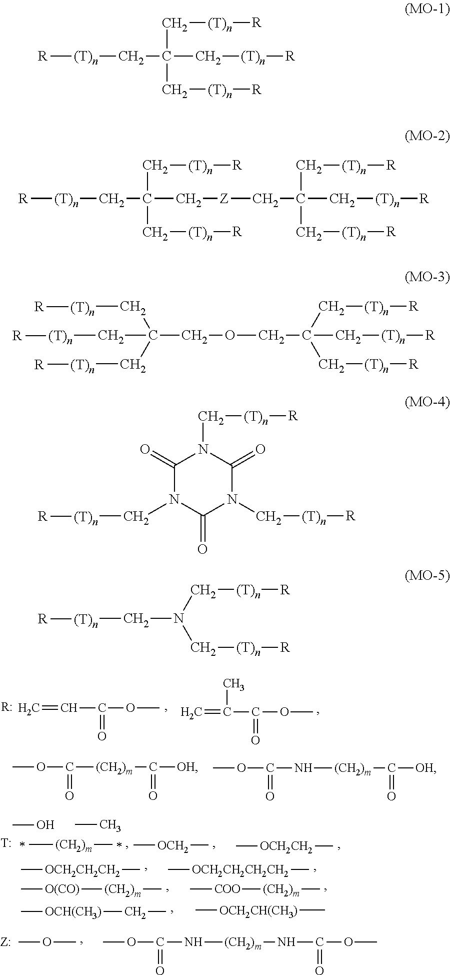

In the formula shown above, n is from 0 to 14; m is from 1 to 8; plural R's in a molecule may be the same as or different from each other; and plural T's in a molecule may be the same as or different from each other.

In each of the polymerizable compound represented by any one of Formulas (MO-1) to (MO-5), at least one of plural R's is a group represented by —OC(═O)CH═CH₂ or —OC(═O)C(CH₃)═CH₂.

Specific examples of the polymerizable compound represented by any one of Formulas (MO-1) to (MO-5) include the compounds described in paragraph Nos. 0248 to 0251 of JP-A No. 2007-269779.

Further, a compound obtained by adding ethylene oxide or propylene oxide to the polyfunctional alcohol described with the specific examples of Formulas (1) and (2) in JP-A No. 10-62986, followed by conversion into (meth)acrylate may be also used as a polymerizable compound.

Among them, preferred examples of the polymerizable compound include dipentaerythritol triacrylate (commercially available as KAYARAD D-330, trade name, manufactured by Nippon Kayaku Co., Ltd.), dipentaerythritol tetraacrylate (commercially available as KAYARAD D-320, trade name, manufactured by Nippon Kayaku Co., Ltd.), dipentaerythritol penta(meth)acrylate (commercially available as KAYARAD D-310, trade name, manufactured by Nippon Kayaku Co., Ltd.), dipentaerythritol hexa(meth)acrylate (commercially available as KAYARAD DPHA, trade name, manufactured by Nippon Kayaku Co., Ltd.), and compounds obtained by modifying the commercially-available compound so that a (meth)acryloyl group thereof is linked via an ethylene glycol or propylene glycol residue. An oligomer of the acrylates may be also used. Hereinbelow, preferred embodiments of the polymerizable compound are described.

The polymerizable compound may be a polyfunctional monomer having an acidic group such as a carboxyl group, a sulfonic acid group, or a phosphoric acid group. When the ethylenic compound has an unreacted carboxyl group like in a mixture described above, the ethylenic compound may be used as it is. However, if necessary, an acidic group may be introduced by reacting the hydroxyl group of an ethylenic compound with a non-aromatic carboxylic anhydride. For such case, specific examples of non-aromatic carboxylic anhydride include tetrahydrophthalic anhydride, alkylated tetrahydrophthalic anhydride, hexahydrophthalic anhydride, alkylated hexahydrophthalic anhydride, succinic anhydride, and maleic anhydride.

In the invention, the monomer having an acidic group is preferably a polyfunctional monomer which is an ester of aliphatic polyhydroxy compound and unsaturated carboxylic acid and has an acidic group by reacting the non-reacted hydroxyl group of an aliphatic polyhydroxy compound with non-aromatic carboxylic anhydride. More preferably, it is an ester in which the aliphatic polyhydroxy compound is pentaerythritol and/or dipentaerythritol. Examples of commercially available product include polybasic acid-modified acryl oligomer M-510, M-520, or the like (trade names, manufactured by TOAGOSEI CO., LTD.).

In the colored radiation-sensitive composition of the invention, the polymerizable compound may be used singly. However, in terms of production of a polymerizable compound, since it is difficult to obtain a single compound, the polymerizable compounds may be also used in combination of two or more thereof.

Further, as a polymerizable compound, a polyfunctional monomer having no acidic group and a polyfunctional monomer having an acidic group may be used in combination, if necessary.

Preferred acid value of the polyfunctional monomer having an acidic group is from 0.1 to 40 mg KOH/g, and particularly preferably 5 to 30 mg KOH/g. When the acid value of the polyfunctional monomer is excessively low, development dissolution property is lowered. On the other hand, when the acid value is excessively high, production or handling becomes difficult so that photopolymerization property is lowered and curing property such as surface smoothness of a pixel or the like is deteriorated. Thus, when two or more types of polyfunctional monomers having different acidic groups are used in combination or a polyfunctional monomer having no acidic group is used in combination therewith, it is preferable that the acidic group in the entire polyfunctional monomers is adjusted to be within the range described above.

It is also preferable that a polyfunctional monomer having a caprolactone structure is included as a polymerizable compound.

The polymerizable compound having a caprolactone structure is not specifically limited, as long as it has a caprolactone structure within the molecule thereof. Examples thereof include ε-caprolactone-modified polyfunctional (meth)acrylates which are obtained by esterification of a polyhydric alcohol such as trimethylol ethane, ditrimethylol ethane, trimethylol propane, ditrimethylol propane, pentaerythritol, dipentaerythritol, tripentaerythritol, glycerin, diglycerol, or trimethylol melamine, with (meth)acrylate and β-caprolactone. Among them, the polyfunctional monomer having a caprolactone structure represented by Formula (Z-1) below is preferable.

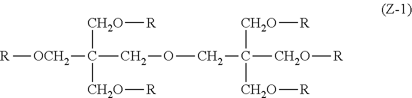

In Formula (Z-1), all of the six R's are each a group represented by Formula (Z-2) below, or 1 to 5 of the six R's are a group represented by Formula (Z-2) and the remainder thereof is a group represented by Formula (Z-3) below.

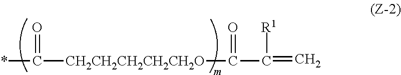

In Formula (Z-2), R¹ represents a hydrogen atom or a methyl group; m represents a number of 1 or 2; and “*” represents a bonding arm.

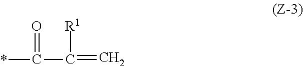

In Formula (Z-3), R¹ represents a hydrogen atom or a methyl group. and “*” represents a bonding arm.

The polyfunctional monomer having a caprolactone structure is commercially available as KAYARAD DPCA series (trade name, manufactured by Nippon Kayaku Co., Ltd.), for example. Examples thereof include DPCA-20 (a compound in which m in Formulas (1) to (3) is 1, the number of groups represented by Formula (2) is 2, and all R¹'s are a hydrogen atom), DPCA-30 (a compound in which m in Formulas (1) to (3) is 1, the number of groups represented by Formula (2) is 3, and all R¹'s are a hydrogen atom), DPCA-60 (a compound in which m in Formulas (1) to (3) is 1, the number of groups represented by Formula (2) is 6, and all R¹'s are a hydrogen atom), and DPCA-120 (a compound in which m in Formulas (1) to (3) is 2, the number of groups represented by Formula (2) is 6, and all R¹'s are a hydrogen atom).

In the invention, the polyfunctional monomer having a caprolactone structure may be used either singly or as a mixture of two or more thereof.

In the invention, the polymerizable compound is preferably a polymerizable compound which contains an alkyleneoxy group having 2 or more carbon atoms (such as an ethyleneoxy group, a propyleneoxy group, or a butyleneoxy group).

Among the polymerizable compounds which contain an alkyleneoxy group having 2 or more carbon atoms, at least one selected from the group consisting of the compounds represented by Formula (i) or (ii) below is particularly preferable.

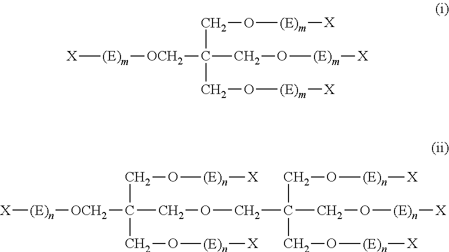

In Formulas (i) and (ii), E's each independently represent —((CH₂)_{y}CH₂O)— or —((CH₂)_{y}CH(CH₃)O)—, in which y independently represents an integer from 0 to 10; and X's independently represents an acryloyl group, a methacryloyl group, a hydrogen atom, or a carboxyl group.

In Formula (1), the total number of acryloyl groups and methacryloyl groups represented by X is 3 or 4; m's each independently represent an integer from 0 to 10; and the sum of the numbers represented by m's is an integer from 0 to 40, provided that any one of X's is a carboxyl group when the sum of the numbers represented by m's is 0.

In Formula (ii), the total number of acryloyl groups and methacryloyl groups represented by X is 5 or 6; n's each independently represent an integer from 0 to 10; and the sum of the numbers represented by n's is an integer from 0 to 60, provided that any one of X's is a carboxyl group when the sum of the numbers represented by n's is 0.

In Formula (i), m's are each preferably an integer from 0 to 6, and more preferably an integer from 0 to 4. Further, the sum of the numbers represented by respective m's is preferably an integer from 2 to 40, more preferably an integer from 2 to 16, and still more preferably an integer from 4 to 8.

In Formula (ii), n's are each preferably an integer from 0 to 6, and more preferably an integer from 0 to 4. Further, the sum of the numbers represented by respective n's is preferably an integer from 3 to 60, more preferably an integer from 3 to 24, and still more preferably an integer from 6 to 12.

It is preferable that the terminal at oxygen atom side of —((CH₂)_{y}CH₂O)— or —((CH₂)_{y}CH(CH₃)O)— in Formula (i) or (ii) is bonded to X.

The compound represented by Formula (i) or (ii) may be used either singly or in combination of two or more thereof. In particular, it is preferable that six X's in Formula (ii) are an acryloyl group.

The compounds represented by Formula (i) or (ii) may be synthesized by a conventionally known process including: binding an open-ring skeleton of ethylene oxide or propylene oxide to pentaerythritol or dipentaerythritol by a ring-opening addition reaction; and introducing a (meth)acryloyl group by a reaction between (meth)acryloyl chloride and a terminal hydroxyl group of the open-ring skeleton, for example. Each process is a well known process, and a person skilled in the art may easily synthesize the compound represented by Formula (i) or (ii).

Among the compounds represented by Formula (i) or (ii), the pentaerythritol derivative and/or dipentaerythritol derivative are more preferable.

Specific examples thereof include a compound represented by the following formulas (a) to (f) (hereinbelow, also referred to as the “exemplary compounds (a) to (f)”), and among them, the exemplary compounds (a), (b), (e), and (f) are preferable.

In particular, the exemplary compound (b) is effective as a polymerizable compound, and it enables significant improvement in the effects of the invention.

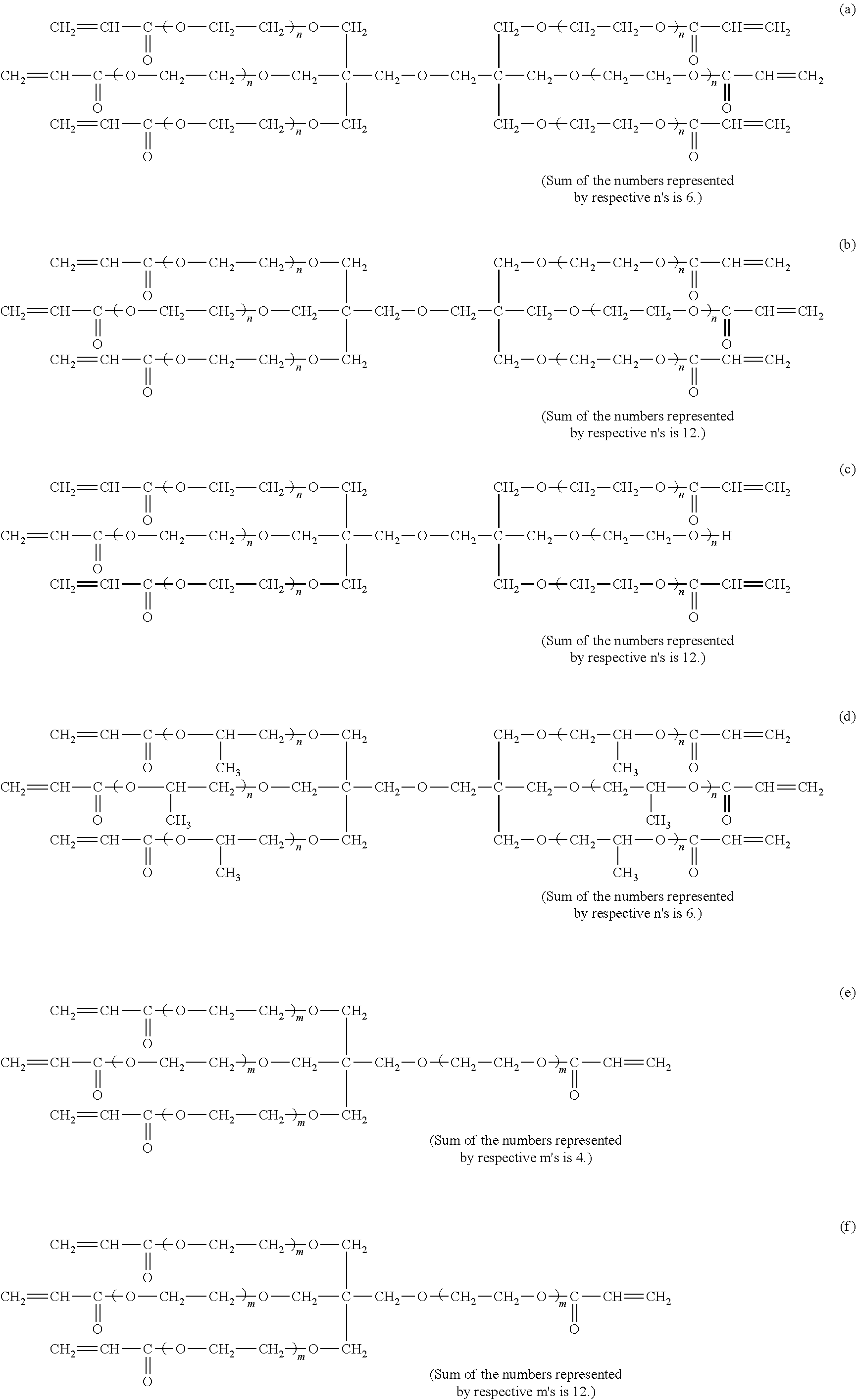

Examples of the commercially available product of a polymerizable compound represented by Formula (i) or (ii) include SR-494 (trade name, manufactured by Sartomer Company, Inc.), which is tetrafunctional acrylate having four ethylene oxy chains, and DPCA-60 that is hexafunctional acrylate having six pentyleneoxy chains, and TPA-330 that is trifunctional acrylate having three isobutyleneoxy chains (trade names, manufactured by Nippon Kayaku Co., Ltd.).

Those described as photocurable monomers and oligomers described in Journal of The Adhesion Society of Japan Vol. 20, No. 7 (pp. 300-308) may also be used as a polymerizable compound.

The content of the polymerizable compound in the colored radiation-sensitive composition of the invention is preferably from 2 to 50% by mass, more preferably from 2 to 30% by mass, and still more preferably from 2 to 25% by mass, with respect to the total solid content of the composition.

Photopolymerization Initiator

The radiation-sensitive composition of the invention preferably contains a photopolymerization initiator.

In the invention, those known as a photopolymerization initiator as described below may be used as a photopolymerization initiator (hereinbelow, it may be abbreviated as a “polymerization initiator”).

The photopolymerization initiator is not specifically limited as long as it has an ability of initiating polymerization of the polymerizable compound, and it may be suitably selected from known photopolymerization initiators. For examples, those having sensitivity for light in UV range to visible range are preferable. The photopolymerization initiator may also be an activating agent which has a certain interaction with a photo-excited sensitizer to produce active radicals or an initiator for initiating cationic polymerization depending on type of a monomer.

Further, the photopolymerization initiator contains at least one compound having molar absorption coefficient of about 50 within the range of about 300 nm to 800 nm (more preferably, 330 nm to 500 nm).

Examples of the photopolymerization initiator include halogenated hydrocarbon derivatives (for example, those having a triazine skeleton and those having an oxadiazole skeleton), an acyl phosphine compound such as acyl phosphine oxide, hexaaryl biimidazole, an oxime compound such as oxime derivatives, an organic peroxide compound, a thio compound, a ketone compound, an aromatic onium salt, a ketooxime ether, an amino acetophenone compound, and a hydroxy acetophenone. Of these, an oxime compound is preferable.

Examples of the halogenated hydrocarbon compound having a triazine skeleton include a compound described in Bull. Chem. Soc. Japan, 42, 2924 (1969) by Wakabayashi, et. al., a compound described in GB Patent No. 1388492, a compound described in JP-A No. 53-133428, a compound described in German Patent No. 3337024, a compound described in J. Org. Chem. 29, 1527 (1964) by F. C. Schaefer, et. al., a compound described in JP-A No. 62-58241, a compound described in JP-A No. 5-281728, a compound described in JP-A No. 5-34920, and a compound described in U.S. Pat. No. 4,212,976.

Examples of the compound described in U.S. Pat. No. 4,212,976 include a compound having an oxadiazole skeleton (for example, 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole; 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloromethyl-5-(1-naphthyl)-1,3,4-oxadiazole, 2-trichloromethyl-5-(4-n-butoxy styryl)-1,3,4-oxadiazole, and 2-tribromomethyl-5-styryl-1,3,4-oxadiazole).

Examples of the polymerization initiator other than those described above include an acridine derivative (for example, 9-phenyl acridine and 1,7-bis(9,9′-acridinyl)heptane), N-phenylglycine, a polyhalogen compound (for example, carbon tetrabromide, phenyl tribromomethyl sulfone, phenyl trichloromethyl ketone), coumarines (for example, 3-(2-benzofuranoyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonyl bis(5,7-di-n-propoxycoumarin), 3,3′-carbonyl bis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, 7-benzotriazol-2-yl coumarin, and a coumarin compound described in JP-ANo. 5-19475, JP-ANo. 7-271028, JP-A No. 2002-363206, JP-ANo. 2002-363207, JP-A No. 2002-363208, JP-A No. 2002-363209, or the like), acylphosphine oxides (for example, bis(2,4,6-trimethylbenzoyl)-phenylphosphine oxide, bis(2,6-dimethoxy benzoyl)-2,4,4-trimethyl-pentylphenylphosphine oxide, Lucirin TPO, or the like), metallocenes (for example, bis(η5-2,4-cyclopentadien-1-yl)-bis(2,6-difluoro-3-(1H-pyrrole-1-yl)-phenyl)titanium, η5-cyclopentadienyl-η6-cumenyl-iron (1+)-hexafluorophosphate(1−) or the like), and a compound described in JP-A No. 53-133428, JP-B No. 57-1819, JP-B No. 57-6096, or U.S. Pat. No. 3,615,455.

Examples of the ketone compound include benzophenone, 2-methyl benzophenone, 3-methyl benzophenone, 4-methyl benzophenone, 4-methoxy benzophenone, 2-chloro benzophenone, 4-chloro benzophenone, 4-bromo benzophenone, 2-carboxy benzophenone, 2-ethoxycarbonyl benzophenone, benzophenone tetracarboxylic acid or tetramethyl ester thereof, 4,4′-bis(dialkylamino)benzophenones (for example, 4,4′-bis(dimethylamino)benzophenone, 4,4′-bisdicyclohexylamino)benzophenone, 4,4′-bis(diethyl amino)benzophenone, 4,4′-bis(dihydroxyethylamino)benzophenone, 4-methoxy-4′-dimethylamino benzophenone, 4,4′-dimethoxy benzophenone, 4-dimethylamino benzophenone, 4-dimethylamino acetophenone), benzyl, anthraquinone, 2-t-butylanthraquinone, 2-methyl anthraquinone, phenanthraquinone, xanthone, thioxanthone, 2-chloro-thioxanthone, 2,4-diethyl thioxanthone, fluorenone, 2-benzyl-dimethylamino-1-(4-morpholino phenyl)-1-butanone, 2-methyl-1-[4-(methylthio)phenyl]-2-morpholino-1-propanone, 2-hydroxy-2-methyl-[4-(1-methylvinyl)phenyl]propanol oligomer, benzoin, benzoin ethers (for example, benzoin methyl ether, benzoin ethyl ether, benzoin propyl ether, benzoin isopropyl ether, benzoin phenyl ether, and benzyl dimethyl ketal), acridone, chloro acridone, N-methyl acridone, N-butyl acridone, and N-butyl-chloro acridone.

As a polymerization initiator, a hydroxy acetophenone compound, an amino acetophenone compound, or an acyl phosphine compound may be also suitably used. More specifically, the amino acetophenone initiator described in JP-A No. 10-291969 or the acyl phosphine oxide initiator described in Japanese Patent No. 4225898 may be also used.

Examples of the hydroxy acetophenone initiator usable in the invention include IRGACURE-184, DAROCUR-1173, IRGACURE-500, IRGACURE-2959, and IRGACURE-127 (trade names, all manufactured by BASF). Examples of the amino acetophenone initiator usable in the invention include IRGACURE-907, IRGACURE-369, and IRGACURE-379 (trade names, all manufactured by BASF). As an acetophenone initiator, a compound having absorption wavelength matched to a light source with long wavelength such as 365 nm or 405 nm as described in JP-A No. 2009-191179 may be also used. Examples of the acyl phosphine initiator usable in the invention include IRGACURE-819 and DAROCUR-TPO (trade names, all manufactured by BASF).

More preferred examples of the polymerization initiator include an oxime compound. Specific examples of oxime compound include a compound described in JP-A No. 2001-233842, a compound described in JP-A No. 2000-80068, and a compound described in JP-A No. 2006-342166.

Examples of the oxime compound such as an oxime derivative suitably used as a polymerization initiator in the invention include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Examples of the oxime compound include compounds such as those described in J. C. S. Perkin II (1979) 1653-1660, J. C. S. Perkin II (1979) 156-162, Journal of Photopolymer Science and Technology (1995) 202-232 or JP-A No. 2000-66385; and compounds such as those described in JP-A No. 2000-80068, Japanese Patent Application National Publication No. 2004-534797, or JP-ANo. 2006-342166.

Examples of the commercially-available product include IRGACURE OXE-01 (trade name, manufactured by BASF) and IRGACURE OXE-02 (trade name, manufactured by BASF).

As the oxime compounds other than those described above, a compound described in Japanese Patent Application National Publication No. 2009-519904 in which an oxime is linked to the N position of carbazole, a compound described in U.S. Pat. No. 7,626,957 in which a hetero substituent group is introduced to a benzophenone moiety, a compound described in JP-A No. 2010-15025 and US Patent Application Laid-Open No. 2009-292039 in which a nitro group is introduced to a pigment moiety, a ketooxime compound described in International Publication No. 2009-131189, a compound described in U.S. Pat. No. 7,556,910 in which a triazine skeleton and an oxime skeleton are contained in the same molecule, and a compound described in JP-A No. 2009-221114 which has absorption maximum at 405 nm and has good sensitivity for g ray light source, may be also used.

The cyclic oxime compounds described in JP-A No. 2007-231000 or JP-A No. 2007-322744 may be also suitably used. Among the cyclic oxime compounds, a cyclic oxime compound fused to a carbazole colorant as described in JP-A No. 2010-32985 or JP-A No. 2010-185072 is particularly preferable in terms of sensitivity increase since it has a high light absorption property.

Further, a compound described in JP-A No. 2009-242469 in which an unsaturated bond is contained at specific part of an oxime compound may be also suitably used because it is capable of achieving sensitivity increase by regeneration of active radical from polymerization inactive radical.

Most preferable examples include an oxime compound having a specific substituent group as described in JP-A No. 2007-269779 and an oxime compound having a thioaryl group as described in JP-A No. 2009-191061.

Specifically, the compound represented by the following Formula (OX-1) is preferred as an oxime compound used in the invention. Regarding the N—O bond in oxime, it may be an oxime compound with (E) form, an oxime compound with (Z) form, or a mixture of (E) form and (Z) form.

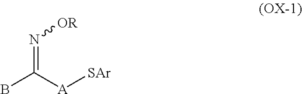

In Formula (OX-1), R and B each independently represent a monovalent substituent group, A represents a divalent organic group, and Ar represents an aryl group.

The monovalent substituent group represented by R in Formula (OX-1) is preferably a monovalent non-metal atomic group.

Examples of the monovalent non-metal atomic group include an alkyl group, an aryl group, an acyl group, an alkoxycarbonyl group, an aryloxy carbonyl group, a heterocyclic group, an alkylthio carbonyl group, and an arylthio carbonyl group. They may also have one or more substituent groups. Further, the substituent groups may further be substituted with an additional substituent group.

Examples of the substituent group include a halogen atom, aryloxy group, an alkoxycarbonyl group, or an aryloxy carbonyl group, an acyloxy group, an acyl group, an alkyl group, and an aryl group.

Preferred examples of the alkyl group which may have a substituent group include an alkyl group having 1 to 30 carbon atoms, and specific examples thereof include a methyl group, an ethyl group, a propyl group, a butyl group, a hexyl group, an octyl group, a decyl group, a dodecyl group, an octadecyl group, an isopropyl group, an isobutyl group, a sec-butyl group, a t-butyl group, a 1-ethylpentyl group, a cyclopentyl group, a cyclohexyl group, a trifluoromethyl group, a 2-ethylhexyl group, a phenacyl group, a 1-naphthoylmethyl group, a 2-naphthoylmethyl group, a 4-methylsulfanylphenacyl group, a 4-phenylsulfanylphenacyl group, a 4-dimethylaminophenacyl group, a 4-cyanophenacyl group, a 4-methylphenacyl group, a 2-methylphenacyl group, a 3-fluorophenacyl group, a 3-trifluoromethylphenacyl group, and a 3-nitrophenacyl group.

Preferred examples of the aryl group which may have a substituent group include an aryl group having 6 to 30 carbon atoms, and specific examples thereof include a phenyl group, a biphenyl group, a 1-naphthyl group, a 2-naphthyl group, a 9-anthryl group, a 9-phenanthryl group, a 1-pyrenyl group, a 5-naphthacenyl group, a 1-indenyl group, a 2-azulenyl group, a 9-fluorenyl group, a terphenyl group, a quarter phenyl group, an o-tolyl group, a m-tolyl group, a p-tolyl group, a xylyl group, an o-cumenyl group, a m-cumenyl group, and a p-cumenyl group, a mesityl group, a pentaenyl group, a binaphthenyl group, a ternaphthenyl group, a quarter naphthalenyl group, a heptalenyl group, a biphenylenyl group, an indacenyl group, a fluoranthenyl group, an acenaphthylenyl group, an aceanthrylenyl group, a phenalenyl group, a fluorenyl group, an anthryl group, a bianthracenyl group, a teranthracenyl group, a quarter anthracenyl group, an anthraquinolyl group, a phenanthryl group, a triphenylenyl group, a pirenyl group, a chrysenyl group, a naphthacenyl group, a pleiadenyl group, a picenyl group, a perylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, and an ovalenyl group.

Preferred examples of an acyl group which may have a substituent group include an acyl group having 2 to 20 carbon atoms, and specific examples thereof include an acetyl group, a propanoyl group, a butanoyl group, a trifluoro acetyl group, a pentanoyl group, a benzoyl group, a 1-naphthoyl group, a 2-naphthoyl group, a 4-methylsulfanylbenzoyl group, a 4-phenylsulfanylbenzoyl group, a 4-dimethylaminobenzoyl group, a 4-diethylaminobenzoyl group, a 2-chlorobenzoyl group, a 2-methylbenzoyl group, a 2-methoxybenzoyl group, a 2-butoxybenzoyl group, a 3-chlorobenzoyl group, a 3-trifluoromethylbenzoyl group, a 3-cyanobenzoyl group, a 3-nitrobenzoyl group, a 4-fluorobenzoyl group, a 4-cyanobenzoyl group, and a 4-methoxybenzoyl group.

Preferred examples of an alkoxycarbonyl group which may have a substituent group include an alkoxycarbonyl group having 2 to 20 carbon atoms, and specific examples thereof include a methoxycarbonyl group, an ethoxycarbonyl group, a propoxycarbonyl group, a butoxycarbonyl group, a hexyloxycarbonyl group, an octyloxycarbonyl group, a decyloxycarbonyl group, an octadecyloxycarbonyl group, and a trifluoromethyloxycarbonyl group.

Specific examples of an aryloxycarbonyl group which may have a substituent group include a phenoxycarbonyl group, a 1-naphthyloxycarbonyl group, a 2-naphthyloxycarbonyl group, a 4-methylsulfanylphenyloxycarbonyl group, a 4-phenylsulfanylphenyloxycarbonyl group, a 4-dimethylaminophenyloxycarbonyl group, a 4-diethylaminophenyloxycarbonyl group, a 2-chlorophenyloxycarbonyl group, a 2-methylphenyloxycarbonyl group, a 2-methoxyphenyloxycarbonyl group, a 2-butoxyphenyloxycarbonyl group, a 3-chlorophenyloxycarbonyl group, a 3-trifluoromethylphenyloxycarbonyl group, a 3-cyanophenyloxycarbonyl group, a 3-nitrophenyloxycarbonyl group, a 4-fluorophenyloxycarbonyl group, a 4-cyanophenyloxycarbonyl group, and a 4-methoxyphenyloxycarbonyl group.

Preferred examples of the heterocyclic group which may have a substituent group include an aromatic or aliphatic heterocycle containing a nitrogen atom, an oxygen atom, a sulfur atom, or a phosphorus atom.

Specific examples thereof include a thienyl group, a benzo[b]thienyl group, a naphtho[2,3-b]thienyl group, a thianthrenyl group, a furyl group, a pyranyl group, an isobenzofuranyl group, a chromenyl group, a xanthenyl group, a phenoxathiinyl group, a 2H-pyrrolyl group, a pyrrolyl group, an imidazolyl group, a pyrazolyl group, a pyridyl group, a pyrazinyl group, a pyrimidinyl group, a pyridazinyl group, an indolidinyl group, an isoindolyl group, a 3H-indolyl group, an indolyl group, a 1H-indazolyl group, a purinyl group, a 4H-quinolidinyl group, an isoquinolyl group, a quinolyl group, a phthalazinyl group, a naphthylidinyl group, a quinoxalinyl group, a quinazolinyl group, a cinnolynyl group, a pteridinyl group, a 4aH-carbazolyl group, a carbazolyl group, a β-carbolinyl group, a phenanthridinyl group, an acridinyl group, a perimidinyl group, a phenanthrolinyl group, a phenadinyl group, a phenarsazinyl group, an isothiazolyl group, a phenothiadinyl group, an isooxazolyl group, a furazanyl group, a phenoxazinyl group, an isochromanyl group, a chromanyl group, a pyrrolidinyl group, a pyrrolinyl group, an imidazolidinyl group, an imidazolinyl group, a pyrazolidinyl group, a pyrazolinyl group, a piperidyl group, a piperazinyl group, an indolynyl group, an isoindolinyl group, a quinuclidinyl group, a morpholinyl group, and a thioxantolyl group.

Specific example of the alkylthiocarbonyl group which may have a substituent group include a methylthiocarbonyl group, a propylthiocarbonyl group, a butylthiocarbonyl group, a hexylthiocarbonyl group, an octylthiocarbonyl group, a decylthiocarbonyl group, an octadecylthiocarbonyl group, and a trifluoromethylthiocarbonyl group.

Specific example of the arylthiocarbonyl group which may have a substituent group include a 1-naphthylthiocarbonyl group, a 2-naphthylthiocarbonyl group, a 4-methylsulfanylphenylthiocarbonyl group, a 4-phenylsulfanylphenylthiocarbonyl group, a 4-dimethylaminophenylthiocarbonyl group, a 4-diethylaminophenylthiocarbonyl group, a 2-chlorophenylthiocarbonyl group, a 2-methylphenylthiocarbonyl group, a 2-methoxyphenylthiocarbonyl group, a 2-butoxyphenylthiocarbonyl group, a 3-chlorophenylthiocarbonyl group, a 3-trifluoromethylphenylthiocarbonyl group, a 3-cyanophenylthiocarbonyl group, a 3-nitrophenylthiocarbonyl group, a 4-fluorophenylthiocarbonyl group, a 4-cyanophenylthiocarbonyl group, and a 4-methoxyphenylthiocarbonyl group.

In Formula (OX-1), examples of the monovalent substituent group represented by B include an aryl group, a heterocyclic group, an aryl carbonyl group, and a heterocyclic carbonyl group, which may each have one or more substituent groups. Examples of the substituent groups include those described above. Further, the substituent groups may be further substituted with an additional substituent group.

Among them, particularly preferred are the structures shown below.

In the structures shown below, Y, X, and n have the same definitions as Y, X, and n, respectively, in Formula (OX-2). Preferred examples thereof are also the same.

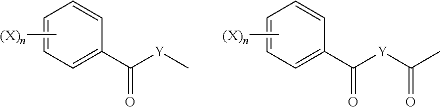

In Formula (OX-1), examples of the divalent organic group represented by A include an alkylene group having 1 to 12 carbon atoms, a cycloalkylene group having 1 to 12 carbon atoms, and an alkynylene group having 1 to 12 carbon atoms. These groups may each have one or more substituent groups. Examples of the substituent groups include those described above. Further, the substituent groups may be substituted with an additional substituent group.

Among them, from the viewpoints of enhancing sensitivity and inhibiting coloration by heating over time, preferred examples of A in Formula (OX-1) include an unsubstituted alkylene group, an alkylene group substituted with an alkyl group (such as a methyl group, an ethyl group, a tert-butyl group, or a dodecyl group), an alkylene group substituted with an alkenyl group (such as a vinyl group or an allyl group), and an alkylene group substituted with an aryl group (such as a phenyl group, a p-tolyl group, a xylyl group, a cumenyl group, a naphthyl group, an anthryl group, a phenanthryl group, or a styryl group).

In Formula (OX-1), examples of the aryl group represented by Ar include an aryl group having 6 to 30 carbon atoms, which may have a substituent group. Examples of the substituent group include the substituent groups that are introduced to the substituted aryl group described as a specific example of an aryl group which may have a substituent group.

Among them, from the viewpoints of enhancing sensitivity and inhibiting coloration by heating over time, a substituted or unsubstituted phenyl group is preferable.

In Formula (OX-1), it is preferable that the structure “SAr” formed from Ar and adjacent S in Formula (OX-1) has any one of the structures shown below, from the viewpoint of sensitivity. In the following structures, Me indicates a methyl group and Et indicates an ethyl group.

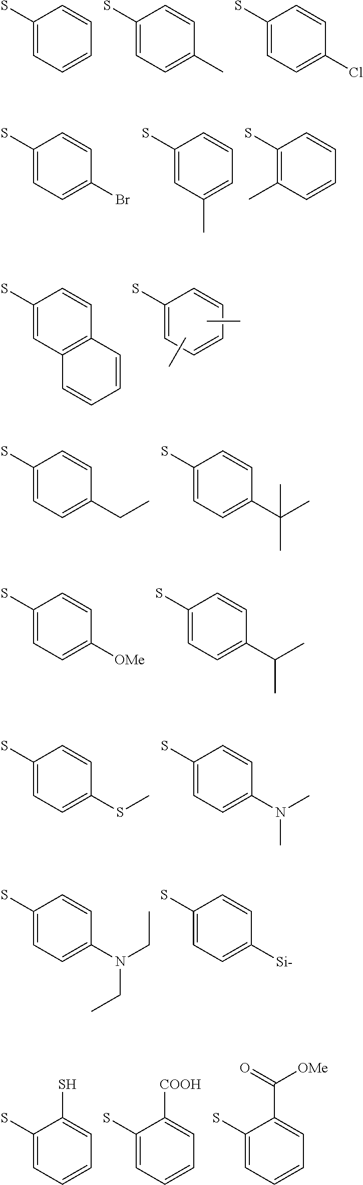

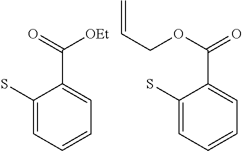

The oxime compound is preferably a compound represented by Formula (OX-2) below.

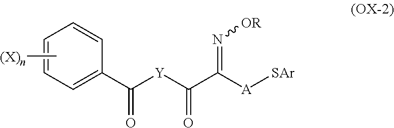

In Formula (OX-2), R and X each independently represent a monovalent substituent group; A and Y independently represent a divalent organic group; Ar represents an aryl group; and n is an integer from 0 to 5. When n is an integer from 2 to 5, plural X's may be the same as or different from each other.

In Formula (OX-2), R, A and Ar have the same definitions as R, A, and Ar, respectively, in Formula (OX-1), and the preferred examples thereof are also the same.

In Formula (OX-2), examples of the monovalent substituent group represented by X include an alkyl group, an aryl group, an alkoxy group, an aryloxy group, an acyloxy group, an acyl group, an alkoxycarbonyl group, an amino group, a heterocyclic group, and a halogen atom, which may each have one or more substituent groups. Examples of the substituent groups include those described above. Further, the substituent groups may each be further substituted with an additional substituent group.

Among them, from the viewpoints of improving solvent solubility and absorption efficiency in long wavelength range, an alkyl group is preferable as X in Formula (OX-2).

Further, n in Formula (OX-2) is an integer from 0 to 5, and an integer from 0 to 2 is preferable.

In Formula (OX-2), examples of the divalent organic group represented by Y include the following structures. In the groups shown below, “*” represents a binding site for the carbon atom which is adjacent to Y in Formula (OX-2).

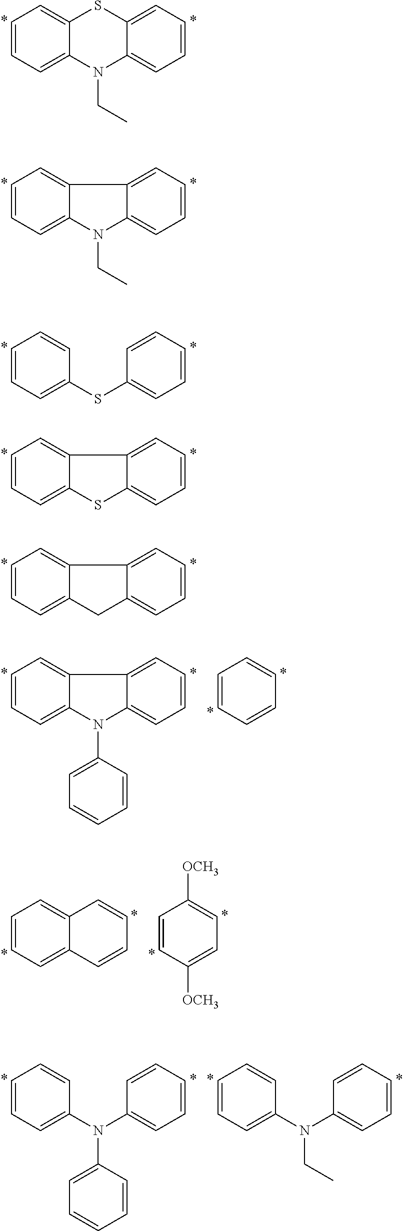

In particular, the photopolymerization initiator is particularly preferably a compound having any one of the following structures, from the viewpoint of sensitivity increase.

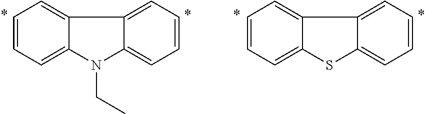

Further, the oxime compound is preferably a compound represented by the following formula (OX-3).

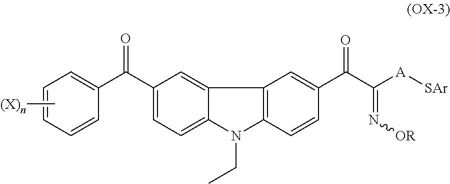

In Formula (OX-3), R and X each independently represent a monovalent substituent group, A represents a divalent organic group, Ar represents an aryl group, and n is an integer from 0 to 5. When n is an integer of 2 to 5, plural X's may be the same as or different from each other.

In Formula (OX-3), R, X, A, Ar, and n have the same definitions as R, X, A, Ar, and n, respectively, in Formula (OX-2), and the preferred examples thereof are also the same.

Hereinbelow, specific examples of the oxime compound usable in the invention are shown, but the invention is not limited to them.

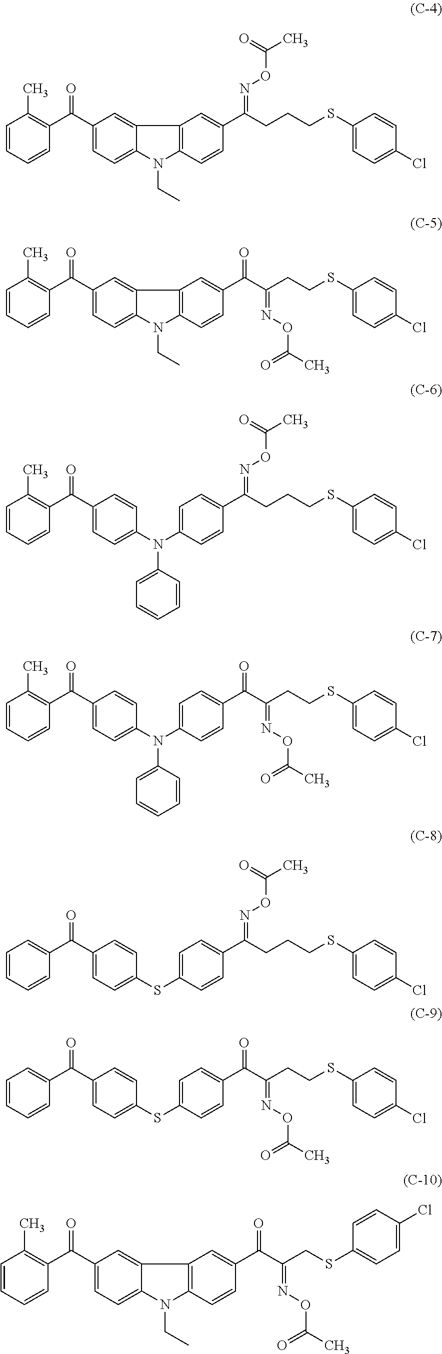

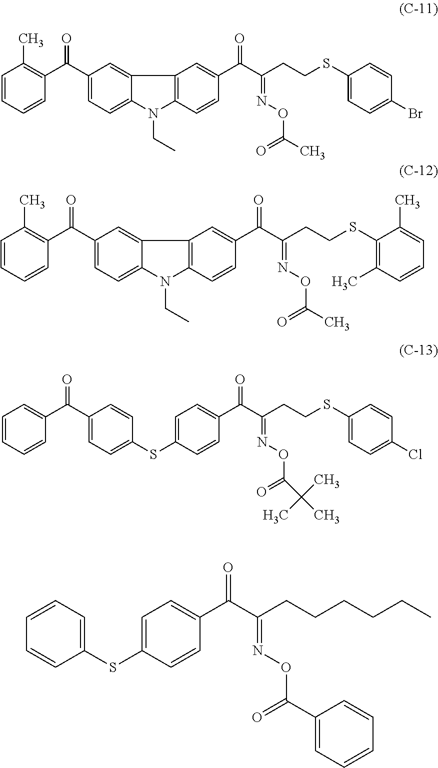 [SMILES: CCn1c2ccc(C(=O)/C(CCSc3ccc(Br)cc3)=N/OC(C)=O)cc2c2cc(C(=O)c3ccccc3C)ccc21 ; CCn1c2ccc(C(=O)/C(CCSc3c(C)cccc3C)=N/OC(C)=O)cc2c2cc(C(=O)c3ccccc3C)ccc21 ; CC(C)(C)C(=O)O/N=C(\CCSc1ccc(Cl)cc1)C(=O)c1ccc(Sc2ccc(C(=O)c3ccccc3)cc2)cc1 ; CCCCCC/C(=N\OC(=O)c1ccccc1)C(=O)c1ccc(Sc2ccccc2)cc1]

The oxime compound has a maximum absorption wavelength in the wavelength region of 350 nm to 500 nm, and preferably an absorption wavelength in the wavelength region of 360 nm to 480 nm. A compound having a high absorbance at 365 nm or 455 nm is particularly preferable.

The molar coefficient of the oxime compound at 365 nm or 405 nm is preferably 1,000 to 300,000, more preferably 2,000 to 300,000, and still more preferably 5,000 to 200,000, from the viewpoint of sensitivity.

The molar absorption coefficient of a compound may be measured by a known method. Specifically, the molar absorption coefficient may be measured using a spectrophotometer (trade name: CARRY 5, manufactured by Varian Inc.) at concentration of 0.01 g/L using ethyl acetate as a solvent.

In the invention, the polymerization initiators may be used in combination of two or more thereof, if necessary.

The polymerization initiator is preferably a compound selected from the group consisting of trihalomethyl triazine compounds, benzyl dimethyl ketal compounds, α-hydroxyketone compounds, α-aminoketone compounds, acylphosphine compounds, phosphine oxide compounds, metallocene compounds, oxime compounds, triaryl imidazole dimer, onium compounds, benzothiazole compounds, benzophenone compounds, acetophenone compounds and derivatives thereof, cyclopentadiene-benzen-iron complexes and salts thereof, halomethyloxadiazole compounds, and 3-aryl-substituted coumarin compounds, from a standpoint of exposure sensitivity.

The polymerization initiator is more preferably at least one compound selected from the group consisting of trihalomethyl triazine compounds, α-aminoketone compounds, acylphosphine compounds, phosphine oxide compounds, oxime compounds, triaryl imidazole dimer, onium compounds, benzophenone compounds, and acetophenone compounds, and most preferably at least one compound selected from the group consisting of trihalomethyl triazine compounds, α-aminoketone compounds, oxime compounds, triaryl imidazole dimer, and benzophenone compounds.

For producing a color filter of the invention, it is necessary to form fine patterns with a sharp shape, and therefore it is particularly important that development is achieved without generation of residues on an un-exposed area while achieving curability. From such viewpoint, it is particularly preferable to use an oxime compound as a polymerization initiator. In particular, when fine patterns are formed for a solid-state image sensor, a stepper exposing machine is used for curing exposure. However, the exposing machine may be damaged by halogen, and therefore an addition amount of a polymerization inhibitor should be kept low. Under the circumstances, to form fine patterns such as a solid-state image sensor, use of an oxime compound as a polymerization initiator is most preferable.

The content of the polymerization initiator in the colored radiation-sensitive composition is preferably from 0.1% by mass to 50% by mass, more preferably from 0.5% by mass to 20% by mass, and still more preferably from 1% by mass to 15% by mass, with respect to the total solid content of the colored radiation sensitive composition. When the content is within the above ranges, favorable sensitivity and pattern formability are obtained.

Organic Solvent

The colored radiation-sensitive composition of the invention preferably contains an organic solvent.

Examples of the organic solvent include:
esters such as ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, alkyl oxyacetate (for example, methyl oxyacetate, ethyl oxyacetate, and butyl oxyacetate, such as methyl methoxyacetate, ethyl methoxyacetate, butyl methoxyacetate, methyl ethoxyacetate, or ethyl ethoxyacetate), 3-oxypropionic acid alkyl esters (for example, methyl 3-oxypropionate and ethyl 3-oxypropionate, such as methyl 3-methoxypropionate, ethyl 3-methoxypropionate, methyl 3-ethoxypropionate, or ethyl 3-ethoxypropionate), 2-oxy propionic acid alkyl esters (for example, methyl 2-oxypropionate, ethyl 2-oxypropionate, and propyl 2-oxypropionate, such as methyl 2-methoxypropionate, ethyl 2-methoxypropionate, propyl 2-methoxypropionate, methyl 2-ethoxypropionate, or ethyl 2-ethoxypropionate), methyl 2-oxy-2-methylpropionate and ethyl 2-oxy-2-methylpropionate (for example, methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate, and ethyl 2-oxobutanoate;
ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate;
ketones such as methyl ethyl ketone, cyclohexanone, 2-heptanone, and 3-heptanone; and
aromatic hydrocarbons such as toluene and xylene.

The organic solvent may be used either singly or in combination of two or more thereof.

When a combination of two or more organic solvents is used, it is particularly preferable to use a mixture solution containing at least two selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol methyl ether acetate.

The amount of the organic solvent contained in the colored radiation-sensitive composition is preferably from 10% by mass to 90% by mass, more preferably from 20% by mass to 80% by mass, and still more preferably from 25% by mass to 75% by mass, with respect to the total mass of the colored radiation-sensitive composition.

Sensitizer

The colored radiation-sensitive composition of the invention may include a sensitizer for a purpose of improving the generation efficiency of starting species a polymerization initiator, or shifting the photosensitive wavelength to a longer wavelength. Examples of the sensitizers include those capable of absorbing light in the wavelength region from 300 nm to 450 nm.

Examples of the sensitizers include polynuclear aromatics such as phenanthrene, anthracene, pyrene, perylene, triphenylene, and 9,10-dialkoxyanthracene, xanthenes such as fluorescein, eosin, erythrosin, rhodamine B, and rose bengal, thioxantones, cyanines, merocyanines, phthalocyanines, thiazines such as thionine, methylene blue, and toluidine blue, acridines, anthraquinones, squaryliums, coumarins, phenothiazines, phenazines, styrylbenzenes, azo compounds, diphenylmethane, triphenylmethane, distyrylbenzenes, carbazoles, porphyrin, spiro compounds, quinacridone, indigo, styryl, pyrylium compounds, pyrromethene compounds, pyrazolotriazole compounds, benzothiazole compounds, barbituric acid derivatives, thiobarbituric acid derivatives, aromatic ketone compounds such as acetophenone, benzophenone, and Michler's ketone, and heterocyclic compounds such as N-aryloxazolidinone.

Chain Transfer Agent

The colored radiation-sensitive composition preferably contains a chain transfer agent, depending on the type of photopolymerization initiator used. Examples of the chain transfer agent include alkyl ester of N,N-dialkyl amino benzoic acid and a thiol compound. Examples of the thiol compound include 2-mercapto benzothiazole, 2-mercapto-1-phenyl benzimidazole, and 3-mercapto propionate, and may be used either singly or in combination of two or more thereof.

Alkali-Soluble Resin

It is preferable that the colored radiation-sensitive composition further contains an alkali-soluble resin. When the colored radiation-sensitive composition contains an alkali-soluble resin, developability and pattern formability are improved.

When the specific binder of the invention exhibits alkali solubility by containing a monomer having (meth)acrylate with an acidic group or a carboxy group such as itaconic acid, a monomer having a phenolic hydroxy group such as N-hydroxyphenyl maleimide, or a monomer having a carboxylic anhydride group such as maleic anhydride or itaconic anhydride as a copolymerization component, the specific binder may be used as an alkali-soluble resin.

The alkali-soluble resin may be a linear organic polymer having a structure different from the specific binder, and it may be suitably selected from alkali-soluble resins which have at least one group capable of enhancing alkali solubility in the molecule (preferably, a molecule containing acrylic copolymer or styrene copolymer as a main chain).

The alkali-soluble resin is described hereinbelow.

From the viewpoint of heat resistance, the alkali-soluble resin is preferably a polyhydroxy styrene resin, a polysiloxane resin, an acrylic resin, an acrylamide resin, or an acryl/acrylamide copolymer resin. From the viewpoint of controlling developability, an acrylic resin, an acrylamide resin, or an acryl/acrylamide copolymer resin is preferable.

Examples of the group capable of enhancing alkali solubility (hereinbelow, may be referred to as an “acidic group”) include a carboxyl group, a phosphoric acid group, a sulfonic acid group, and a phenolic hydroxyl group. Preferably, a group that enables dissolution in an organic solvent and development using a weakly alkaline aqueous solution is used, and (meth)acrylate is particularly preferable. The acidic groups may be used either singly or in combination of two or more thereof.

Examples of the monomer capable of imparting an acidic group after polymerization include a monomer having a hydroxyl group such as 2-hydroxyethyl(meth)acrylate, a monomer having an epoxy group such as glycidyl(meth)acrylate, and a monomer having an isocyanate group such as 2-isocyante ethyl(meth)acrylate. The monomers used for introducing such acidic group may be used either singly or in combination two or more thereof. To introduce an acidic group to an alkali-soluble binder, it is preferable that the monomer having an acidic group and/or the monomer capable of imparting an acidic group after polymerization (hereinbelow, also referred to as a “monomer for introducing an acidic group”) are polymerized as a monomer component. Further, when an acidic group is introduced by using the monomer capable of imparting an acidic group after polymerization, a treatment for adding an acidic group after polymerization is needed as described below.

For preparation of an alkali-soluble resin, a known radical polymerization method may be employed. Conditions for polymerization such as temperature and pressure for producing an alkali-soluble resin by radical polymerization, the type and amount of radical polymerization initiator, and the type of solvent, and the like may be easily determined by a skilled person in the art, and it may be also determined by experiments.

As an alkali-soluble resin, a polymer having carboxylic acid in a side chain thereof is preferable. Examples thereof include a methacrylic acid copolymer, an acrylate copolymer, an itaconic acid copolymer, a crotonic acid copolymer, a maleic acid copolymer, a partially esterified maleic acid copolymer, an alkali-soluble phenol resin such as Novolac resin, an acidic cellulose derivative having carboxylic acid in a side chain thereof, and a product obtained by addition of an acid anhydride to a polymer having a hydroxyl group. In particular, a copolymer between (meth)acrylate and another monomer which is copolymerizable with (meth)acrylate is preferable as an alkali-soluble resin. Examples of another monomer which is copolymerizable with (meth)acrylate include alkyl(meth)acrylate, aryl(meth)acrylate, and a vinyl compound. Examples of alkyl(meth)acrylate and aryl(meth)acrylate include methyl(meth)acrylate, ethyl(meth)acrylate, propyl(meth)acrylate, butyl(meth)acrylate, isobutyl(meth)acrylate, pentyl(meth)acrylate, hexyl(meth)acrylate, octyl(meth)acrylate, phenyl(meth)acrylate, benzyl(meth)acrylate, tolyl(meth)acrylate, naphthyl(meth)acrylate, and cyclohexyl(meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, polystyrene macromonomer, polymethyl methacrylate macromonomer, and N-position-substituted maleimide monomer described in JP-A No. 10-300922 like N-phenyl maleimide and N-cyclohexyl maleimide. The monomer which is copolymerizable with (meth)acrylates may be used either singly or in combination of two or more.

The alkali-soluble phenol resin may be suitably used when the colored radiation-sensitive composition of the invention is prepared as a positive-working composition. Examples of the alkali soluble phenol resin include a Novolac resin and a vinyl polymer.

Examples of the Novolac resin include those obtained by condensation of phenols and aldehydes in the presence of an acid catalyst. Examples of the phenols include phenol, cresol, ethyl phenol, butyl phenol, xylenol, phenyl phenol, catechol, resorcinol, pyrogallol, naphthol, and bisphenol A.

Examples of the aldehydes include formaldehyde, paraformaldehyde, acetaldehyde, propionaldehyde, and benzaldehyde.

The phenols and aldehydes may be used either singly or in combination of two or more, respectively.

Specific examples of the Novolac resin include a product obtained by condensation between metacresol, paracresol, or a mixture thereof and formalin.

The molecular weight distribution of the Novolac resin may be controlled by a method such as fractionation. Furthermore, a low molecular weight component having a phenolic hydroxyl group such as bisphenol C or bisphenol A may be also added to the Novolac resin.

To improve the crosslinking efficiency of the colored radiation-sensitive composition of the invention, an alkali-soluble resin having a polymerizable group may be also used. Examples of an alkali-soluble resin having a polymerizable group usable in the invention include an alkali-soluble resin which contains in a side chain thereof an allyl group, a (meth)acryl group, or an allyloxy alkyl group.

Examples of the polymer having a polymerizable group include DIANAL NR series (trade name, manufactured by MITSUBISHI RAYON Co., Ltd.), Photomer 6173 (COOH-containing polyurethane acrylic oligomer, trade name, manufactured by Diamond Shamrock Co. Ltd.), BISCOAT R-264 and KS RESIST 106 (trade names, all manufactured by OSAKA ORGANIC CHEMICAL INDUSTRY LTD.), CYCLOMER P series and PLACCEL CF200 series (trade names, all manufactured by Daicel Corporation), and EBECRYL 3800 (trade name, manufactured by Daicel-UCB Co., Ltd.).

Preferred examples of the alkali-soluble resin having a polymerizable group include a urethane-modified acryl resin containing a polymerizable double bond that is obtained by reacting in advance an isocyanate group with OH for yielding one unreacted isocyanate group and reacting a compound containing a (meth)acryloyl group and an acryl resin containing a carboxyl group, an acryl resin containing an unsaturated group obtained by reacting an acryl resin containing a carboxyl group and a compound having both an epoxy group and a polymerizable double bond in the molecule, an acryl resin having a polymerizable double bond obtained by reacting an acid pendant type epoxy acrylate resin, an acryl resin containing OH group, and dibasic acid anhydride having a polymerizable double bond, a resin obtained by reacting an acryl resin containing OH group and a compound having isocyanate and a polymerizable compound, and a resin obtained by basic treatment of a resin which has an ester group in the side chain with a leaving group like sulfonate group or a halogen atom at a position or β position as described in JP-A No. 2002-229207 and JP-A No. 2003-335814.

As an alkali-soluble resin, a benzyl(meth)acrylate/(meth)acrylate copolymer or a multi-component copolymer of benzyl(meth)acrylate/(meth)acrylate/other comonomer is preferable. In addition to them, examples of alkali-soluble resin include a copolymerization product of 2-hydroxyethyl methacrylate, and a 2-hydroxypropyl(meth)acrylate/polystyrene macromonomer/benzyl methacrylate/methacrylic acid copolymer, a 2-hydroxy-3-phenoxypropylacrylate/polymethylmethacrylate macromonomer/benzyl methacrylate/methacrylic acid copolymer, a 2-hydroxyethyl methacrylate/polystyrene macromonomer/methyl methacrylate/methacrylic acid copolymer, a 2-hydroxyethyl methacrylate/polystyrene macromonomer/benzyl methacrylate/methacrylic acid copolymer, or the like, which are described in JP-A No. 7-140654.

The alkali-soluble resin preferably contains a polymer (a), which is obtained by polymerization of monomer components, including the compound represented by the following Formula (ED) as an essential component (hereinbelow, suitably referred to as an “ether dimer”).

By containing the polymer (a), the colored radiation-sensitive composition of the invention provides a cured coating film which has excellent transparency as well as excellent heat resistance.

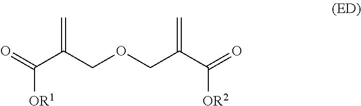

In Formula (ED), R¹ and R² each independently represent a hydrogen atom or a hydrocarbon group having 1 to 25 carbon atoms which may have a substituent group.

In Formula (ED), the hydrocarbon group having 1 to 25 carbon atoms which may have a substituent group, which is represented by R¹ or R², is not specifically limited, and examples thereof include a linear or branched alkyl group such as a methyl group, an ethyl group, an n-propyl group, an isopropyl group, an n-butyl group, an isobutyl group, a t-butyl group, a t-amyl group, a stearyl group, a lauryl group, or a 2-ethyl hexyl group; an aryl group such as a phenyl group; an alicyclic group such as a cyclohexyl group, a t-butyl cyclohexyl group, a dicyclopentadienyl group, a tricyclodecanyl group, an isobornyl group, an adamantyl group, or a 2-methyl-2-adamantyl group; an alkoxy-substituted alkyl group such as a 1-methoxyethyl group or a 1-ethoxyethyl group; and an aryl-substituted alkyl group such as a benzyl group. Among these, the substituent group is particularly preferably a group of primary or secondary carbon, which is hardly dissociable by acid or heat, such as a methyl group, an ethyl group, a cyclohexyl group, or a benzyl group, from the viewpoint of heat resistance.

Specific examples of the ether dimer include dimethyl-2,2′-[oxybis(methylene)]bis-2-propenoate, diethyl-2,2′-[oxybis(methylene)]bis-2-propenoate, di(n-propyl)-2,2′-[oxybis(methylene)]bis-2-propenoate, di(isopropyl)-2,2′-[oxybis(methylene)]bis-2-propenoate, di(n-butyl)-2,2′-[oxybis(methylene)]bis-2-propenoate, di(isobutyl)-2,2′-[oxybis(methylene)]bis-2-propenoate, di(t-butyl)-2,2′-[oxybis(methylene)]bis-2-propenoate, di(t-amyl)-2,2′-[oxybis(methylene)]bis-2-propenoate, di(stearyl)-2,2′-[oxybis(methylene)]bis-2-propenoate, di(lauryl)-2,2′-[oxybis(methylene)]bis-2-propenoate, di(2-ethylhexyl)-2,2′-[oxybis(methylene)]bis-2-propenoate, di(1-methoxyethyl)-2,2′-[oxybis(methylene)]bis-2-propenoate, di(1-ethoxyethyl)-2,2′-[oxybis(methylene)]bis-2-propenoate, dibenzyl-2,2′-[oxybis(methylene)]bis-2-propenoate, diphenyl-2,2′-[oxybis(methylene)]bis-2-propenoate, dicyclohexyl-2,2′-[oxybis(methylene)]bis-2-propenoate, di(t-butylcyclohexyl)-2,2′-[oxybis(methylene)]bis-2-propenoate, di(dicyclopentadienyl)-2,2′-[oxy bis(methylene)]bis-2-propenoate, di(tricyclodecanyl)-2,2′-[oxybis(methylene)]bis-2-propenoate, di(isobornyl)-2,2′-[oxybis(methylene)]bis-2-propenoate, diadamantyl-2,2′-[oxybis(methylene)]bis-2-propenoate, and di(2-methyl-2-adamantyl)-2,2′-[oxybis(methylene)]bis-2-propenoate. Of these, dimethyl-2,2′-[oxybis(methylene)]bis-2-propenoate, diethyl-2,2′-[oxybis(methylene)]bis-2-propenoate, dicyclohexyl-2,2′-[oxybis(methylene)]bis-2-propenoate, and dibenzyl-2,2′-[oxybis(methylene)]bis-2-propenoate are particularly preferable. The ether dimer may be used either singly or in combination of two or more.

The proportion of the ether dimer in monomers used for obtaining the polymer (a) is, although not specifically limited, preferably 2 to 60% by mass, more preferably 5 to 55% by mass, and still more preferably 5 to 50% by mass, with respect to the total monomer components, from the viewpoints of transparency and heat resistance of a coating film to be formed using the colored radiation-sensitive composition of the invention.

The polymer (a) may be also a copolymer obtained by copolymerization of an ether dimer with another monomer.

Examples of another monomer capable of being copolymerized with an ether dimer include a dimer for introducing an acidic group, a monomer for introducing a radical polymerizable double bond, a monomer for introducing an epoxy group, and a copolymerizable monomer other than those. The monomers may be used either singly or in combination of two or more thereof.

Examples of the monomer for introducing an acidic group include a monomer having a carboxyl group such as (meth)acrylic acid or itaconic acid, a monomer having a phenolic hydroxyl group such as N-hydroxyphenyl maleimide, and a monomer having a carboxylic anhydride group such as maleic anhydride or itaconic anhydride. Of these, (meth)acrylic acid is particularly preferable.

Further, the monomer for introducing an acidic group may be a monomer capable of imparting an acidic group after polymerization, and examples thereof include a monomer having a hydroxyl group such as 2-hydroxyethyl(meth)acrylate, a monomer having an epoxy group such as glycidyl(meth)acrylate, and a monomer having an isocyanate group such as 2-isocyante ethyl(meth)acrylate. When a monomer for introducing a radical polymerizable double bond is used, a treatment for adding an acidic group is necessary after polymerization when a monomer capable of providing an acidic group after polymerization is used. The treatment for providing an acidic group after polymerization varies depending on type of a monomer, and examples include the followings. When a monomer having a hydroxyl group is used, a treatment of adding an acid anhydride such as succinic anhydride, tetrahydrophthalic anhydride, or maleic anhydride may be employed. When a monomer having an epoxy group is used, a compound having an amino group and an acidic group, such as N-methylamino benzoic acid or N-methylamino phenol may be added, for example, or a treatment including adding an acid such as (meth)acrylic acid to produce a hydroxyl group, followed by adding an acid anhydride such as succinic anhydride, tetrahydrophthalic anhydride, or maleic anhydride to the generated hydroxyl group. When a monomer having an isocyanate group is used, a treatment including adding a compound having both a hydroxyl group and an acidic group such as 2-hydroxy butyric acid, may be used.

When the monomer used for obtaining a polymer (a) contains a monomer for introducing an acidic group, the content ratio thereof is, although not specifically limited, preferably 5 to 70% by mass, and more preferably 10 to 60% by mass, with respect to the total monomer components.

Examples of the monomer for introducing radical polymerizable double bond include a monomer having a carboxyl group such as (meth)acrylic acid and itaconic acid; a monomer having a carboxylic anhydride group such as maleic anhydride and itaconic anhydride; and a monomer having an epoxy group such as glycidyl(meth)acrylate, 3,4-epoxy cyclohexyl methyl(meth)acrylate, and o- (or m- or p-)vinyl benzyl glycidyl ether. When a monomer for introducing radical polymerizable double bond is used, there is a need to carry out a treatment for introducing radical polymerizable double bond after polymerization. The treatment for introducing radical polymerizable double bond after polymerization varies depending on the type of a monomer used for introducing a radical polymerizable double bond, and examples of the treatment include the followings. When a monomer having a carboxyl group such as (meth)acrylic acid or itaconic acid is used, there is a treatment for adding a compound having an epoxy group and a radical polymerizable double bond such as glycidyl(meth)acrylate, 3,4-epoxy cyclohexyl methyl(meth)acrylate, or o- (or m- or p-)vinyl benzyl glycidyl ether. When a monomer having a carboxylic anhydride group such as maleic anhydride or itaconic anhydride is used, there is a treatment for adding a compound having a hydroxyl group and a radical polymerizable double bond such as 2-hydroxyethyl(meth)acrylate. When a monomer having an epoxy group such as glycidyl(meth)acrylate, 3,4-epoxy cyclohexyl methyl(meth)acrylate, or o- (or m- or p-) vinyl benzyl glycidyl ether is used, there is a treatment for adding a compound having an acidic group and a radical polymerizable double bond such as (meth)acrylic acid.

When the monomer for obtaining a polymer (a) contains a monomer for introducing a radical polymerizable double bond, the content ratio thereof is, although not specifically limited, preferably 5 to 70% by mass, and more preferably 10 to 60% by mass, with respect to the total monomer components.

Examples of the monomer for introducing an epoxy group include glycidyl(meth)acrylate, 3,4-epoxy cyclohexyl methyl(meth)acrylate, and o-vinyl benzyl glycidyl ether, m-vinyl benzyl glycidyl ether, and p-vinyl benzyl glycidyl ether.

When the monomer for obtaining a polymer (a) contains a monomer for introducing an epoxy group, the content ratio thereof is, although not specifically limited, preferably 5 to 70% by mass, and more preferably 10 to 60% by mass, with respect to the total monomer components.

Examples of other copolymerizable monomer include (meth)acrylate esters such as methyl(meth)acrylate, ethyl(meth)acrylate, n-propyl(meth)acrylate, isopropyl(meth)acrylate, n-butyl(meth)acrylate, isobutyl(meth)acrylate, t-butyl(meth)acrylate, methyl 2-ethylhexyl(meth)acrylate, cyclohexyl(meth)acrylate, benzyl(meth)acrylate, and 2-hydroxyethyl(meth)acrylate; aromatic vinyl compounds such as styrene, vinyl toluene, and α-methylstyrene; N-substituted maleimides such as N-phenyl maleimide and N-cyclohexyl maleimide; a butadiene or substituted butadiene compound such as butadiene and isoprene; an ethylene or substituted ethylene compound such as ethylene, propylene, vinyl chloride, and acrylonitrile; and vinyl esters such as vinyl acetate. Of these, from the viewpoint that the transparency is favorable and heat resistance is not easily deteriorated, methyl(meth)acrylate, cyclohexyl(meth)acrylate, benzyl(meth)acrylate, and styrene are preferable.

When the monomer for obtaining a polymer (a) contains other copolymerizable monomer, the content ratio thereof is, although not specifically limited, preferably 95% by mass or less, and more preferably 85% by mass or less.

The weight average molecular weight of the polymer (a) is, although not specifically limited, preferably 2,000 to 200,000, more preferably 5,000 to 100,000, and still more preferably 5,000 to 20,000, from the viewpoints of the viscosity of the colored radiation sensitive composition and heat resistance of a coating film formed from the composition.

When the polymer (a) contains an acidic group, the acid value thereof is preferably 30 to 500 mgKOH/g, and more preferably 50 to 400 mgKOH/g.

The polymer (a) may be easily obtained at least by polymerizing the monomer which essentially contains an ether dimer. In such case, cyclization of an ether dimer occurs simultaneously with the polymerization, yielding a tetrahydropyran ring structure.

The polymerization method used for synthesis of the polymer (a) is not specifically limited, and various known methods may be used. However, solvent polymerization is preferable, in particular. More specifically, for example, the polymer (a) may be synthesized in view of the method for producing a polymer (a) as described in JP-A No. 204-300204.

Hereinbelow, exemplary compounds of the polymer (a) are shown, but the invention is not limited to them. The compositional ratio of the exemplary compounds described below is based on mol %.

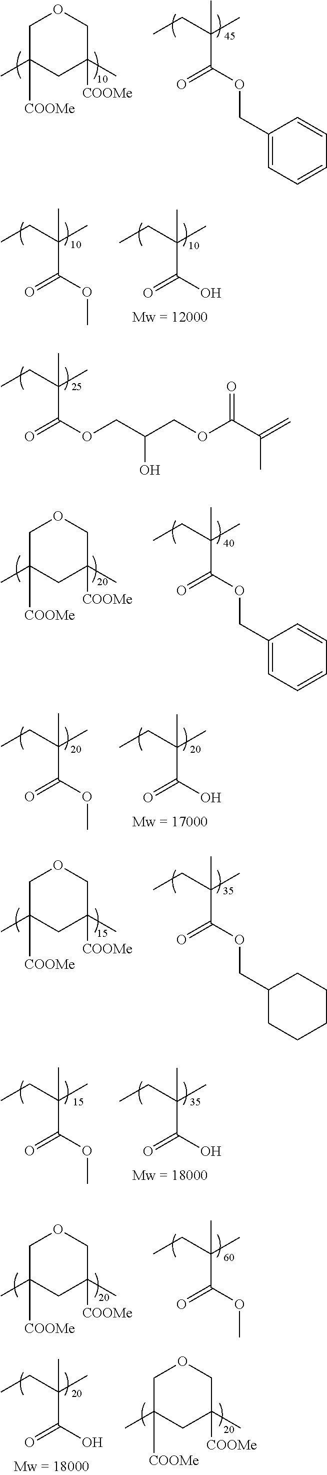

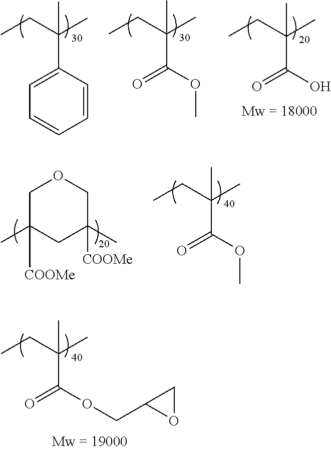

Among the alkali-soluble resins above, particularly preferred resins are a benzyl(meth)acrylate/(meth)acrylate copolymer and a multi-component copolymer of benzyl(meth)acrylate/(meth)acrylate/other monomer. In addition to them, examples of the alkali-soluble resins include a copolymer of 2-hydroxyethyl methacrylate and a 2-hydroxypropyl(meth)acrylate/polystyrene macromonomer/benzyl methacrylate/methacrylic acid copolymer, a 2-hydroxy-3-phenoxypropyl acrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, and a 2-hydroxyethyl methacrylate/polystyrene macromonomer/benzyl methacrylate/methacrylic acid copolymer, which are described in JP-A No. 7-140654.

The colored radiation-sensitive composition of the invention may include an alkali-soluble resin having a polymerizable group for a purpose of improving the cross-linking efficiency of the composition.

As an alkali-soluble resin having a polymerizable group, an alkali-soluble resin having an allyl group, a (meth)acryl group, or an allyloxy alkyl group in a side chain thereof is useful.

Preferred examples of the alkali-soluble resin having a polymerizable group include a urethane-modified acryl resin containing a polymerizable double bond that is obtained by reacting in advance an isocyanate group with OH for yielding one unreacted isocyanate group and reacting a compound containing (meth)acryloyl group and an acryl resin containing a carboxyl group, an acryl resin containing an unsaturated group obtained by reacting an acryl resin containing a carboxyl group and a compound having both an epoxy group and a polymerizable double bond in the molecule, an acryl resin having a polymerizable double bond obtained by reacting an acid pendant epoxy acrylate resin, an acryl resin containing OH group, and dibasic acid anhydride having a polymerizable double bond, a resin obtained by reacting an acryl resin containing OH group and a compound having isocyanate and a polymerizable compound, and a resin obtained by basic treatment of a resin which has an ester group with a leaving group such as a halogen atom or sulfonate group at α-position or β-position as described in JP-A No. 2002-229207 and JP-A No. 2003-335814.

The acid value of an alkali-soluble resin is preferably 30 mgKOH/g to 200 mgKOH/g, more preferably 50 mgKOH/g to 150 mgKOH/g, and still more preferably 70 to 120 mgKOH/g.

The weight average molecular weight (Mw) of the alkali-soluble resin is preferably 2,000 to 50,000, more preferably 5,000 to 30,000, and still more preferably 7,000 to 20,000.

The content of the alkali-soluble resin in the colored radiation-sensitive composition is preferably 1 to 15% by mass, more preferably 2 to 12% by mass, and particularly preferably 3 to 10% by mass, with respect to the total solid content of the composition.

Polymerization Inhibitor

The colored radiation-sensitive composition of the invention may include a small amount of polymerization inhibitor for suppressing undesired thermal polymerization of a polymerizable compound during the production or storage of the colored radiation-sensitive composition.

Examples of the polymerization inhibitor usable in the invention include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and an N-nitrosophenylhydroxyamine cerium (I) salt. Of these, p-methoxy phenol is preferable.

The addition amount of the polymerization inhibitor is preferably from about 0.01% by mass to about 5% by mass with respect to the total mass of the colored radiation-sensitive composition.

Substrate Adhesion Improver

The colored radiation-sensitive composition may further contain a substrate adhesion improver in order to improve the adhesiveness to a substrate.

Examples of the substrate adhesion improver include a silane coupling agent, a titanium coupling agent, and an aluminum coupling agent. Examples of the silane coupling agents include γ-methacryloxypropyl trimethoxy silane, γ-methacryloxypropyl triethoxy silane, γ-acryloxypropyl trimethoxy silane, γ-acrylooxypropyl triethoxy silane, γ-mercaptopropyl trimethoxy silane, γ-aminopropyltriethoxy silane, and phenyltrimethoxy silane. Of these, γ-methacryloxypropyl trimethoxy silane is preferable as a substrate adhesion promoter.

The content of the substrate adhesion improver is preferably from 0.1% by mass to 30% by mass, more preferably from 0.5% by mass to 20% by mass, and particularly preferably from 1% by mass to 10% by mass, with respect to the total solid content of the colored radiation-sensitive composition, from the viewpoint that no residues remain in an unexposed area after the colored radiation-sensitive composition has been subjected to light exposure and development.

Surfactant

The colored radiation-sensitive composition may further include a surfactant from the viewpoint of additionally improving the coatability. Various surfactants such as a fluoro-surfactant, a nonionic surfactant, a cationic surfactant, an anionic surfactant, or a silicone surfactant may be used as the surfactant.

In particular, when the colored radiation-sensitive composition of the invention contains a fluoro-surfactant, liquid properties (in particular, fluidity) of the composition when it is prepared as a coating solution may be further improved. As a result, uniformity in coating thickness is further improved and the liquid-saving property is further improved.

In other words, when a film is formed using a coating solution which is a colored radiation-sensitive composition containing a fluoro-surfactant, a surface tension of the coating solution with respect to a surface to be coated is decreased, and wettability with respect to the surface to be coated is improved, thereby improving coatability to the surface to be coated. Accordingly, a film having a thickness with suppressed unevenness is suitably formed even when a thin film having a thickness of several micrometers is formed with a small liquid amount.

The content of fluorine in a fluoro-surfactant is preferably in the range from 3% by mass to 40% by mass, more preferably from 5% by mass to 30% by mass, and particularly preferably from 7% by mass to 25% by mass. A fluoro-surfactant containing fluorine in an amount within the above ranges is effective in terms of forming a coating film with suppressed thickness unevenness and in the aspect of liquid-saving property, and also exhibits favorable solubility in the colored radiation sensitive composition.

Examples of the fluoro-surfactant include MEGAFAC F171, MEGAFAC F172, MEGAFAC F173, MEGAFAC F176, MEGAFAC F177, MEGAFAC F141, MEGAFAC F142, MEGAFAC F143, MEGAFAC F144, MEGAFAC R30, MEGAFAC F437, MEGAFAC F475, MEGAFAC F479, MEGAFAC F482, MEGAFAC F554, MEGAFAC F780, and MEGAFAC F781 (all trade names, manufactured by DIC Corporation), FLUORAD FC430, FLUORAD FC431, and FLUORAD FC171 (all trade names, manufactured by Sumitomo 3M Limited), SURFLON S-382, SURFLON SC-101, SURFLON SC-103, SURFLON SC-104, SURFLON SC-105, SURFLON SC-1068, SURFLON SC-381, SURFLON SC-383, SURFLON S393, and SURFLON KH-40 (all trade names, manufactured by Asahi Glass Co., Ltd.).

Specific examples of the nonionic surfactant include glycerol, trimethylol propane, trimethylol ethane, and an ethoxylate or propoxylate thereof (such as glycerol propoxylate or glycerin ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid ester (such as PLURONIC L10, L31, L61, L62, 10R5, 17R2, 25R2, TETRONIC 304, 701, 704, 901, 904, 150R1, all trade names, manufactured by BASF and SOLSPERSE 20000 (trade name, manufactured by Lubrizol Corporation)).

Specific examples of the cationic surfactant include phthalocyanine derivatives (trade name: EFKA-745, manufactured by Morishita & Co., Ltd.), organosiloxane polymer KP341 (trade name, manufactured by Shin-Etsu Chemical Co., Ltd.), (meth)acrylic(co)polymers POLYFLOW No. 75, No. 90, and No. 95 (trade name, manufactured by Kyoeisha Chemical Co., Ltd.), and W001 (trade name, manufactured by Yusho Co., Ltd.).

Specific examples of the anionic surfactant include W004, W005, and W017 (all trade names, manufactured by Yusho Co., Ltd.).

Examples of the silicone surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all trade names, manufactured by Dow Corning Toray Silicone Co., Ltd.), TSF-4440, TSF-4300, TSF-4445, TSF-4460, and TSF-4452 (all trade names, manufactured by Momentive Performance Materials Inc.), KP341, KF6001, and KF6002 (trade name, manufactured by Shin-Etsu Silicone Co., Ltd.), and BYK307, BYK323, and BYK330 (all trade names, manufactured by BYK Chemie).

The surfactants may be used either singly or in a combination of two or more kinds thereof.

The amount of surfactant to be added is preferably 0.001% by mass to 2.0% by mass, and more preferably 0.005% by mass to 1.0% by mass, with respect to the total mass of the colored radiation-sensitive composition.

Other Components

The colored radiation-sensitive composition of the invention contains, if necessary, various additive such as a chain transfer agent such as N,N-dialkyl amino benzoic acid alkyl ester or 2-mercapto benzothiazole, a thermal polymerization initiator such as an azo compound or a peroxide compound, a thermal polymerization component, a polyfunctional thiol or epoxy compound for improving strength and sensitivity of a film, a UV absorbing agent such as alkoxy benzophenone, a plasticizer such as dioctyl phthalate, an agent for improving developability of low molecular weight organic carboxylic acid, other fillers, a polymer compound other than the specific binder and alkali soluble resin mentioned above, an anti-oxidant, and an anti-aggregation agent.

Further, to increase the curing level of a film by post heating after development, a thermal curing agent may be added. Examples of the thermal curing agent include a thermal polymerization initiator such as an azo compound or peroxide, a Novolac resin, a resol resin, an epoxy compound, and a styrene compound.

The total content of the colorants (that is, pigment and/or dye) contained in the radiation-sensitive composition of red, green, or blue color, which is used for producing the color filter of the invention, is preferably 20% by mass to 80% by mass, more preferably 25% by mass to 65% by mass, and still more preferably 30% by mass to 50% by mass, with respect to the total solid content in the radiation sensitive composition of each color.

By having the content of the colorant(s) within the above ranges, the color filter obtained exhibits favorable color reproducibility even in a thin film. Further, as the curing by radiation is fully progressed and strength of a cured colored film is maintained, narrowing of a development latitude at the time of alkali development is prevented.

According to the invention, the colored radiation-sensitive composition having red, green, or blue color may be produced by mixing and stirring respective components such as the colorant (in case of a pigment, a pigment dispersion is preferably prepared in advance and used), polymerizable compound, photopolymerization initiator, organic solvent, and if necessary, an alkali-soluble resin and a surfactant, and carrying out the filtration as described below.

The colored radiation-sensitive composition of the invention is preferably filtered by using a filter under the purpose of removing impurities or reducing defects. Any filter may be used without specific limitation, as long as it is conventionally used for filtering purpose of the like. Examples of the filter include a filter made of a fluoro resin such as PTFE (polytetrafluoro ethylene), a polyamide resin such as Nylon-6 and Nylon-6,6, and a polyolefin resin such as polyethylene and polypropylene (including high density and ultrahigh molecular weight). Of these, polypropylene (including high density polypropylene) is preferable.

The pore size of the filter is preferably about 0.01 to about 7.0 μm, more preferably about 0.01 to about 2.5 μm, and still more preferably about 0.01 to about 2.0 μm. When the pore size is within the ranges, complete removal of fine impurities, which inhibit a homogeneous and uniform production of a colored radiation-sensitive composition during a following process, is achieved.

When a filter is used, a combination of different filters may be used. In such a case, filtering using a first filter may be carried out either once or two or more times.

Alternatively, plural first filters having different pore size within the above ranges may be used in combination. As used herein, the pore size may be determined with reference to the nominal value provided by the manufacturer of a filter. Commercially available filter may be selected from various filters provided by Japan Pall Corporation, Advantec Toyo Kaisha, Ltd., Entegris, Inc. (formerly, Japan Micro Labs), or KITZ MICROFILTER CORPORATION, for example.

As the second filter, those formed with the same material as the first filtering may be used.

For example, only a dispersion may be filtered using the first filter, and the second filtering may be carried out after other components have been added to the filtered dispersion.

Production of Color Filter Using Colored Radiation-Sensitive Composition

Next, the color filter of the invention and the method for producing the color filter are described.

The color filter of the invention has a colored region (that is, color pattern) on a substrate, in which the colored region is obtained using the colored radiation-sensitive composition.

Hereinbelow, the color filter of the invention is described in greater detail in view of the production method thereof (that is, method for producing the color filter of the invention).

The method for producing a color filter of the invention includes: applying the colored radiation-sensitive composition described above on a substrate to form a colored radiation-sensitive composition layer (that is, colored layer) (colored layer formation process); subjecting the radiation-sensitive composition layer to pattern light exposure (exposure process); and developing the colored radiation-sensitive composition layer after the exposure to form a colored pattern (development process).

Colored Layer Formation Process

In the colored layer formation process, the colored radiation-sensitive composition is applied by coating on a substrate to form a colored layer (that is, colored radiation-sensitive composition layer) formed from the colored radiation-sensitive composition.

Examples of the substrate usable for this process include alkali-free glass, soda glass, PYREX (registered trade name) glass, quartz glass and products formed by adhering a transparent conductive film to them, which are used for a photoelectronic conversion element device substrate of CCD, CMOS, or organic CMOS used for a solid-state image sensor, a silicon substrate, or a liquid crystal display device or the like. On these substrates, a black matrix for isolating respective pixels may be also formed.

A lower coating layer may be formed on the substrates in order to achieve improvement of adhesion to upper layer, prevention of substance diffusion, or smoothening of a surface of the substrate.

As a method for coating the substrate with the colored radiation-sensitive composition, any one of various coating methods such as slit coating, ink jet coating, rotation coating, conformal coating, roll coating, and screen printing may be used.

The colored layer (that is, colored radiation-sensitive composition layer) formed by coating on a substrate may be dried (pre-baked), for example, by heating the substrate at 50° C. to 140° C. for 10 seconds to 300 seconds using a hot plate or an oven.

From the viewpoints of ensuring color density and lowering defects such as the difference in light collection efficiency between the terminal and center of a device and loss of light in tilt direction before reaching a light receiver, the film thickness of the colored layer after post-baking is preferably 0.05 μm or more and less than 1.0 μm, preferably from 0.1 μm to 0.9 μm, and particularly preferably from 0.2 μm to 0.9 μm.

Exposure Process

In the exposure process, the colored layer (that is, colored radiation-sensitive composition layer) formed in the colored layer formation process is exposed to light to yield a pattern shape.

In an exposure treatment in this process, the light exposure of a colored layer is preferably carried out by light exposure through a pre-determined mask pattern and curing only a portion of the coated film which is exposed to light. Preferred examples of the radiation usable for light exposure include radiation such as g ray, h ray, and i ray, and it is particularly preferably i ray. The exposure dose is preferably 30 mJ/cm² to 1,500 mJ/cm², more preferably 50 mJ/cm² to 1,000 mJ/cm², and still more preferably 80 mJ/cm² to 500 mJ/cm².

Development Process

Subsequent to the exposure process, the alkali development process (that is, development process) is performed to dissolve an uncured portion after light exposure using a developer and only the light-cured portions are remained intact. According to the development process, a patterned, coated film including pixels of each color is formed.

The development system is any of a dip system, a shower system, a spray system, and a puddle system, which may be combined with a swing system, a spin system, an ultrasonic system, or the like.

It is also possible to previously wet the surface to be developed with water or the like before allowing the surface to contact a developer, to prevent unevenness of development.

As a developer, an organic alkali developer which causes no damage on an underlying circuit or the like is preferable. The development temperature is generally 20° C. to 30° C., and the development time is from 20 seconds to 90 seconds.

Examples of the alkali agent contained in the developer include an organic alkaline compound such as aqueous ammonia, ethylamine, diethylamine, dimethyl ethanolamine, tetramethyl ammonium hydroxide, tetraethyl ammonium hydroxide, choline, pyrrole, piperidine, or 1,8-diazabicyclo-[5,4,0]-7-undecene, and an inorganic compound such as sodium hydroxide, potassium hydroxide, sodium hydrogen carbonate, or potassium hydrogen carbonate.

As a developer, an aqueous alkali solution in which the above-mentioned alkali agent is diluted with pure water to have concentration of 0.001% by mass to 10% by mass, and preferably 0.01% by mass to 1% by mass is preferably used. Further, when a developer including an aqueous alkali solution is used, washing with pure water (that is, rinsing) is generally performed to remove an excess developing solution followed by drying.

The production method of the invention may further include, after performing the colored layer forming process, exposure process, and development process, a curing process for curing the color pattern formed by post heating (that is, post-baking) or post exposure, if necessary. The post-basking is a process for achieving complete curing, that is, a heating treatment after development. In general, heating treatment is 100° C. to 270° C.

When light is used, g ray, h ray, or i ray, an excimer laser such as KrF or ArF, electronic beam, X ray, or the like may be used. However, it is preferably carried out at low temperature such as 20 to 50° C. using a known high pressure mercury lamp. Radiation time is from 10 seconds to 180 seconds, and preferably 30 seconds to 60 seconds. When post exposure and post heating are carried out in combination, it is preferable that post exposure is performed first.

By repeating the colored layer forming process, exposure process, and development process (in addition, curing process, if necessary) with desired number of times, a color filter having desired color hues is produced.

In the color filter of the invention, the composition cured at exposed portion has excellent adhesiveness to a substrate and excellent development resistance, the adhesiveness between a color pattern and a substrate is high, and colored pixels have fine patterns which can provide desired cross section shape.

Even when the colored radiation-sensitive composition in the invention adheres to nozzles of ejection ports of the application device, piping of the application device, or inside the application device, for example, it may be readily removed with a known cleaning liquid.

In order to perform the cleaning efficiently, the organic solvent described above as the solvent that may be used in the colored radiation sensitive composition is preferably used as a cleaning liquid.

Cleaning liquids described in JP-A No. 7-128867, JP-A No. 7-146562, JP-A No. 8-278637, JP-A No. 2000-273370, JP-A No. 2006-85140, JP-A No. 2006-291191, JP-A No. 2007-2101, JP-A No. 2007-2102, and JP-A No. 2007-281523 are also suitably used as a cleaning liquid for removing the colored radiation-sensitive composition of the invention.

The cleaning liquid is preferably alkylene glycol monoalkyl ether carboxylate or alkylene glycol monoalkyl ether.

These organic solvents which may be used as a cleaning liquid may be used either singly or in a combination of two or more kinds thereof.

When two or more organic solvents are mixed, a mixture of an organic solvent having a hydroxyl group and an organic solvent not having a hydroxyl group is preferred. The mass ratio of an organic solvent having a hydroxyl group and an organic solvent not having a hydroxyl group is from 1/99 to 99/1, preferably 10/90 to 90/10, and still more preferably 20/80 to 80/20. The mixture is particularly preferably a combination of propylene glycol monomethyl ether acetate (PGMEA) and propylene glycol monomethyl ether (PGME) mixed at a mass ratio of 60/40.

In order to improve permeability of the cleaning liquid with respect to the colored radiation sensitive composition, a surfactant as described above as the surfactant that may included in the colored radiation sensitive composition may be added to the cleaning liquid.

Accordingly, the color filter of the invention that is produced by the method for producing the color filter of the invention may be suitably used for a solid-state image sensor such as a CCD sensor, a CMOS sensor, or an organic CMOS sensor, an image display device such as electronic paper or organic EL, a liquid crystal display, or the like. In particular, the color filter of the invention is suitably used for a solid-state image sensor such as a CCD sensor, a CMOS sensor, or an organic CMOS sensor having a high resolution such as more than one million pixels. The color filter may be also used as a color filter which is placed between light receiver of each pixel and a micro lens for collecting light which constitutes a CCD device, for example.

Solid-State Image Sensor

The solid-state image sensor of the invention includes the color filter of the invention. The configuration of the solid-state image sensor of the invention is not specifically limited as long as it includes the color filter of the invention and functions as a solid-state image sensor. Examples thereof are described in the following.

An example of the solid-state image sensor of the invention has a configuration including plural photodiodes that constitute a light receiving area of a solid-state image sensor (such as a CCD sensor, CMOS sensor, organic CMOS sensor, or the like), and transfer electrodes made of polysilicon or the like formed on the substrate, a light shielding film including tungsten or the like in which only light receiving area of a photodiode remains open on the photodiodes and the transfer electrodes, a device protecting film including silicon nitride or the like formed on the light shielding film to cover the entire surface of the light shielding film and light receiving area of photodiodes, and the color filter for a solid-state image sensor of the invention is placed on the device protecting film.

Further, a configuration in which a method for collecting light (for example, a micro lens or the like, ditto herein below) is placed on top of the device protecting layer but under the color filter (that is, a side close to the substrate) or a configuration in which a method for collecting light is placed on the color filter may be also used.

Organic CMOS

The organic CMOS sensor has a bilayer hybrid structure including a thin panchromatic radiation sensitive organic photoelectric conversion film as a photoelectric conversion film and a substrate for reading CMOS signal, in which the organic materials are responsible for trapping light and converting it into an electric signal and the inorganic materials are responsible for delivering the electric signal to outside. In principle, the aperture ratio can be set as 100% compared to the incident light. Since the organic photoelectric conversion film is a continuous film which is free of any structure, and may be applied on a CMOS signal readout substrate, it does not require any expensive fine processing and is suitable for pixel micronization.

An example of a solid-state image sensor that is an organic CMOS is explained hereinbelow by referring to figures.

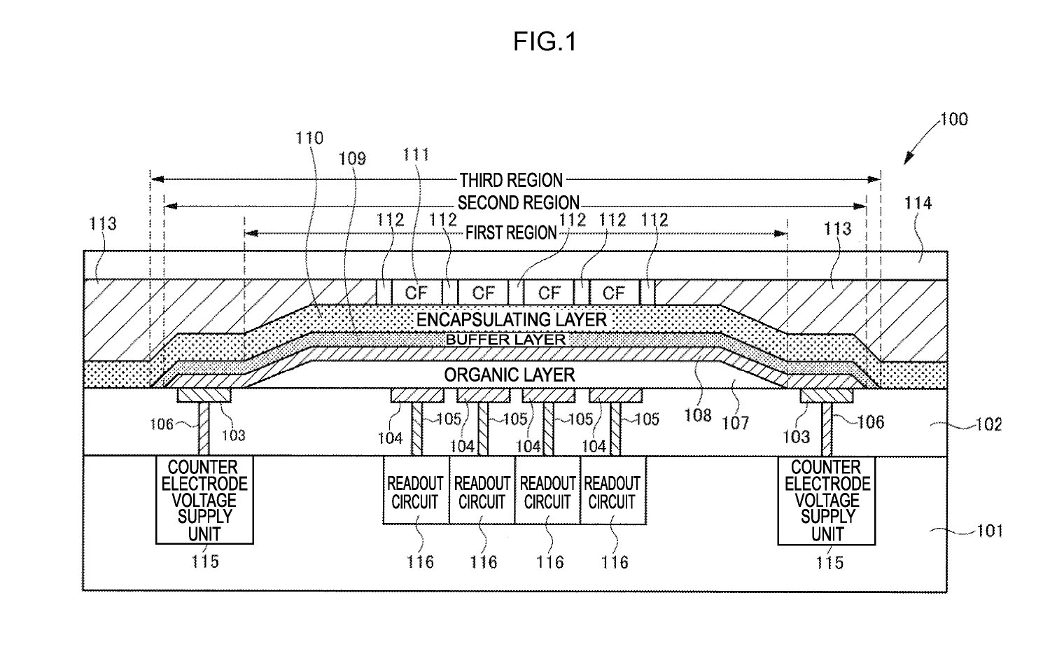

FIG. 1 is a schematic cross-sectional view of the configuration of a laminated image sensor (organic CMOS).

The image sensor 100 shown in FIG. 1 has: a substrate 101; an insulating layer 102; connection electrodes 103; pixel electrodes 104; connection portions 105; connection portions 106; an organic layer 107; a counter electrode 108; a buffer layer 109; a capping layer 110; color filters 111; partition walls 112; a light-shielding layer 113; a protective layer 114; counter electrode voltage supply units 115; and readout circuits 116.

When the color filter of the invention as described above is used as the color filters 111, an image sensor with less noise and excellent color reproduction is obtained.

The substrate 101 is a glass substrate or a semiconductor substrate made from silicon or the like. The insulating layer 102 is formed on the substrate 101, and on the surface of the insulating layer 102, plural pixel electrodes 104 and plural connection electrodes 103 are formed.

The organic layer 107 at least includes a photoelectric conversion layer. The photoelectric conversion layer generates electric charges in accordance with the received light, and is a layer formed from an inorganic or organic photoelectric conversion material. The organic layer 107 is formed on the plural pixel electrodes 104 so as to cover them. The organic layer 107 has a constant thickness on the pixel electrodes 104, but has a substantially trapezoidal shape at a terminal thereof, which declines toward the substrate 101 side.

When the organic layer 107 includes plural sub-layers, all of the sub-layers may be formed from organic materials, or a part of the sub-layers may be formed from an inorganic material.

The counter electrode 108 is an electrode that faces the pixel electrodes 104, and is formed on the organic layer 107 so as to cover the organic layer 107. The counter electrode 108 is formed from an electroconductive material, such as ITO, which is transparent to incident light so that the light is capable of entering the organic layer 107. The counter electrode 108 is also formed over the connection electrodes 103 that are arranged in regions outside of the organic layer 107, and is electrically connected to the connection electrodes 103.

The connection portions 106 are each embedded in the insulating layer 102, and each are a plug or the like that electrically connects the connection electrodes 103 and the counter electrode voltage supply units 115. The counter electrode voltage supply units 115 are each formed in the substrate 101, and each supply a predetermined voltage to the counter electrodes 104 via the connecting portions 106 and the connection electrodes 103. In a case in which the voltage to be supplied to the counter electrodes 104 is higher than the source voltage of the image sensor 100, the source voltage is raised using a voltage-increasing circuit such as a charge pump to the predetermined voltage.

The pixel electrodes 104 are charge-collecting electrodes that collect charges generated in the organic layer 107 that is present between the pixel electrodes 104 and the counter electrodes 108. The readout circuits 116 are arranged in the substrate 101 with respect to the plural pixel electrodes 104, and read out the signals corresponding to the charges collected by the pixel electrodes 104. The readout circuit 116 may be formed from a CCD, MOS circuit, or TFT circuit, and is protected by a light-shielding layer (not shown).

The buffer layer 109 is formed on the counter electrode 108 so as to cover the counter electrode 108. The capping layer 110 is formed on the buffer layer 109 so as to cover the buffer layer 109. The color filters 111 are formed on the capping layer 110 at positions facing the respective pixel electrodes 104. The partition walls 112 are arranged in the gaps between the color filters 111, and improve light transmission efficiency of the color filters 111. The light-shielding layer 113 is formed in a region on the capping layer 110 other than the region in which the color filters 111 and the partition walls 112 are formed, and the light-shielding layer 113 prevents light from entering the peripheral circuits. The protective layer 114 is formed on the color filters 111, the partition walls 112, and the light-shielding layer 113, and protects the entire image sensor.

In the example shown in FIG. 1, the pixel electrodes 104 and the connection electrodes 103 are formed so as to be embedded on the surface of the insulating layer 102, but the pixel electrodes 104 and the connection electrodes 103 may be formed on the insulating layer 102. Meanwhile, two sets of a connection electrode 103, a connecting portion 106, and a counter electrode voltage supply unit 115 are present in the example shown in FIG. 1, but there may be only one set thereof. In a case in which the voltage is supplied to the counter electrodes 108 from the two terminals of the counter electrodes 108 as shown in the example of FIG. 1, a reduction in voltage in the counter electrodes 108 is prevented. The number of sets may be appropriately increased or decreased in consideration of the chip area of the image sensor.

The image sensor 100 has plural pixel portions. The plural pixel portions are two-dimensionally arranged when viewed from the light incidence side of the substrate 101. The pixel portions each include at least a pixel electrode 104, an organic layer 107, a counter electrode 108 that faces the pixel electrode 104, a capping layer 110, a color filter 111, a partition wall 112, and a readout circuit 116.

Next, an example of configuration of peripheral circuits will be described. The readout circuit 116 mentioned above is preferably a CCD or CMOS circuit in a case of a general image sensor. From the viewpoints of noise and high speed, it is preferable to use a CMOS circuit. The example of configuration of peripheral circuits described below is an example of the configuration in which a CMOS circuit is used as the readout circuit 116.

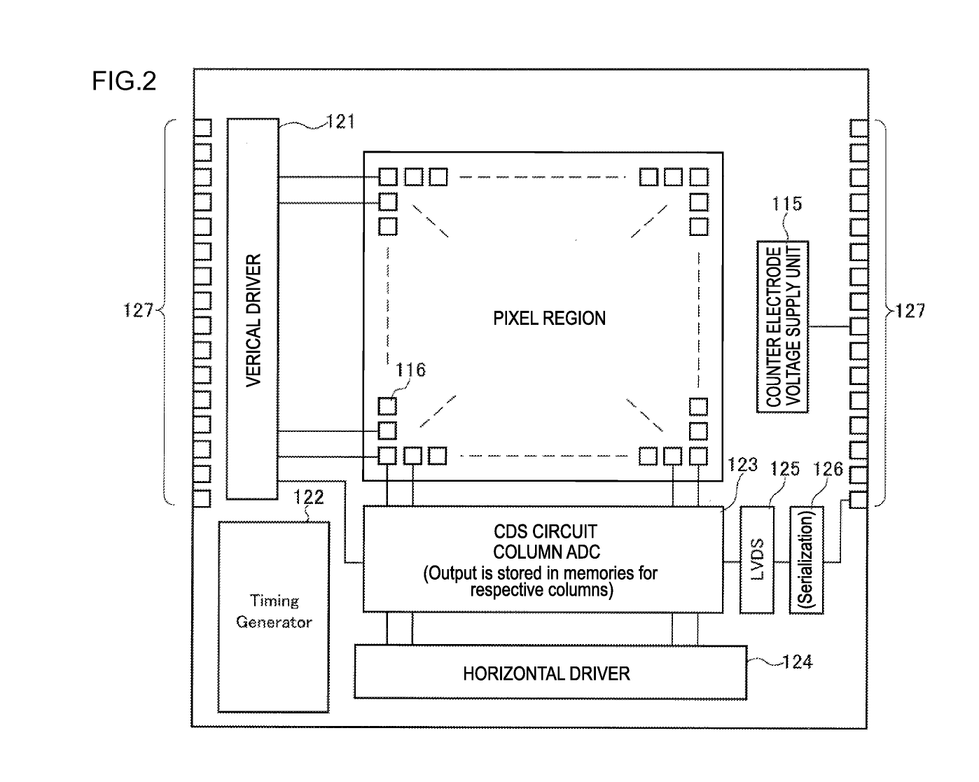

FIG. 2 is a view of the entire configuration example of the peripheral circuits of the image sensor shown in FIG. 1. As shown in FIG. 2, the image sensor 100 has, in addition to the configuration shown in FIG. 1, a vertical driver 121, a timing generator 122, a signal processing circuit 123, a horizontal driver 124, a LVDS 125, a serial conversion unit 126, and pads 127.

The pixel region shown in FIG. 2 corresponds to the first region shown in FIG. 1. The blocks in the pixel region each indicate a readout circuit 116. As the peripheral circuits of the image sensor, peripheral circuits that are substantially the same as those used in a commonly-used CMOS image sensor may be used. The image sensor of the invention is different from the commonly-used CMOS image sensor in that the peripheral circuits of the image sensor of the invention additionally includes a counter electrode voltage supply unit 115.

The pads 127 are each an interface used for input from and output to the outside. The timing generator 122 provides the timing for driving the image sensor, and also controls the readout such as sawing-in readout or partial readout. The signal processing circuit 123 is provided corresponding to the each row of readout circuit. The signal processing circuit 123 subjects the signal output from the corresponding row to correlated double sampling (CDS), and converts the processed signal to a digital signal. The signal which has undergone the processing in the signal processing circuit 123 is stored in a memory provided for each row. The vertical driver has functions such as controlling the readout of a signal from the readout circuit 116. The horizontal driver 124 controls the sequential readout of the signals corresponding to one row stored in the memory of the signal processing circuit 123, and output thereof to the LVDS 125. The LVDS 125 transmits a digital signal in accordance with LVDS (low voltage differential signaling). The serial conversion unit 126 converts the input parallel digital signal to a serial digital signal and outputs it.

The serial conversion unit 126 may be omitted. Alternatively, a configuration may be employed in which the signal processing circuit 123 conducts only correlated double sampling, and an AD converter circuit is provided instead of the LVDS 125. Alternatively, a configuration may be employed in which the signal processing circuit 123 conducts only correlated double sampling, and the LVDS 125 and the serial conversion unit 126 are omitted. In this case, an AD converter circuit may be provided outside the image sensor chip. The signal processing circuit 123, LVDS 125, and serial conversion unit 126 may be arranged in both regions adjacent to the pixel region, respectively. In this case, the half (for example, the odd number sequence) of the row the readout circuit 116 may be processed using the signal processing unit 123 in the region adjacent to the pixel region, and the other half (for example, the even number sequence) thereof may be processed using the signal processing unit 123 in another region adjacent to the pixel region.

### EXAMPLES

Hereinbelow, the invention is described in greater detail by referring to the examples. However, the invention is not limited to the examples as long as not departing from the gist of the invention. Further, unless specifically noted otherwise, the terms “part(s)” and “%” are in mass basis.

Preparation of Pigment Dispersion r-1

A mixture having the formulation mentioned below was mixed and dispersed for 3 hours using a bead mill (high-pressure dispersing machine equipped with a device for lowering pressure NANO-3000-10 (trade name, manufactured by Beryu Co., Ltd.) with zirconia beads having diameters of 0.3 mm, thereby preparing a pigment dispersion r-1.

| | |
|---|---|
| C.I. Pigment Red 254 | 8.9 parts |
| C.I. Pigment Yellow 139 | 4.0 parts |
| Dispersant: BYK-2001 (trade name, manufactured by BYK) | 3.9 parts |
| Resin 1: benzyl methacrylate/methacrylic acid copolymer | 1.3 parts |
| (=70/30 molar ratio, Mw: 30,000) | |
| Organic solvent: propylene glycol methyl ether acetate | 82 parts |

Preparation of Pigment Dispersions r-2 to r-5, g-1 to g-4, b-1, and b-2

The pigment dispersions r-2 to r-5, g-1 to g-4, b-1, and b-2 were prepared in the same manner as the preparation of the pigment dispersion r-1, except that C. I. Pigment Red 254 and C. I. Pigment Yellow 139 used for preparing the pigment dispersion r-1 were replaced with those described in the following Table 1A.

TABLE 1A

| Pigment | Colorant 1 | | Colorant 2 | | Colorant 3 | |
|---|---|---|---|---|---|---|
| dispersion | Type | Amount | Type | Amount | Type | Amount |
| r-1 | PR254 | 8.9 | PY139 | 4.0 | — | — |
| r-2 | Compound | 9.9 | PY139 | 3.0 | — | — |
| | A | | | | | |
| r-3 | PR254 | 2.0 | PY139 | 3.0 | PO71 | 7.9 |
| r-4 | PR254 | 5.4 | PY139 | 3.0 | PR166 | 4.4 |
| r-5 | PR254 | 12.9 | — | — | — | — |
| g-1 | PG36 | 7.1 | PY185 | 5.8 | — | — |
| g-2 | PG36 | 7.1 | PY150 | 5.8 | — | — |
| g-3 | PG36 | 8.7 | PY139 | 4.2 | — | — |
| g-4 | PG36 | 8.7 | PY150 | 2.1 | PY139 | 2.1 |
| b-1 | PB15:6 | 12.9 | — | — | — | — |
| b-2 | PB15:6 | 10.3 | PV23 | 2.6 | — | — |

In Table 1A, the colorants are as described below.
PR254: C. I. Pigment Red 254
PY139: C. I. Pigment Yellow 139
Compound A: a compound having the structure shown below, which was synthesized according to the synthetic method described in JP-A No. 2010-47750.
PR224: C. I. Pigment Red 224
PR166: C. I. Pigment Red 166
PO71: C. I. Pigment Orange 71
PG36: C. I. Pigment Green 36
PY150: C. I. Pigment Yellow 150
PY185: C. I. Pigment Yellow 185
PV23: C. I. Pigment Violet 23

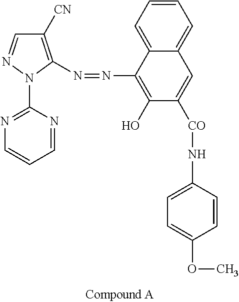 [SMILES: COc1ccc(NC(=O)c2cc3ccccc3c(N=Nc3c(C#N)cnn3-c3ncccn3)c2O)cc1]

Preparation of Colored Radiation-Sensitive Composition R-1

The following components were mixed, thereby preparing a colored radiation-sensitive composition R-1.

| | |
|---|---|
| Pigment dispersion R-1 | 46.7 parts |
| Alkali-soluble resin: Resin 1 described above | 3.6 parts |
| Polymerizable compound 1: dipentaerythritol hexaacrylate | 1.5 parts |
| (trade name: KAYARAD DPHA, manufactured by Nippon | |
| Kayaku Co., Ltd.) | |
| Polymerization initiator 1: a compound having the structure | 1.5 parts |
| described below (trade name: OXE-01, manufactured by | |
| BASF) | |
| Organic solvent: propylene glycol methyl ether acetate | 46.7 parts |

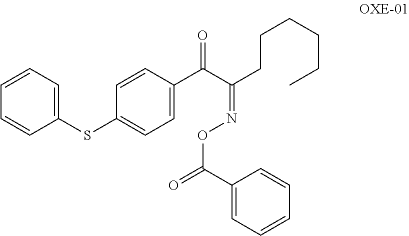 [SMILES: CCCCCC/C(=N/OC(=O)c1ccccc1)C(=O)c1ccc(Sc2ccccc2)cc1]

Preparation of Colored Radiation-Sensitive Compositions R-2 to R-5, G-1 to G-4, B-1, and B-2

The colored radiation-sensitive compositions R-2 to R-5, G-1 to G-4, B-1, and B-2 were prepared in the same manner as the preparation of the colored radiation-sensitive composition R-1, except that the type and amount of the pigment dispersion, amount of the alkali-soluble resin (above-mentioned Resin 1), and amount of the organic solvent were changed as shown in the following Table 2.

Meanwhile, for preparing the colored radiation-sensitive composition B-1, 2.4 parts of exemplary compound 1-2, which is a compound (dye) represented by Formula (M), was further added.

TABLE 2

| Colored | | | | |
|---|---|---|---|---|
| radiation- | | | Amount of alkali- | |
| sensitive | Pigment dispersion | | soluble resin | Amount of |
| composition | Type | Amount | (Resin 1) | organic solvent |
| R-1 | r-1 | 46.7 | 3.6 | 46.7 |
| R-2 | r-2 | 64.2 | 0.4 | 32.4 |
| R-3 | r-3 | 64.2 | 0.4 | 32.4 |
| R-4 | r-4 | 64.2 | 0.4 | 32.4 |
| R-5 | r-5 | 46.7 | 3.6 | 46.7 |
| G-1 | g-1 | 47.9 | 3.4 | 45.8 |
| G-2 | g-2 | 47.9 | 3.4 | 45.8 |
| G-3 | g-3 | 52.5 | 2.5 | 41.9 |
| G-4 | g-4 | 52.5 | 2.5 | 41.9 |
| B-1 | b-1 | 39.7 | 2.5 | 52.5 |
| B-2 | b-2 | 44.4 | 4.0 | 48.6 |

Examples 1 to 12 and Comparative Examples 1 to 3 were carried out using the colored radiation-sensitive compositions R-1 to R-5, G-1 to G-4, B-1, and B-2 in the combinations as shown in the following Table 3, followed by the following evaluations.

Spectral Characteristics

Each colored radiation-sensitive composition was spin-coated on a glass substrate to have a film thickness of 0.8 μm after post-baking, and dried using a hot plate at 100° C. for 180 seconds, followed by drying and a heating treatment (that is, post-baking) using a hot plate at 200° C. for 300 seconds.

The thus-obtained glass substrate having colored pixels thereon was subjected to transmission measurement in the wavelength range of 400 nm to 700 nm by using an ultraviolet, visible, and near infrared spectrophotometer UV3600 (trade name, manufactured by Shimadzu Corporation) (reference: glass substrate).

Transmittance of each colored pixel is shown in the following Table 3.

Color Reproducibility and Noise

The procedures of simulation were as follows.

Regarding 24 colors of a Macbeth chart, light source for illumination was defined and spectral reflection ratio was obtained for 400 to 700 nm. After that, infrared cut filter characteristics of a sensor and spectral sensitivity of a sensor were defined, and the exposure amount for each of RGB received by the spectral sensor measured above was calculated. After that, the quantity of electric charge for each color of R, G, and B was calculated based on the exposure amount.

Further, in view of the quantity of electric charge, output signals r, g, and b for each color of R, G, and B and noise (short noise, dark noise, and fixed pattern noise) were calculated.

From the noise values thus obtained, luminance signal-to-noise (S/N) was calculated, and the luminance value at which S/N is 10 (referred to as “SNR10”) was used as an indicator of noise. A smaller SNR 10 value indicates a better score in the noise evaluation.

Regarding the color reproducibility, L*a*b* was calculated for the 24 colors of a Macbeth chart used for the original calculation. Further, by calculating each L*a*b* from the output signal r, g, and b obtained from above, color difference compared to the original Macbeth chart (referred to as “ΔE2000”) was calculated and used as an indicator of color reproducibility. A smaller ΔE2000 value indicates a better score in the color reproducibility evaluation.

Based on the ΔE2000 value, 5-level evaluation of the color reproducibility was conducted. Level 3 or higher level was recognized as acceptable.

Based on the SNR 10 value, 5-level evaluation of the noise was conducted. Level 3 or higher level was recognized as acceptable.

TABLE 3

| | Colored radiation- | | | | | Transmittance | | | | | Color | |
|---|---|---|---|---|---|---|---|---|---|---|---|---|
| | sensitive | | | Transmittance | | in green pixel | | Transmittance | | | reproduc- | |
| | composition | | | in red pixel | | | 500 nm to | in blue pixel | | | ibility | Noise |
| | Red | Green | Blue | 400 nm | 650 nm | 450 nm | 600 nm | 450 nm | 500 nm | 700 nm | (ΔE2000) | (SNR10) |
| Example 1 | R-1 | G-1 | B-1 | 15% or less | 90% or more | 5% or | 90% or | 85% or | 10% to 50% | 10% or less | 3 | 3 |
| | | | | | | less | more | more | | | | |
| Example 2 | R-1 | G-2 | B-1 | 15% or less | 90% or more | 5% or | 90% or | 85% or | 10% to 50% | 10% or less | 3 | 3 |
| | | | | | | less | more | more | | | | |
| Example 3 | R-1 | G-4 | B-1 | 15% or less | 90% or more | 5% or | 90% or | 85% or | 10% to 50% | 10% or less | 3 | 3 |
| | | | | | | less | more | more | | | | |
| Example 4 | R-3 | G-1 | B-1 | 15% or less | 90% or more | 5% or | 90% or | 85% or | 10% to 50% | 10% or less | 4 | 4 |
| | | | | | | less | more | more | | | | |
| Example 5 | R-3 | G-2 | B-1 | 15% or less | 90% or more | 5% or | 90% or | 85% or | 10% to 50% | 10% or less | 4 | 3 |
| | | | | | | less | more | more | | | | |
| Example 6 | R-3 | G-4 | B-1 | 15% or less | 90% or more | 5% or | 90% or | 85% or | 10% to 50% | 10% or less | 5 | 5 |
| | | | | | | less | more | more | | | | |
| Example 7 | R-4 | G-1 | B-1 | 15% or less | 90% or more | 5% or | 90% or | 85% or | 10% to 50% | 10% or less | 4 | 4 |
| | | | | | | less | more | more | | | | |
| Example 8 | R-4 | G-2 | B-1 | 15% or less | 90% or more | 5% or | 90% or | 85% or | 10% to 50% | 10% or less | 4 | 3 |
| | | | | | | less | more | more | | | | |
| Example 9 | R-4 | G-4 | B-1 | 15% or less | 90% or more | 5% or | 90% or | 85% or | 10% to 50% | 10% or less | 4 | 4 |
| | | | | | | less | more | more | | | | |
| Example 10 | R-2 | G-1 | B-1 | 15% or less | 90% or more | 5% or | 90% or | 85% or | 10% to 50% | 10% or less | 3 | 4 |
| | | | | | | less | more | more | | | | |
| Example 11 | R-2 | G-2 | B-1 | 15% or less | 90% or more | 5% or | 90% or | 85% or | 10% to 50% | 10% or less | 3 | 4 |
| | | | | | | less | more | more | | | | |
| Example 12 | R-2 | G-4 | B-1 | 15% or less | 90% or more | 5% or | 90% or | 85% or | 10% to 50% | 10% or less | 3 | 5 |
| | | | | | | less | more | more | | | | |
| Comparative | R-5 | G-1 | B-1 | More than | 90% or more | 5% or | 90% or | 85% or | 10% to 50% | 10% or less | 2 | 3 |
| Example 1 | | | | 15% | | less | more | more | | | | |
| Comparative | R-1 | G-1 | B-2 | 15% or less | 90% or more | 5% or | 90% or | Less | 10% to 50% | 10% or less | 2 | 2 |
| Example 2 | | | | | | less | more | than | | | | |
| | | | | | | | | 85% | | | | |
| Comparative | R-1 | G-3 | B-1 | 15% or less | 90% or more | 5% or | Less than | 85% or | 10% to 50% | 10% or less | 2 | 3 |
| Example 3 | | | | | | less | 90% | more | | | | |

Details of Evaluation Simulation

The calculation processes for the simulation were as described in the following. First, the exposure amounts ER, EG, and EB of in the respective pixels of the sensor having R, G, B colors were calculated according to the following Formulae (I-1) to (I-3).

E_{R}=∫L(λ)·R(λ)·CMM_{R}(λ)·IRC(λ)·SEN(λ)·dλ (I-1)

E_{G}=∫L(λ)·R(λ)·CMM_{G}(λ)·IRC(λ)·SEN(λ)·dλ (I-2)

E_{B}=∫L(λ)·R(λ)·CMM_{B}(λ)·IRC(λ)·SEN(λ)·dλ (I-3)

Details of Formula (I-1) to (I-3) were as described below.

L(λ) indicates the spectral intensity distribution of the light source.

R(λ) indicates the spectral reflection ratio of an object.

CMMi(λ) indicates the spectral transmittance of a color mosaic material, in which i indicates R, G, or B.

IRC(λ) indicates the spectral transmittance of an infrared light cut filter.

SEN(λ) indicates the spectral sensitivity of the sensor itself.

For L(λ), the data obtained when a D65 light source was used was used for ΔE2000 that is a standard for the evaluation of color reproduction, and the data obtained when an A light source was used for SNR10 that was a standard for the evaluation of noise.

For R(λ), spectral reflection factors of 24 colors which were obtained using COLOR CHECKER manufactured by Gretag Macbeth described below.

For CMMi(λ), the data of spectral transmittances of R, G, and B obtained in the Examples of the present application were respectively used.

For the data of IRC(λ), the data shown in the following Table 4 were used.

TABLE 4

| Wavelength | Relative transmission amount |
|---|---|
| 400 | 0.9109 |
| 410 | 0.8954 |
| 420 | 0.9297 |
| 430 | 0.9245 |
| 440 | 0.8857 |
| 450 | 0.9341 |
| 460 | 0.9444 |
| 470 | 0.9498 |
| 480 | 0.9690 |
| 490 | 0.9562 |
| 500 | 0.9396 |
| 510 | 0.9614 |
| 520 | 0.9094 |
| 530 | 0.9738 |
| 540 | 0.9692 |
| 550 | 0.9471 |
| 560 | 0.9689 |
| 570 | 0.9573 |
| 580 | 0.9702 |
| 590 | 0.9628 |
| 600 | 0.9674 |
| 610 | 0.9739 |
| 620 | 0.9676 |
| 630 | 0.9610 |
| 640 | 0.9655 |
| 650 | 0.8403 |
| 660 | 0.4879 |
| 670 | 0.2264 |
| 680 | 0.0948 |
| 690 | 0.0435 |
| 700 | 0.0239 |

For the data of SEN(λ), the data shown in the following Table 5 were used.

TABLE 5

| Wavelength | Relative sensitivity |
|---|---|
| 400 | 0.47 |
| 410 | 0.49 |
| 420 | 0.53 |
| 430 | 0.56 |
| 440 | 0.55 |
| 450 | 0.55 |
| 460 | 0.56 |
| 470 | 0.57 |
| 480 | 0.56 |
| 490 | 0.54 |
| 500 | 0.53 |
| 510 | 0.53 |
| 520 | 0.53 |
| 530 | 0.52 |
| 540 | 0.51 |
| 550 | 0.50 |
| 560 | 0.49 |
| 570 | 0.47 |
| 580 | 0.45 |
| 590 | 0.43 |
| 600 | 0.42 |
| 610 | 0.41 |
| 620 | 0.40 |
| 630 | 0.38 |
| 640 | 0.36 |
| 650 | 0.35 |
| 660 | 0.33 |
| 670 | 0.31 |
| 680 | 0.28 |
| 690 | 0.26 |
| 700 | 0.25 |

The obtained exposure amounts were standardized in accordance with the following standard values.

That is, the value among ER, EG, and RB that showed the maximum exposure amount with respect to a white object (i.e., an object having a reflectance of 1 with respect to any wavelength) was defined as the standard value Emax.

Subsequently, the exposure amounts were converted to generated charge amounts GCR, GCG, and GCB in accordance with the following Formulae (II-1) to (II-3).

$$\begin{matrix}{GC}_{R} = \frac{{C}_{MAX}}{2} \cdot \frac{{E}_{R}}{{E}_{MAX}} & ( II - 1 ) \\ {GC}_{G} = \frac{{C}_{MAX}}{2} \cdot \frac{{E}_{G}}{{E}_{MAX}} & ( II - 2 ) \\ {GC}_{B} = \frac{{C}_{MAX}}{2} \cdot \frac{{E}_{B}}{{E}_{MAX}} & ( II - 3 )\end{matrix}$$

In Formulae (II-1) to (II-3), CMAX indicates the number of saturated charges of the sensor, and CMAX was set to be 6,000.

In Formulae (II-1) to (II-3), ER, EG, and EB correspond to the exposure amounts ER, EG, and EB which are calculated by Formula (I-1) and (I-3) above, respectively, and Emax corresponds to the Emax mentioned above.

As described above, generated charge amounts of GCR, GCG, and GCB in respective channels of R, G, and B were determined.

The total noise Ni was defined as described below

Ni=(GCi+(GCi)²/10000+9)^{0.5}

Subsequently, the following color conversion matrix was applied to the values obtained by standardizing the charge amounts with respect to the charge amounts of white light source, thereby obtaining output signals r, g, and b.

$$( \begin{matrix}r \\ g \\ b\end{matrix} ) = ( \begin{matrix}a & b & c \\ d & e & f \\ g & h & i\end{matrix} ) ( \begin{matrix}{GC}_{R} \text{/} {GC}_{R\_White} \\ {GC}_{G} \text{/} {GC}_{G\_White} \\ {GC}_{B} \text{/} {GC}_{B\_White}\end{matrix} ) \qquad ( III )$$

In Formula (III), Ci_white (in which i=R, G, or B) was calculated by multiplying the spectral sensitivity of light sources and image sensors of respective colors.

The respective components a to i of the 3×3 matrix were determined by the following process.

Specifically, the output value of the present simulation system was subjected to 3×3 matrix conversion using, as a target value, the exposure amount calculated using a spectral sensitivity defined by the transmission standard (ITU-R, BT. 470-6), and the matrix coefficients were optimized so that the thus-obtained value can reach the target value as possible, thereby determining the value.

More specifically, the 24 colors of Gretag Machbeth Color Checker were used as an object, and the 9 matrix factors were optimized so that the margin of errors in exposure amount for the image output values of the 24 sets become the minimum, with respect to the target value calculated according to the transmission standard.

The noise signal amounts nr, ng, and nb respectively corresponding to r, g, and b signals were represented by the following Formula (IV-1) to (IV-3).

nr=\sqrt{a²·N_{R}²+b²·N_{G}²+c²·N_{B}²} (IV-1)

ng=\sqrt{d²·N_{R}²+e²·N_{G}²+f²·N_{B}²} (IV-2)

nb=\sqrt{g²·N_{R}²+h²·N_{G}²+i²·N_{B}²} (IV-3)

Using Formula (IV-1) to (IV-3), the S/N represented by the following Formula (V) was calculated.

$$\begin{matrix}S \text{/} N = Y \text{/} {N}_{Y} \\ = ( x \cdot r + y \cdot g + z \cdot b ) \text{/} ( \sqrt{{x}^{2} \cdot n {r}^{2} + {y}^{2} \cdot {ng}^{2} + {z}^{2} \cdot {nb}^{2}} )\end{matrix} \qquad ( V )$$

In Formula (V), x, y, and z indicates the proportions of the R, G, and B signals that constitute the luminance, respectively, and the values employed in the transmission standard used herein were as follows: (x, y, z)=(0.299, 0.587, 0.114).

The S/N value under certain conditions can be calculated as described above. However, since the S/N value may change depending on the intensity of illumination, an illuminance value (SNR 10) with which a S/N value of exactly 10 is obtained was used as an evaluation value.

Specifically, the intensity of illumination spectral distribution L(λ) was proportionally reduced and the S/N values were calculated, so as to determine the relationship between the relative intensity of illumination and the S/N value. Then, the relative intensity of illumination at which the S/N value of 10 was obtained was determined, and the obtained value was used as the SNR¹⁰ value.

The color reproduction error Δ2000 was indicated as an average color difference in the L*a*b* space with respect to the Machbeth 24 colors. The conversion of the r, g, b signals to X, Y, and Z was performed according to the matrix shown in the following Formula (VI).

$$( \begin{matrix}X \\ Y \\ Z\end{matrix} ) = ( \begin{matrix}0.43055 & 0.34155 & 0.17835 \\ 0.22200 & 0.70665 & 0.07134 \\ 0.02018 & 0.12955 & 0.93932\end{matrix} ) ( \begin{matrix}r \\ g \\ b\end{matrix} ) \qquad ( VI )$$

The factor values of the conversion matrix of Formula (VI) have the same definition as those of the conversion matrix defined in the transmission standard. The conversion of XYZ to L*a*b* was performed according to a known conversion equation. The color differences ΔE2000 between the obtained L*a*b* values for the Macbeth Color Checker 24 colors and the L*a*b* value of the original color were obtained in accordance with a known equation, and the average color difference was calculated and the obtained average value was used as ΔE2000.

As described above, the factor values of the conversion matrix of Formula (VI) were the same as the conversion matrix factors defined by the transmission standard. Thus, when color radiation-sensitive compositions of respective colors obtained in the Examples of the present invention are used, excellent color filters which is conformable with the transmission standard are obtained.

The present application claims priority from Japanese Patent Application Nos. 2011-126294 and 2012-096541, the disclosures of which are incorporated herein by reference.

All publications, patent applications, and technical standards mentioned in this specification are herein incorporated by reference to the same extent as if each individual publication, patent application, or technical standard was specifically and individually indicated to be incorporated by reference.

1. A color filter, comprising:
a red pixel in which a transmittance of a light having a wavelength of 400 nm is 15% or less, and a transmittance of a light having a wavelength of 650 nm is 90% or more;
a green pixel in which a transmittance of a light having a wavelength of 450 nm is 5% or less, and a transmittance of a light having a wavelength within a range of from 500 nm to 600 nm is 90% or more; and
a blue pixel in which a transmittance of a light having a wavelength of 450 nm is 85% or more, a transmittance of a light having a wavelength of 500 nm is from 10% to 50%, and a transmittance of a light having a wavelength of 700 nm is 10% or less.

2. The color filter according to claim 1, wherein:
the red pixel comprises C. I. Pigment Yellow 139;
the green pixel comprises at least one of C. I. Pigment Yellow 185 or C. I. Pigment Yellow 150; and
the blue pixel comprises a dipyrromethene dye represented by the following Formula (M): 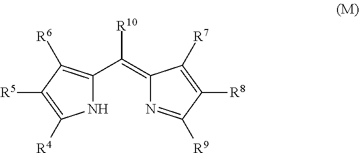
wherein, in Formula (M), R⁴ to R¹⁰ each independently represent a hydrogen atom or a monovalent substituent; provided that R⁴ and R⁹ do not bind with each other to form a ring.

3. The color filter according to claim 2, wherein the total content of C. I. Pigment Yellow 185 and C. I. Pigment Yellow 150 in the green pixel is from 10% by mass to 60% by mass with respect to the total mass of the colorants included in the green pixel.

4. The color filter according to claim 2, wherein the content of C. I. Pigment Yellow 139 in the red pixel is from 20% by mass to 50% by mass with respect to the total mass of the colorants included in the red pixel.

5. The color filter according to claim 3, wherein the content of C. I. Pigment Yellow 139 in the red pixel is from 20% by mass to 50% by mass with respect to the total mass of the colorants included in the red pixel.

6. The color filter according to claim 2, wherein the content of the dipyrromethene dye represented by Formula (M) in the blue pixel is from 10% by mass to 50% by mass with respect to the total mass of the colorants included in the blue pixel.

7. The color filter according to claim 3, wherein the content of the dipyrromethene dye represented by Formula (M) in the blue pixel is from 10% by mass to 50% by mass with respect to the total mass of the colorants included in the blue pixel.

8. The color filter according to claim 4, wherein the content of the dipyrromethene dye represented by Formula (M) in the blue pixel is from 10% by mass to 50% by mass with respect to the total mass of the colorants included in the blue pixel.

9. The color filter according to claim 5, wherein the content of the dipyrromethene dye represented by Formula (M) in the blue pixel is from 10% by mass to 50% by mass with respect to the total mass of the colorants included in the blue pixel.

10. A CCD sensor, comprising the color filter according to claim 1.

11. A CMOS sensor, comprising the color filter according to claim 1.

12. An organic CMOS sensor, comprising the color filter according to claim 1.

13. A solid-state image sensor, comprising the color filter according to claim 1.
